(19) United States
(12) Patent Application Publication
(10) Pub. No.: US 2021/0091002 A1
(43) Pub. Date: Mar. 25, 2021

(54) SEMICONDUCTOR MEMORY DEVICE AND METHOD FOR MANUFACTURING SEMICONDUCTOR MEMORY DEVICE

(71) Applicant: Kioxia Corporation, Minato-ku (JP)

(72) Inventor: Kojiro Shimizu, Yokkaichi (JP)

(73) Assignee: Kioxia Corporation, Minato-ku (JP)

(21) Appl. No.: 16/936,656

(22) Filed: Jul. 23, 2020

(30) Foreign Application Priority Data
Sep. 20, 2019 (JP) 2019-171226

(51) Int. Cl. H01L 23/535; H01L 27/11565; H01L 27/11582; H01L 27/1157; H01L 23/522; H01L 23/528; H01L 21/768

(52) U.S. Cl. CPC H01L 23/535; H01L 27/11565; H01L 27/11582; H01L 27/1157; H01L 21/76895; H01L 23/5283; H01L 21/76877; H01L 21/76805; H01L 23/5226

(57) ABSTRACT

A semiconductor memory device according to one embodiment includes: a first laminated body including a first conductive layer, a first insulating layer, a second conductive layer, and a second insulating layer that are sequentially stacked; a first pillar passing through the first laminated body, and including portions intersecting with the first and second conductive layers and configured to function as first and second memory cell transistors, respectively; a third insulating layer provided above the first laminated body; a first stopper provided on the first insulating layer on a first region of the first conductive layer; and a second stopper provided on the second insulating layer on a second region of the second conductive layer, and separated from the first stopper.

### CROSS-REFERENCE TO RELATED APPLICATIONS

This application is based upon and claims the benefit of priority from prior Japanese Patent Application No. 2019-171226, filed Sep. 20, 2019; the entire contents of which are incorporated herein by reference.

### FIELD

Embodiments described herein relate generally to a semiconductor memory device and a method for manufacturing the semiconductor memory device.

### BACKGROUND

A NAND flash memory, which can non-volatilely store data, is known.

### BRIEF DESCRIPTION OF THE DRAWINGS

FIG. 1 is a block diagram showing an example of the configuration of a semiconductor memory device according to an embodiment.

FIG. 2 is a circuit diagram showing an example of the circuit configuration of a memory cell array included in the semiconductor memory device according to the embodiment.

FIG. 3 is a plan view showing an example of the planar layout of the memory cell array included in the semiconductor memory device according to the embodiment.

FIG. 4 shows an example of the detailed planar layout in a cell area of the memory cell array of the semiconductor memory device according to the embodiment, focusing on area A in FIG. 3.

FIG. 5 shows an example of the cross-sectional structure in the cell area of the memory cell array of the semiconductor memory device according to the embodiment.

FIG. 6 is a cross-sectional view taken along line D-D in FIG. 5, showing an example of a memory pillar in the semiconductor memory device according to the embodiment.

FIG. 7 shows an example of the detailed planar layout in a hookup area of the memory cell array of the semiconductor memory device according to the embodiment, focusing on area B in FIG. 3.

FIG. 8 is a cross-sectional view taken along line E-E in FIG. 7, showing an example of the cross-sectional structure in the hookup area of the memory cell array included in the semiconductor memory device according to the embodiment.

FIG. 9 is a cross-sectional view taken along line F-F in FIG. 7, showing an example of the cross-sectional structure in the hookup area of the memory cell array included in the semiconductor memory device according to the embodiment.

FIG. 10 is a cross-sectional view taken along line G-G in FIG. 7, showing an example of the cross-sectional structure in the hookup area of the memory cell array included in the semiconductor memory device according to the embodiment.

FIG. 11 is a cross-sectional view taken along line H-H in FIG. 7, showing an example of the cross-sectional structure in the hookup area of the memory cell array included in the semiconductor memory device according to the embodiment.

FIG. 12 is a flowchart showing an example of a method for manufacturing the semiconductor memory device according to the embodiment.

FIG. 13 shows an example of the planar layout of the semiconductor memory device during manufacturing.

FIG. 14 is a cross-sectional view showing a cross section taken along line E-E in FIG. 13 and a cross section taken along line F-F in FIG. 13.

FIG. 15 is a cross-sectional view showing a cross section taken along line G-G in FIG. 13 and a cross section taken along line H-H in FIG. 13.

FIG. 16 shows an example of the planar layout of the semiconductor memory device during manufacturing.

FIG. 17 is a cross-sectional view showing a cross section taken along line E-E in FIG. 16 and a cross section taken along line F-F in FIG. 16.

FIG. 18 is a cross-sectional view showing a cross section taken along line G-G in FIG. 16 and a cross section taken along line H-H in FIG. 16.

FIG. 19 shows an example of the planar layout of the semiconductor memory device during manufacturing.

FIG. 20 is a cross-sectional view showing a cross section taken along line E-E in FIG. 19 and a cross section taken along line F-F in FIG. 19.

FIG. 21 is a cross-sectional view showing a cross section taken along line G-G in FIG. 19 and a cross section taken along line H-H in FIG. 19.

FIG. 22 is a cross-sectional view showing a cross section taken along line E-E in FIG. 19 and a cross section taken along line F-F in FIG. 19.

FIG. 23 is a cross-sectional view showing a cross section taken along line G-G in FIG. 19 and a cross section taken along line H-H in FIG. 19.

FIG. 24 is a cross-sectional view showing a cross section taken along line E-E in FIG. 19 and a cross section taken along line F-F in FIG. 19.

FIG. 25 is a cross-sectional view showing a cross section taken along line G-G in FIG. 19 and a cross section taken along line H-H in FIG. 19.

FIG. 26 shows an example of the planar layout of the semiconductor memory device during manufacturing.

FIG. 27 is a cross-sectional view showing a cross section taken along line E-E in FIG. 26 and a cross section taken along line F-F in FIG. 26.

FIG. 28 is a cross-sectional view showing a cross section taken along line G-G in FIG. 26 and a cross section taken along line H-H in FIG. 26.

FIG. 29 shows an example of the planar layout of the semiconductor memory device during manufacturing.

FIG. 30 is a cross-sectional view showing a cross section taken along line E-E in FIG. 29.

FIG. 31 is a cross-sectional view showing a cross section taken along line F-F in FIG. 29.

FIG. 32 is a cross-sectional view showing a cross section taken along line G-G in FIG. 29.

FIG. 33 is a cross-sectional view showing a cross section taken along line H-H in FIG. 29.

FIG. 34 shows an example of the planar layout of the semiconductor memory device during manufacturing.

FIG. 35 is a cross-sectional view showing a cross section taken along line E-E in FIG. 34.

FIG. 36 is a cross-sectional view showing a cross section taken along line F-F in FIG. 34.

FIG. 37 is a cross-sectional view showing a cross section taken along line H-H in FIG. 34.

FIG. 38 shows an example of the planar layout of the semiconductor memory device during manufacturing.

FIG. 39 is a cross-sectional view showing a cross section taken along line F-F in FIG. 38.

FIG. 40 is a cross-sectional view showing a cross section taken along line H-H in FIG. 38.

FIG. 41 shows an example of the planar layout of the semiconductor memory device during manufacturing.

FIG. 42 is a cross-sectional view showing a cross section taken along line E-E in FIG. 41.

FIG. 43 is a cross-sectional view showing a cross section taken along line F-F in FIG. 41.

FIG. 44 is a cross-sectional view showing a cross section taken along line H-H in FIG. 41.

FIG. 45 shows an example of the planar layout of the semiconductor memory device during manufacturing.

FIG. 46 is a cross-sectional view showing a cross section taken along line E-E in FIG. 45.

FIG. 47 is a cross-sectional view showing a cross section taken along line F-F in FIG. 45.

FIG. 48 is a cross-sectional view showing a cross section taken along line E-E in FIG. 45.

FIG. 49 is a cross-sectional view showing a cross section taken along line F-F in FIG. 45.

FIG. 50 is a cross-sectional view showing a cross section taken along line G-G in FIG. 45.

FIG. 51 is a cross-sectional view showing a cross section taken along line H-H in FIG. 45.

FIG. 52 shows an example of the planar layout of the semiconductor memory device during manufacturing.

FIG. 53 is a cross-sectional view showing a cross section taken along line E-E in FIG. 52.

FIG. 54 is a cross-sectional view showing a cross section taken along line F-F in FIG. 52.

FIG. 55 shows an example of the planar layout of the semiconductor memory device during manufacturing.

FIG. 56 is a cross-sectional view showing a cross section taken along line E-E in FIG. 55.

FIG. 57 is a cross-sectional view showing a cross section taken along line G-G in FIG. 55.

FIG. 58 shows an example of the planar layout of the semiconductor memory device during manufacturing.

FIG. 59 is a cross-sectional view showing a cross section taken along line E-E in FIG. 58.

FIG. 60 is a cross-sectional view showing a cross section taken along line G-G in FIG. 58.

FIG. 61 is a flowchart showing an example of a method for manufacturing a semiconductor memory device according to a first modification of the embodiment.

FIG. 62 is a cross-sectional view showing a cross section taken along line E-E in FIG. 55.

FIG. 63 is a cross-sectional view showing a cross section taken along line F-F in FIG. 55.

FIG. 64 is a cross-sectional view showing a cross section taken along line G-G in FIG. 55.

FIG. 65 is a cross-sectional view showing a cross section taken along line E-E in FIG. 55.

FIG. 66 is a cross-sectional view showing a cross section taken along line F-F in FIG. 55.

FIG. 67 is a cross-sectional view showing a cross section taken along line G-G in FIG. 55.

FIG. 68 is a cross-sectional view showing a cross section taken along line E-E in FIG. 58.

FIG. 69 is a cross-sectional view showing a cross section taken along line G-G in FIG. 58.

FIG. 70 is a cross-sectional view showing a cross section taken along line E-E in FIG. 7.

FIG. 71 is a cross-sectional view showing a cross section taken along line G-G in FIG. 7.

FIG. 72 is a flowchart showing an example of a method for manufacturing a semiconductor memory device according to a second modification of the embodiment.

FIG. 73 is a cross-sectional view showing a cross section taken along line E-E in FIG. 55.

FIG. 74 is a cross-sectional view showing a cross section taken along line G-G in FIG. 55.

FIG. 75 is a cross-sectional view showing a cross section taken along line E-E in FIG. 55.

FIG. 76 is a cross-sectional view showing a cross section taken along line G-G in FIG. 55.

FIG. 77 is a cross-sectional view showing a cross section taken along line E-E in FIG. 58.

FIG. 78 is a cross-sectional view showing a cross section taken along line G-G in FIG. 58.

FIG. 79 is a cross-sectional view showing a cross section taken along line E-E in FIG. 7.

FIG. 80 is a cross-sectional view showing a cross section taken along line G-G in FIG. 7.

FIG. 81 is a flowchart showing an example of a method for manufacturing a semiconductor memory device according to a third modification of the embodiment.

FIG. 82 is a cross-sectional view showing a cross section taken along line E-E in FIG. 58.

FIG. 83 is a cross-sectional view showing a cross section taken along line G-G in FIG. 58.

FIG. 84 is a cross-sectional view showing a cross section taken along line E-E in FIG. 7.

FIG. 85 is a cross-sectional view showing a cross section taken along line G-G in FIG. 7.

### DETAILED DESCRIPTION

A semiconductor memory device according to one embodiment includes: a first laminated body including a first conductive layer, a first insulating layer, a second conductive layer, and a second insulating layer, the first conductive layer, the first insulating layer, the second conductive layer, and the second insulating layer being sequentially stacked in a first direction; a first pillar passing through the first laminated body, and including portions intersecting with the first and second conductive layers and configured to function as first and second memory cell transistors, respectively; a third insulating layer provided above the first laminated body; a first stopper having an etching rate different from etching rates of the first to third insulating layers and provided on the first insulating layer on a first region of the first conductive layer; a second stopper having an etching rate different from the etching rates of the first to third insulating layers, provided on the second insulating layer on a second region of the second conductive layer, and separated from the first stopper; a third conductive layer passing through the first insulating layer, the first stopper, and the third insulating layer, and coupled to the first region; and a fourth conductive layer passing through the second insulating layer, the second stopper, and the third insulating layer, and coupled to the second region.

Hereinafter, an embodiment will be described with reference to the accompanying drawings. The embodiment exemplifies the device and method that embodies the technical concept. The drawings are schematic or conceptual, and the dimensions, ratios, and the like in the drawings are not always the same as the actual ones. The technical idea of the embodiment is not specified by the shapes, structures, arrangements, and the like of the constituent elements.

In the following description, structural elements having substantially the same function and configuration will be assigned the same reference symbol. A numeral following letters constituting a reference symbol is used to distinguish between elements that have the same configuration that are referred to by reference symbols that have the same letters. If elements represented by reference symbols that have the same letters need not be distinguished, those elements are assigned reference symbols that have only the same letters.

### <1> Embodiment

Hereinafter, a semiconductor memory device 1 according to an embodiment will be described.

### <1-1> Overall Configuration of Semiconductor Memory Device

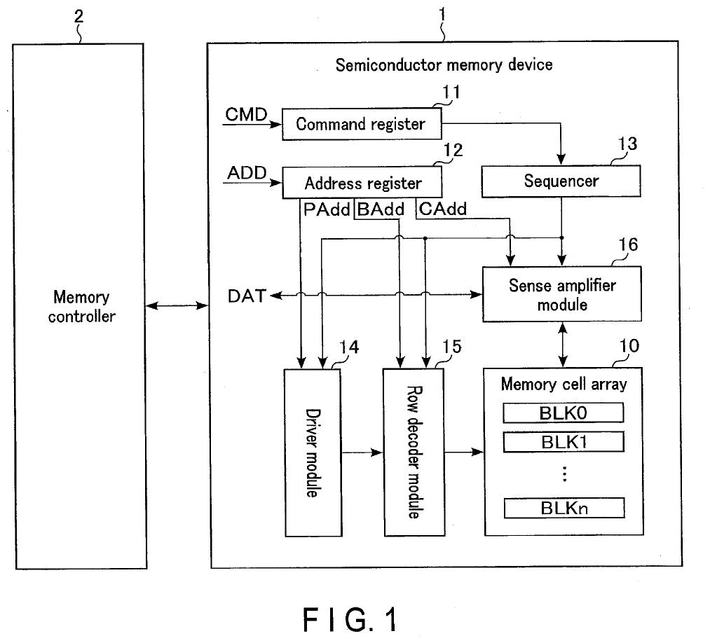

FIG. 1 shows a configuration example of the semiconductor memory device 1 according to the embodiment. The semiconductor memory device 1 is a NAND-type flash memory, which can non-volatilely store data, and is controlled by an external memory controller 2. Communication between the semiconductor memory device 1 and the memory controller 2 is based on, for example, a NAND interface standard.

As shown in FIG. 1, the semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer larger than or equal to 1). The block BLK is a set of a plurality of memory cells that can non-volatilely store data, and is used as, for example, a data erase unit. A plurality of bit lines and a plurality of word lines are provided in the memory cell array 10. Each memory cell is associated with, for example, one bit line and one word line. A detailed configuration of the memory cell array 10 will be described later.

The command register 11 holds a command CMD received by the semiconductor memory device 1 from the memory controller 2. The command CMD includes an order to cause the sequencer 13 to execute a read operation, a write operation, an erase operation, or the like.

The address register 12 holds address information ADD received by the semiconductor memory device 1 from the memory controller 2. The address information ADD includes, for example, a block address BAdd, a page address PAdd, and a column address CAdd. For example, the block address BAdd, the page address PAdd, and the column address CAdd are used to select a block BLK, a word line, and a bit line, respectively.

The sequencer 13 controls the overall operation of the semiconductor memory device 1. For example, the sequencer 13 controls the driver module 14, the row decoder module 15, the sense amplifier module 16, and the like based on the command. CMD held in the command register 11, to execute a read operation, a write operation, an erase operation, and the like.

The driver module 14 generates voltages used in a read operation, a write operation, an erase operation, and the like. Then, the driver module 14 applies a generated voltage to a signal line corresponding to a selected word line based on, for example, the page address PAdd held in the address register 12.

Based on the block address BAdd held in the address register 12, the row decoder module 15 selects one corresponding block BLK in the memory cell array 10. Then, the row decoder module 15 transfers, for example, the voltage applied to the signal line corresponding to the selected word line to the selected word line in the selected block BLK.

In a write operation, the sense amplifier module 16 applies a desired voltage to each bit line in accordance with write data DAT received from the memory controller 2. In a read operation, the sense amplifier module 16 determines data stored in a memory cell based on the voltage of the corresponding bit line, and transfers the determination result to the memory controller 2 as read data DAT.

The above-described semiconductor memory device 1 and memory controller 2 may constitute a single semiconductor device in combination. Examples of such a semiconductor memory device include a memory card such as an SD™ card, and a solid state drive (SSD).

### <1-2> Circuit Configuration of Memory Cell Array

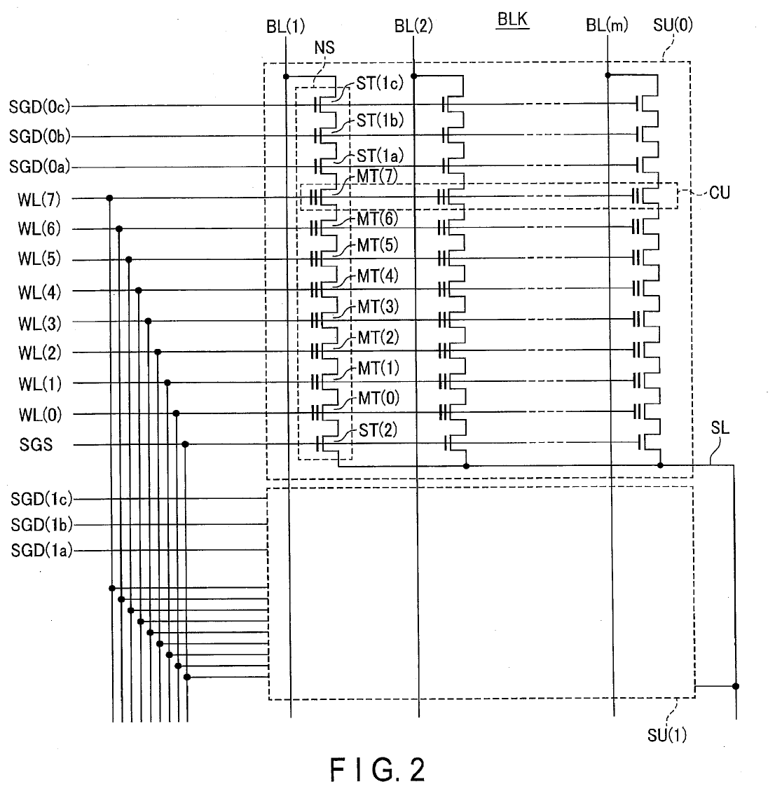

FIG. 2 shows an example of the circuit configuration of the memory cell array 10 included in the semiconductor memory device 1 according to the present embodiment. Specifically, FIG. 2 representatively shows string units SU(0) and SU(1) in one block BLK of a plurality of blocks BLK included in the memory cell array 10.

Each string unit SU includes a plurality of NAND strings NS associated with bit lines BL (0) to BL (m) (where m is an integer larger than or equal to 1), respectively. Each NAND string NS includes, for example, memory cell transistors MT(0) to MT(7) and select transistors ST(1a), ST(1b), ST(1c), and ST(2) Each memory cell transistor MT includes a control gate and a charge storage layer, and non-volatilely stores data. Each of the select transistors ST(1a), ST(1b), ST(1c), and ST(2) is used to select a string unit. SU in various operations.

In each NAND string NS, the select transistors ST(1a), ST(1b), and ST(1c) are coupled in series. In each NAND string NS, the memory cell transistors MT(0) to MT(7) are also coupled in series. One end of the select transistors ST(1a), ST(1b), and ST(1c) coupled in series is coupled to a corresponding bit line BL, and the other end thereof is coupled to one end of the memory cell transistors MT(0) to MT(7) coupled in series. One end of the select transistor ST(2) is coupled to the other end of the memory cell transistors MT(0) to MT(7) coupled in series, and the other end thereof is coupled to the source line SL.

The control gates of the memory cell transistors MT(0) to MT(7) in the same block BLK are coupled in common to the respective word lines WL(0) to WL(7). The gates of the select transistors ST(1a), ST(1b), and ST(1c) in the string unit SU(0) are coupled in common to respective select gate lines SGD(0a), SGD(0b), and SGD(0c). The gates of the select transistors ST(1a), ST(1b), and ST(1c) in the string unit SU(1) are coupled in common to respective select gate lines SGD(1a), SGD(1b), and SGD(1c). The gates of the select transistors ST(2) in the same block BLK are coupled in common to a select gate line SGS. When the select transistors ST(1a), ST(1b), and ST(1c) are not distinguished from one another, each will be merely referred to as a select transistor ST(1). When the select gate lines SGD(0a), SGD(0b), and SGD(0c) are not distinguished from one another, each will be referred to as a select gate line SGD.

Each bit line BL is shared among the NAND strings NS to which the same column address is assigned in the respective string units SU. The source line SL is shared among, for example, a plurality of blocks BLK.

A set of memory cell transistors MT coupled to a common word line WL in one string unit SU is referred to as, for example, a cell unit CU. For example, the storage capacity of the cell unit CU including memory cell transistors MT each configured to store 1-bit data is defined as “1-page data”. The cell unit CU may have a storage capacity of 2 or more-page data in accordance with the number of bits of data stored in each memory cell transistor MT.

The circuit configuration of the memory cell array 10 included in the semiconductor memory device 1 according to the embodiment is not limited to the above-described one. For example, the numbers of memory cell transistors MT, select transistors ST(1), and select transistors ST(2) in each NAND string NS may be any number. The number of string units SU included in each block BLK may be any number.

### <1-3> Configuration of Memory Cell Array

Hereinafter, an example of the configuration of the memory cell array 10 in the embodiment will be described.

In the drawings to be referred to below, “Y direction” corresponds to the direction in which the bit lines BL extend, “X direction” corresponds to the direction in which the word lines WL extend, and “Z direction” corresponds to the direction vertical to the surface of a semiconductor substrate 20 on which the semiconductor memory device 1 is formed. In the plan views, hatching is applied as appropriate, for improved visibility. The hatching applied in the plan views does not necessarily relate to the material or characteristics of the hatched constituent element. In the cross-sectional views, constituent elements such as insulating layers (interlayer insulating films), interconnects, contact plugs, and the like are omitted as appropriate, for improved visibility.

### <1-3-1> Planar Layout of Memory Cell Array

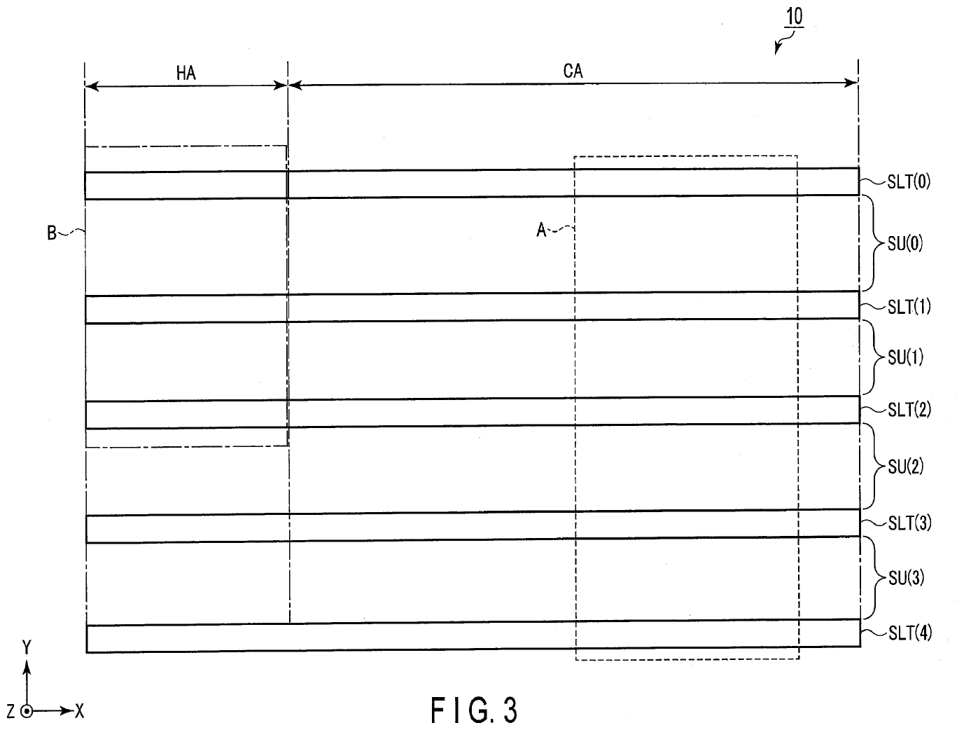

An example of the planar layout of the memory cell array 10 included in the semiconductor memory device 1 according to the embodiment will be described with reference to FIG. 3. FIG. 3 shows an example of the planar layout of the memory cell array 10 included in the semiconductor memory device 1 according to the embodiment, focusing on an area corresponding to the string units SU(0) to SU(3).

As shown in FIG. 3, the planar layout of the memory cell array 10 is divided in the X direction into a cell area CA and a hookup area HA. The memory cell array 10 includes a plurality of slits SLT(SLT(0) to SLT(4) in FIG. 3).

The cell area CA is an area in which NAND strings NS are formed.

The hookup area HA is an area in which contacts are formed to electrically connect the row decoder module 15 with the word lines WL and select gate lines SGS and SGD coupled to the NAND strings NS.

The slits SLT extend in the X direction, and are aligned in the Y direction. Each slit SLT crosses the hookup area HA and the cell area CA in the X direction.

Specifically, each slit SLT divides each of a plurality of interconnect layers corresponding to, for example, the word lines WL(0) to WL(7), select gate line SGD, and select gate line SGS.

The slit SLT has a structure obtained by embedding an insulating member in a trench PSLT. The slit SLT may have a structure obtained by embedding a conductor in a trench PSLT via an insulating member, and the conductor may be used as a contact plug for the source line SL.

In the above-described planar layout of the memory cell array 10, the areas obtained by dividing the cell area CA by the slits SLT correspond to string units SU, respectively. Namely, in this example, the string units SU(0) to SU(3), each extending in the X direction, are aligned in the Y direction. The pattern shown in FIG. 3 for example, is repeated in the Y direction in the memory cell array 10.

Specifically, a plurality of NAND strings NS provided in an area between the slit SLT(0) and the slit SLT(1) in the Y direction are referred to as the string unit SU(0). Further, a plurality of NAND strings NS provided in an area between the slit SLT(1) and the slit SLT(2) in the Y direction are referred to as the string unit SU(1). Similarly, a plurality of NAND strings NS provided in an area between the slit SLT(2) and the slit SLT(3) in the Y direction are referred to as the string unit SU(2). Moreover, a plurality of NAND strings NS provided in an area between the slit SLT(3) and the slit SLT(4) in the Y direction are referred to as the string unit SU(3).

### <1-3-2> Structure of Memory Cell Array in Cell Area

Next, a detailed planar layout in the cell area CA of the memory cell array 10 of the semiconductor memory device 1 according to the embodiment will be described.

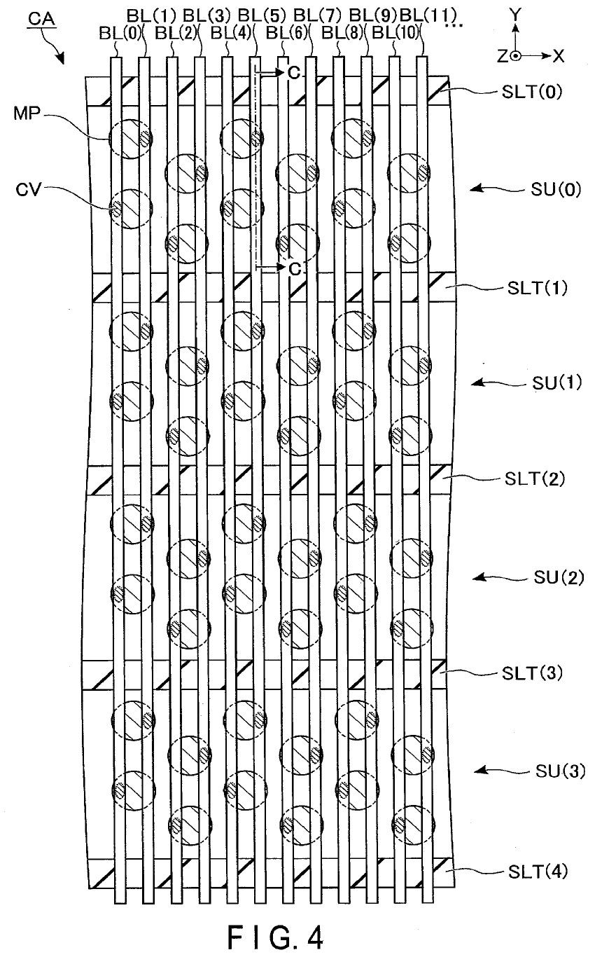

FIG. 4 shows an example of the detailed planar layout in the cell area CA of the memory cell array 10 of the semiconductor memory device 1 according to the embodiment, focusing on an area (area A in FIG. 3) corresponding to the string units SU(0) to SU(3). As shown in FIG. 4, in the cell area. CA, the memory cell array 10 further includes a plurality of memory pillars MP, a plurality of contact plugs CV, and a plurality of bit lines BL.

Each memory pillar MP functions as, for example, one NAND string NS. The memory pillars MP are disposed in four rows in a staggered configuration, for example in an area between the adjacent slits SLT(0) and SLT(1).

The bit lines BL extend in the Y direction, and are aligned in the X direction. Each bit line BL is disposed to overlap at least one memory pillar MP in each string unit SU. In this example, two bit lines BL overlap each memory pillar MP. A contact plug CV is provided between a memory pillar MP and one of the bit lines BL overlapping the memory pillar MP. Each memory pillar MP is electrically coupled to the corresponding bit line BL via a contact plug CV.

### <1-3-3> Cross-Sectional Structure of Memory Cell Array in Cell Area

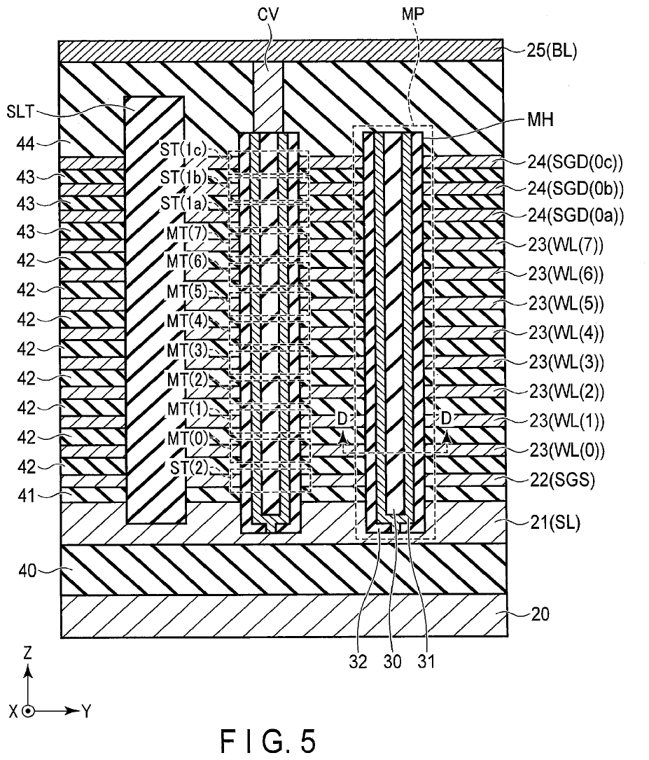

Next, an example of the cross-sectional structure in the cell area CA of the memory cell array 10 included in the semiconductor memory device 1 according to the embodiment will be described with reference to FIG. 5.

FIG. 5 is a cross-sectional view taken along line C-C in FIG. 4, which shows an example of the cross-sectional structure in the cell area CA of the memory cell array 10 included in the semiconductor memory device 1 according to the embodiment. As shown in FIG. 5, the memory cell array 10 further includes conductive layers 21 to 25. The conductive layers 21 to 25 are provided above the semiconductor substrate 20 in the Z direction.

Specifically, the conductive layer 21 is provided above the semiconductor substrate 20 in the Z direction with an insulating layer 40 interposed therebetween. Circuits corresponding to the row decoder module 15, the sense amplifier module 16, and the like may be provided in the insulating layer 40 between the semiconductor substrate 20 and the conductive layer 21, although they are omitted in the figure. The conductive layer 21 has a plate-like shape expanding along the X-Y plane for example, and is used as the source line SL. The conductive layer 21 includes, for example, silicon (Si).

The conductive layer 22 is provided above the conductive layer 21 in the Z direction with an insulating layer 41 interposed therebetween. The conductive layer 22 has a plate-like shape expanding along the X-Y plane for example, and is used as the select gate line SGS. The conductive layer 22 includes, for example, silicon.

Insulating layers 42 and the conductive layers 23 are alternately stacked above the conductive layer 22 in the Z direction. Namely, multiple sets of the insulating layer 42 and the conductive layer 23 are stacked. The conductive layer 23 has a plate-like shape expanding along the X-Y plane for example. The stacked conductive layers 23 correspond to the word lines WL(0) to WL(7) in order from the semiconductor substrate 20 side, for example. The conductive layer 23 includes, for example, tungsten (W).

Insulating layers 43 and the conductive layers 24 are alternately stacked above the topmost conductive layer 23 in the Z direction. Namely, multiple sets of the insulating layer 43 and the conductive layer 24 are stacked. The conductive layer 24 has a plate-like shape expanding along the X-Y plane for example. The stacked conductive layers 24 correspond to the select gate lines SGD, for example. The conductive layer 24 includes, for example, tungsten (W). The structure constituted by the conductive layers 21 to 24 and insulating layers 41 to 43 may be referred to as a laminated body or laminated structure.

The conductive layer 25 is provided above the topmost conductive layer 24 in the Z direction with an insulating layer 44 interposed therebetween. The conductive layer 25 has a linear shape extending in the Y direction for example, and is used as the bit line EL. The conductive layer 25 includes, for example, copper (Cu).

Each memory pillar MP extends in the Z direction, and passes through the conductive layers 22 to 24 and insulating layers 41 to 43. Each memory pillar MP is formed inside a memory hole MH.

The memory hole MH passes through the conductive layers 22 to 24 and insulating layers 41 to 43 so that the bottom thereof is in contact with the conductive layer 21.

Each memory pillar MP includes a core member 30, a semiconductor layer 31, and a laminated film 32.

Specifically, the core member 30 extends in the Z direction. For example, the top end of the core member 30 is included in a layer above the topmost conductive layer 24, and the bottom end of the core member 30 is included in a layer in which the conductive layer 21 is provided. The semiconductor layer 31 includes, for example, a portion covering the side and bottom surfaces of the core member 30, and a columnar portion extending in the Z direction at the bottom of the core member 30. For example, the bottom of the columnar portion of the semiconductor layer 31 is included in a layer in which the conductive layer 21 is provided. The laminated film 32 covers the side and bottom surfaces of the semiconductor layer 31 excluding the part where the columnar portion of the semiconductor layer 31 is provided. For example, the bottom of the laminated film 32 is included in a layer in which the conductive layer 21 is provided. The core member 30 includes, for example, an insulator such as silicon oxide (SiO₂). The semiconductor layer 31 includes, for example, silicon.

A columnar contact plug CV is provided on the top surface of the semiconductor layer 31 in the memory pillar MP. In the figure, a contact plug CV corresponding to one of the two memory pillars MP is shown.

The top surface of the contact plug CV is in contact with one conductive layer 25, i.e., one bit line BL. In one string unit SU, one contact plug CV is coupled to one conductive layer 25.

The slit SLT has a plate-like shape expanding on the X-Z plane for example, and divides each of the conductive layers 22 to 24. The top end of the slit SLT is included in a layer between the topmost conductive layer 24 and the conductive layer 25. The bottom end of the slit SLT is included in, for example, a layer in which the conductive layer 21 is provided. The slit SLT includes, for example, an insulator such as silicon oxide.

### <1-3-4> Cross-Sectional Structure of Memory Pillar of Memory Cell Array

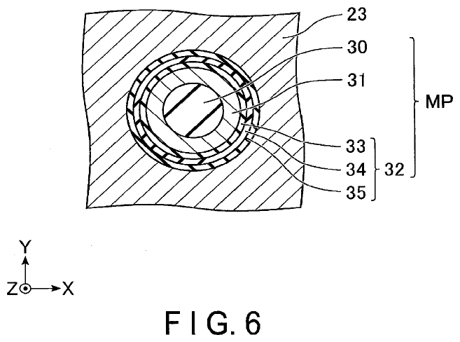

FIG. 6 is a cross-sectional view taken along line D-D in FIG. 5, which shows an example of the cross-sectional structure of the memory pillar MP in the semiconductor memory device 1 according to the embodiment. Specifically, FIG. 6 shows a cross-sectional structure of the memory pillar MP in a layer parallel to the surface of the semiconductor substrate 20 and including the conductive layer 23.

As shown in FIG. 6, in the layer including the conductive layer 23, the core member 30 is provided, for example, at the center of the memory pillar MP. The semiconductor layer 31 surrounds the side surface of the core member 30. The laminated film 32 surrounds the side surface of the semiconductor layer 31. The laminated film 32 includes, for example, a tunnel insulating film 33, an insulating film 34, and a block insulating film 35.

The tunnel insulating film 33 surrounds the side surface of the semiconductor layer 31. The insulating film 34 surrounds the side surface of the tunnel insulating film 33. The block insulating film 35 surrounds the side surface of the insulating film 34. The conductive layer 23 surrounds the side surface of the block insulating film 35. The tunnel insulating film 33 and block insulating film 35 each include, for example, silicon oxide. The insulating film 34 includes, for example, silicon nitride (SiN).

In the above-described structure of the memory pillar MP, the portion where the memory pillar MP intersects the conductive layer 22 functions as the select transistor ST(2). The portion where the memory pillar MP intersects the conductive layer 23 functions as the memory cell transistor MT. The portion where the memory pillar MP intersects the conductive layer 24 functions as the select transistor ST(1).

Namely, the semiconductor layer 31 is used as the channel of each of the memory cell transistors MT(0) to MT(7) and select transistors ST(1) and ST(2). The insulating film 34 is used as the charge storage layer of the memory cell transistor MT. Accordingly, each memory pillar MP functions as one NAND string NS.

### <1-3-5> Hookup Area of Memory Cell Array

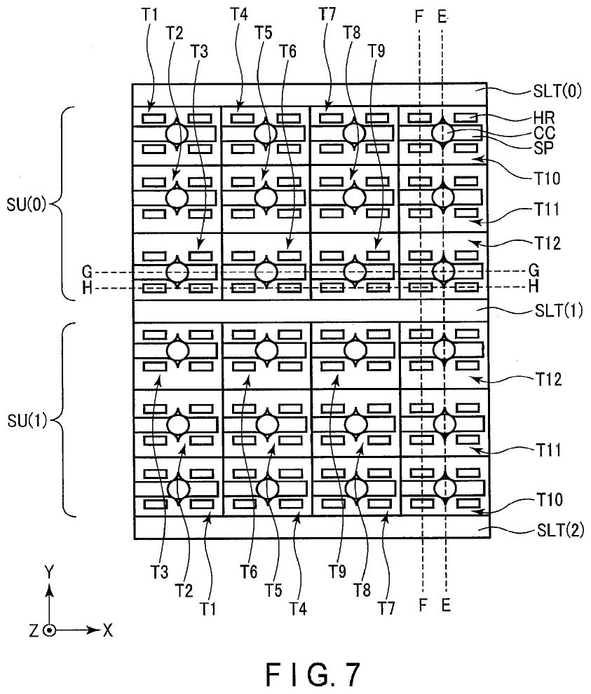

FIG. 7 shows an example of the detailed planar layout in the hookup area HA (area B in FIG. 3) of the memory cell array 10 of the semiconductor memory device 1 according to the embodiment, focusing on an area corresponding to two string units SU. In FIG. 7, the insulating layers 44 are omitted.

As shown in FIG. 7, the memory cell array 10 has a staircase structure in the hookup area HA. The staircase structure is a structure including a plurality of steps parallel to the X-Y plane (hereinafter also referred to as, for example, terraces, terrace portions, steps, or step portions), in which the steps are at different levels in the Z direction.

The ends of the conductive layers corresponding to the select gate line SGS, word lines WL(0) to WL(7), and select gate line SGD are drawn out from the cell area CA to the hookup area HA. The conductive layers corresponding to the select gate line SGS, word lines WL(0) to WL(7), and select gate line SGD each have a terrace that does not overlap the upper conductive layers in the Z direction.

For example, FIG. 7 shows terraces T1 to T12 in each of the area relating to the string unit SU(0) and the area relating to the string unit SU(1). Since the structure in the area relating to the string unit SU(0) is the same as that in the area relating to the string unit SU(1), descriptions will be provided without making a distinction between the areas. When the terraces T1 to T12 are not distinguished from one another, each will be merely referred to as a “terrace T”.

As shown in FIG. 7, a contact plug CC is disposed at approximately the center of each terrace T. A stopper region SP is disposed to surround the contact plug CC. The stopper region SP will be described later. In addition, a plurality of support pillars HR (four in FIG. 7) are disposed around the contact plug CC and stopper region SP. These support pillars HR will be described later.

The terraces T are provided to form steps. Details will be described below.

The terraces T12, T11, and T10 form steps aligned in the Y direction. The terraces T9, T8, and T7 form steps aligned in the Y direction. The terraces T6, T5, and T4 form steps aligned in the Y direction. The terraces T3, T2, and T1 form steps aligned in the Y direction.

The terraces T12, T9, T6, and T3 form steps aligned in the X direction. The terraces T11, T8, T5, and T2 form steps aligned in the X direction. The terraces T10, T7, T4, and T1 form steps aligned in the X direction.

The terrace T1 corresponds to the select gate line SGS. The terraces T2 to T9 correspond to the word lines WL(0) to WL(7), respectively. The terraces T10 to T12 correspond to the select gate lines SGD, respectively.

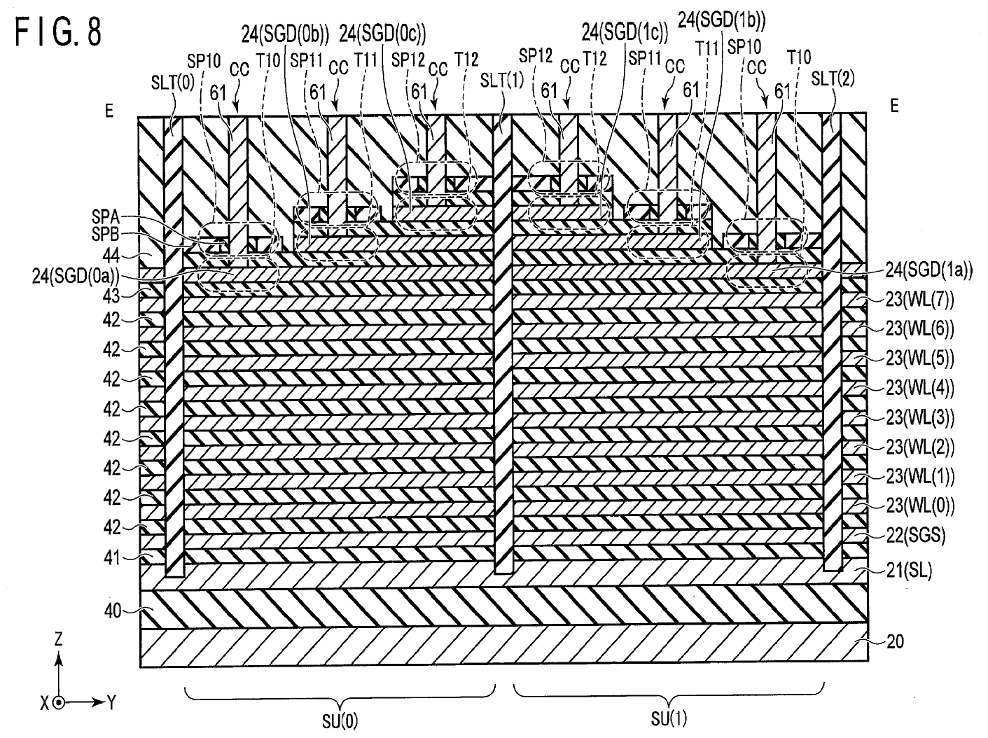

FIG. 8 is a cross-sectional view taken along line E-E in FIG. 7. Specifically, FIG. 8 shows an example of the cross-sectional structure in the hookup area HA of the memory cell array 10 included in the semiconductor memory device 1 according to the embodiment. Shown in FIG. 8 is a cross section relating to the terraces T12, T11, and T10 of the string unit SU(0) and the terraces T12, T11, and T10 of the string unit SU(1).

As shown in FIG. 8, the terraces T of the conductive layer 24 corresponding to the select gate line SGD(0c), the conductive layer 24 corresponding to the select gate line SGD(0b), and the conductive layer 24 corresponding to the select gate line SGD(0a) are aligned in the Y direction in descending order of level in the Z direction. Namely, the terrace T is provided for each conductive layer with respect to the Y direction.

As shown in FIG. 8, the stopper region SP is provided above each terrace T in the Z direction. The stopper region SP is used when a hole that connects the terrace T to a contact plug CC is formed. The contact plug CC is formed by embedding a conductive layer 61 in the hole. Advantageous effects of the stopper region SP will be described in detail later. The stopper region SP includes a region SPA in contact with the side surface of the contact plug CC and a region SPB surrounding the region SPA on the X-Y plane. The regions SPA and SPB include different materials. In particular, the region SPA may be made of any material having an etching rate different from the etching rates of the region SPB and insulating layers 41 to 44.

Specifically, as shown in FIG. 8, a stopper region SP12 is provided above the terrace T12 in the Z direction with the insulating layer 43 interposed therebetween. A contact plug CC passes through the stopper region SP12 and the insulating layer 43 in the Z direction, and is coupled to the terrace T12. A stopper region SP11 is provided above the terrace T11 in the Z direction with the insulating layer 43 interposed therebetween. A contact plug CC passes through the stopper region SP11 and the insulating layer 43, and is coupled to the terrace T11. A stopper region SP10 is provided above the terrace T10 in the Z direction with the insulating layer 43 interposed therebetween. A contact plug CC passes through the stopper region SP10 and the insulating layer 43 in the Z direction, and is coupled to the terrace T10.

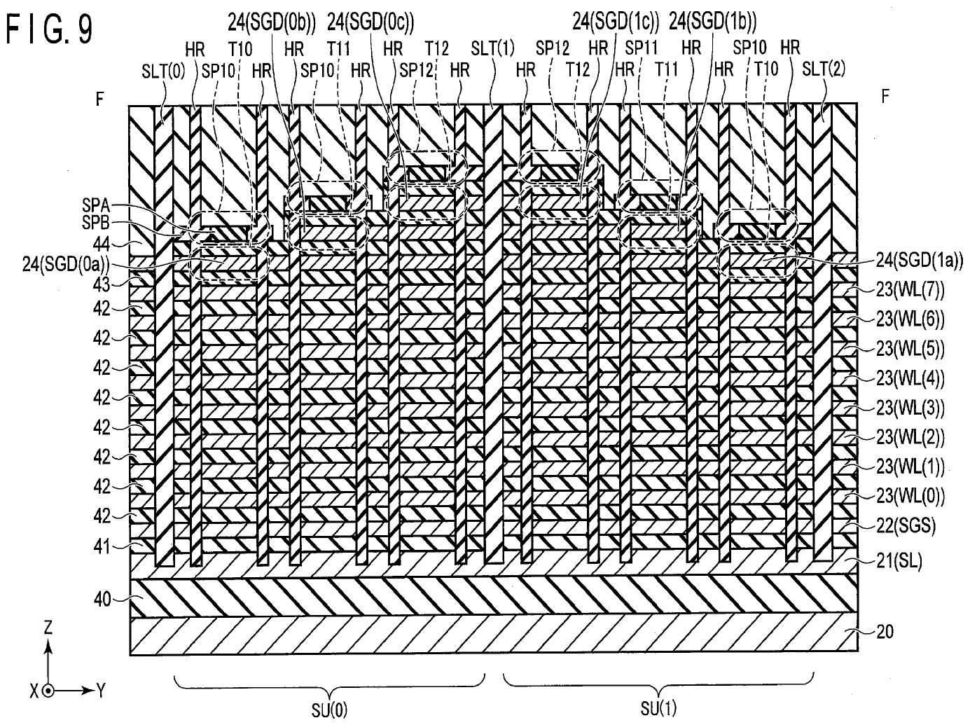

FIG. 9 is a cross-sectional view taken along line F-F of FIG. 7. Specifically, FIG. 9 shows an example of the cross-sectional structure in the hookup area HA of the memory cell array 10 included in the semiconductor memory device 1 according to the embodiment. Shown in FIG. 9 is a cross section relating to the terraces T12, T11, and T10 of the string unit SU(0) and the terraces T12, T11, and T10 of the string unit SU(1). FIG. 9 shows a cross section relating to the support pillars HR, although FIG. 8 shows a cross section relating to the contact plugs CC.

As shown in FIG. 9, the support pillar HR has a structure obtained by embedding an insulating member in a hole extending in the Z direction, and passes through the stacked interconnect layers (such as the select gate lines SGD, word lines WL, and select gate line SGS).

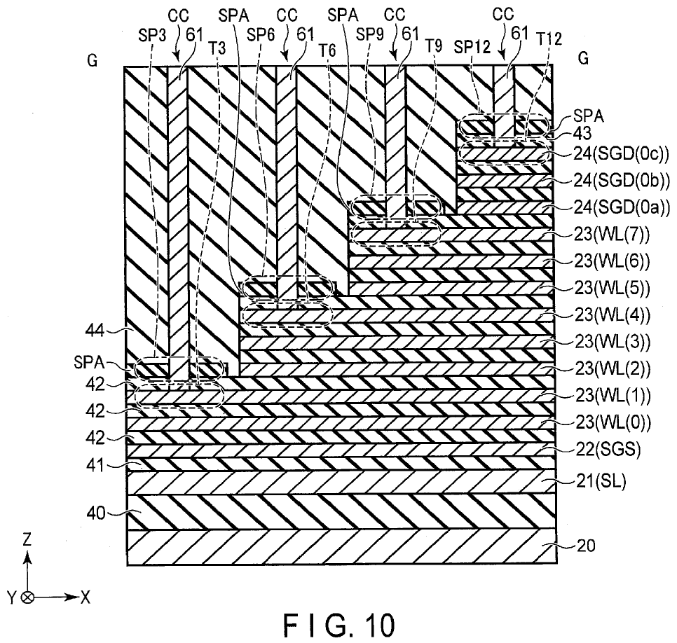

FIG. 10 is a cross-sectional view taken along line G-G of FIG. 7. Specifically, FIG. 10 shows an example of the cross-sectional structure in the hookup area HA of the memory cell array 10 included in the semiconductor memory device 1 according to the embodiment. Shown in FIG. 10 is a cross section relating to the terraces T12, T9, T6, and T3 of the string unit SU(0).

As shown in FIG. 10, the terraces T of the conductive layer 24 corresponding to the select gate line SGD(0c), the conductive layer 23 corresponding to the word line WL(7), the conductive layer 23 corresponding to the word line WL(4), and the conductive layer 23 corresponding to the word line WL(1) are aligned in the X direction in descending order of level in the Z direction. Namely, the terrace T is provided for every three conductive layers with respect to the X direction.

The stopper region SP12 is provided above the terrace T12 in the Z direction with the insulating layer 43 interposed therebetween. A contact plug CC passes through the stopper region SP12 and the insulating layer 43 in the Z direction, and is coupled to the terrace T12. A stopper region SP9 is provided above the terrace T9 in the Z direction with the insulating layer 43 interposed therebetween. A contact plug CC passes through the stopper region SP9 and the insulating layer 43 in the Z direction, and is coupled to the terrace T9. A stopper region SP6 is provided above the terrace T6 in the Z direction with the insulating layer 42 interposed therebetween. A contact plug CC passes through the stopper region SP6 and the insulating layer 42 in the Z direction, and is coupled to the terrace T6. A stopper region SP3 is provided above the terrace T3 in the Z direction with the insulating layer 42 interposed therebetween. A contact plug CC passes through the stopper region SP3 and the insulating layer 42 in the Z direction, and is coupled to the terrace T3.

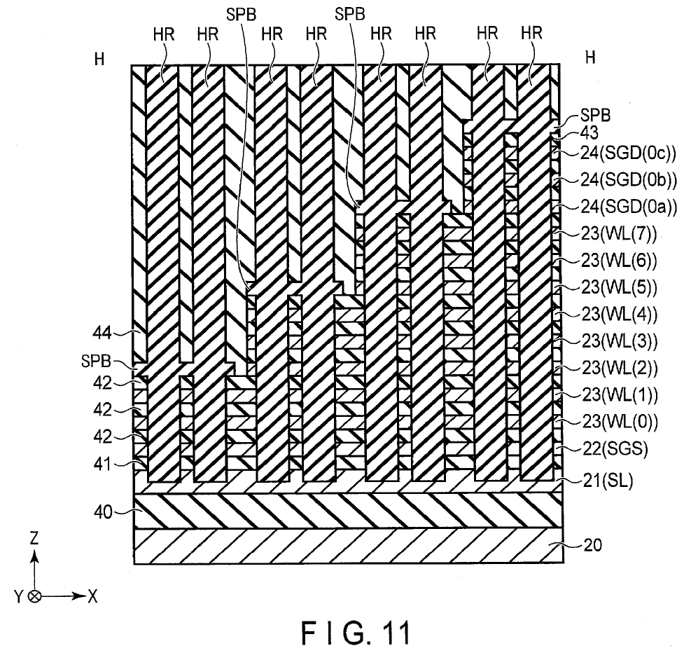

FIG. 11 is a cross-sectional view taken along line H-H of FIG. 7. Specifically, FIG. 11 shows an example of the cross-sectional structure in the hookup area HA of the memory cell array 10 in the semiconductor memory device 1 according to the embodiment. Shown in FIG. 11 is a cross section relating to the terraces T12, T9, T6, and T3 relating to the string unit SU(0). FIG. 11 shows a cross section relating to the support pillars HR, although FIG. 10 shows a cross section relating to the contact plugs CC.

As shown in FIG. 11, the support pillar HR has a structure obtained by embedding an insulating member in a hole extending in the Z direction, and passes through the stacked interconnect layers (such as the select gate lines SGD, word lines WL, and select gate line SGS).

The above-described staircase structure in the hookup area HA is merely an example, and the structure is not limited to the above-described one.

### <1-4> Method for Manufacturing Semiconductor Memory Device

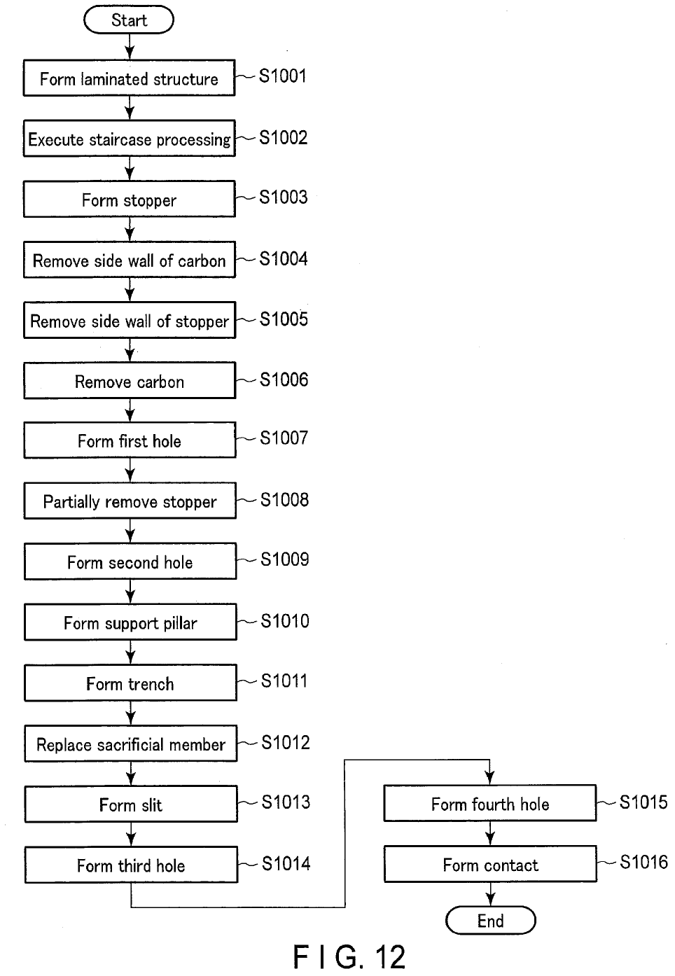

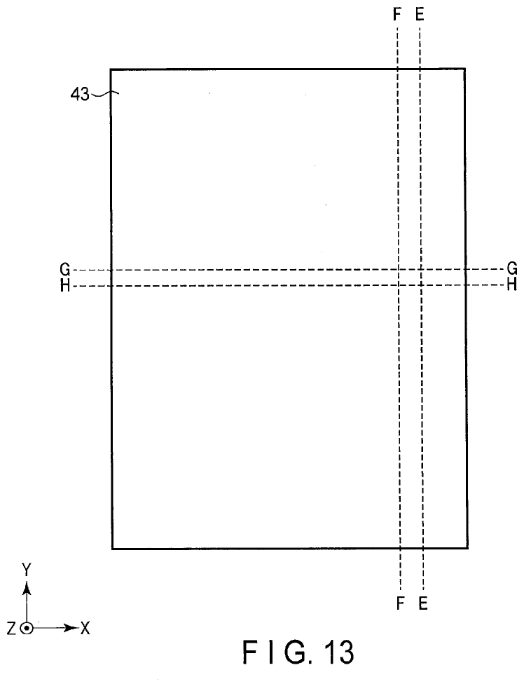

Hereinafter, an example of the series of manufacturing steps relating to the hookup area in the semiconductor memory device 1 according to the embodiment will be described with reference to FIG. 12 as appropriate. FIG. 12 is a flowchart showing an example of the method for manufacturing the semiconductor memory device 1 according to the embodiment. FIGS. 13 to 60 show cross-sectional structures respectively including structures corresponding to the memory cell array 10 in the respective manufacturing steps of the semiconductor memory device 1 according to the embodiment. For simplification, descriptions of the steps for manufacturing the cell area. CA are omitted herein. The plan view of each manufacturing step to be referred to below shows the area corresponding to FIG. 7.

[S1001]

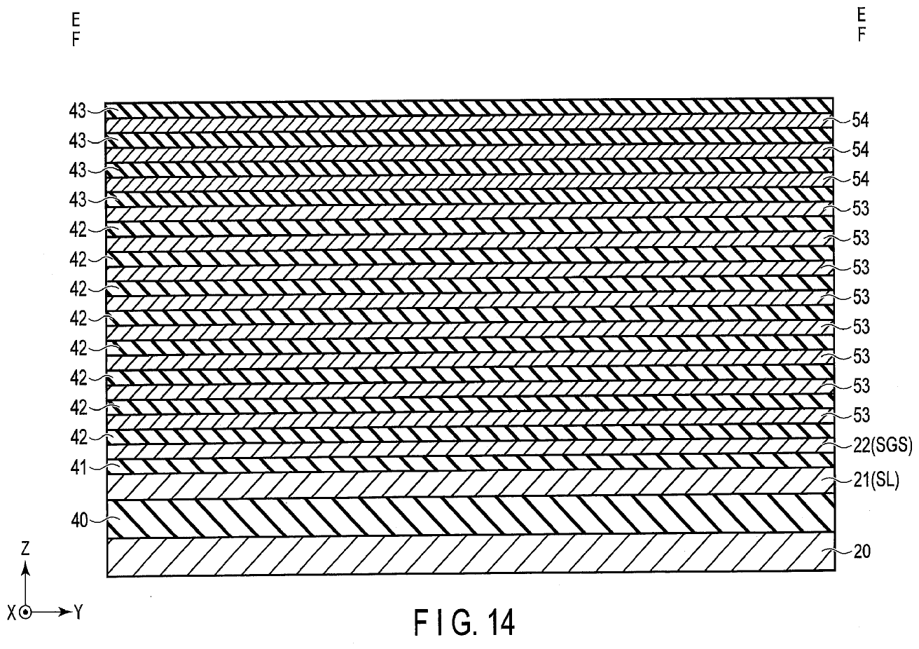

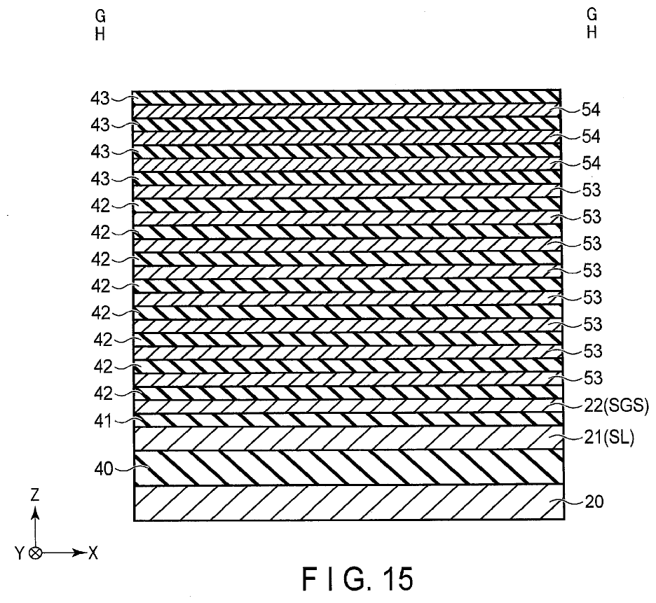

Step S1001 will be described with reference to FIGS. 13 to 15. FIG. 13 shows the area corresponding to FIG. 7. Shown in FIG. 13 is the topmost insulating layer 43 in the Z direction. FIG. 14 is a cross-sectional view showing a cross section taken along line E-E in FIG. 13 and a cross section taken along line F-F in FIG. 13. FIG. 15 is a cross-sectional view showing a cross section taken along line G-G in FIG. 13 and a cross section taken along line H-H in FIG. 13.

A laminated structure is formed on the semiconductor substrate 20 in step S1001. Specifically, as shown in FIGS. 13 to 15, the insulating layer 40 and the conductive layer 21 are sequentially stacked on the semiconductor substrate 20. A circuit corresponding to the sense amplifier module 16 or the like is formed in the insulating layer 40, although this is omitted in the figures. Then, the insulating layer 41 and conductive layer 22 are stacked on the conductive layer 21. After that, the insulating layers 42 and a sacrificial members 53 are alternately stacked on the conductive layer 22. The insulating layers 43 and a sacrificial members 54 are then alternately stacked on the topmost sacrificial member 53.

The conductive layer 21 is used as the source line SL. The conductive layer 21 includes, for example, silicon (Si). The conductive layer 22 is used as the select gate line SGS. The conductive layer 22 includes, for example, silicon (Si). The insulating layers 41 to 43 each include, for example, silicon oxide (SiO₂). For example, the number of layers of sacrificial members 53 corresponds to the number of layers of the word lines WL through which the memory hole MH passes. The sacrificial members 53 include, for example, silicon nitride (SiN). For example, the number of layers of sacrificial members 54 corresponds to the number of layers of the select gate lines SOD through which the memory hole MH passes. The sacrificial members 54 include, for example, silicon nitride (SiN).

[S1002]

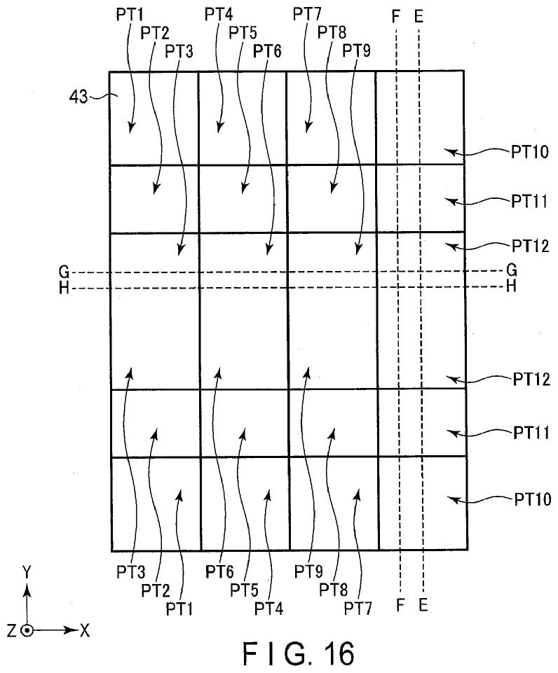

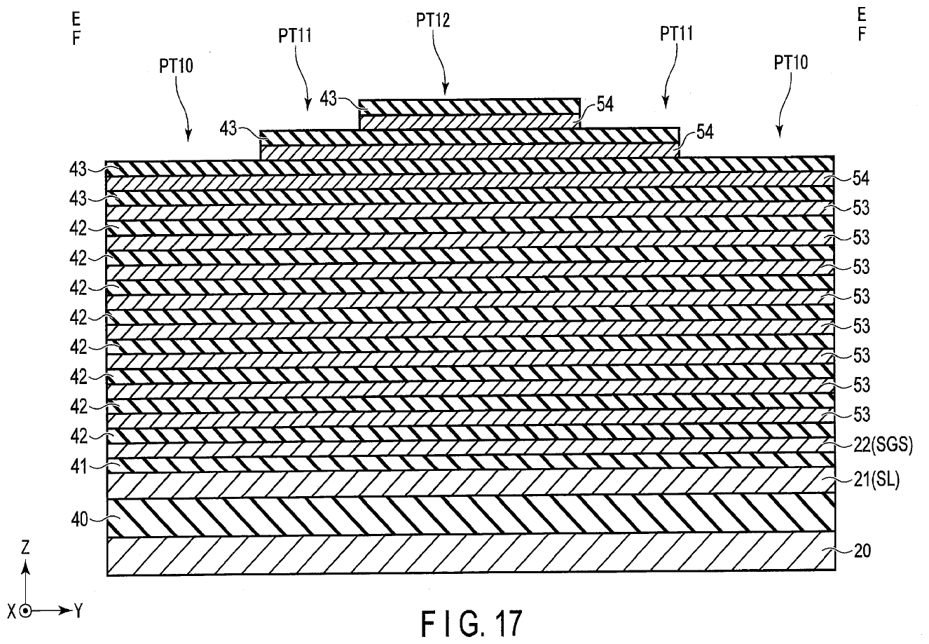

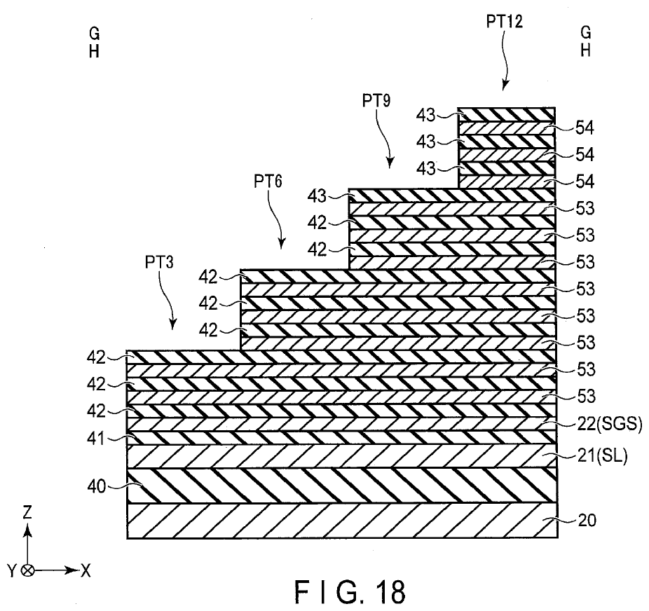

Step S1002 will be described with reference to FIGS. 16 to 18. FIG. 16 shows the area corresponding to FIG. 7. Shown in FIG. 16 is an area (step) corresponding to the terraces T and stopper regions to be formed later. FIG. 17 is a cross-sectional view showing a cross section taken along line E-E in FIG. 16 and a cross section taken along line F-F in FIG. 16. FIG. 18 is a cross-sectional view showing a cross section taken along line G-G in FIG. 16 and a cross section taken along line H-H in FIG. 16.

Staircase processing is executed on the laminated structure in step S1002. Specifically, as shown in FIGS. 16 to 18, a mask (not shown) is provided on the top surface of the insulating layer 43 over the entire hookup area HA. After a pattern is formed on the mask by photolithography, anisotropic etching on the laminated structure based on the obtained pattern and partial removal of the pattern of the mask by slimming thereof are sequentially repeated. The mask used in this step is removed after completion of the staircase processing on the lower layer. The anisotropic etching in this step is, for example, reactive ion etching (RIE).

In FIGS. 16 to 18, the area corresponding to the terrace T1 to be formed later is referred to as a “step PT1”. Similarly, the areas corresponding to the terraces T2 to T12 are referred to as “steps PT2 to PT12”, respectively. When the steps PT1 to PT12 are not distinguished from one another, each will be merely referred to as a “step PT”. The steps PT are provided in accordance with the number of the terraces T.

[S1003]

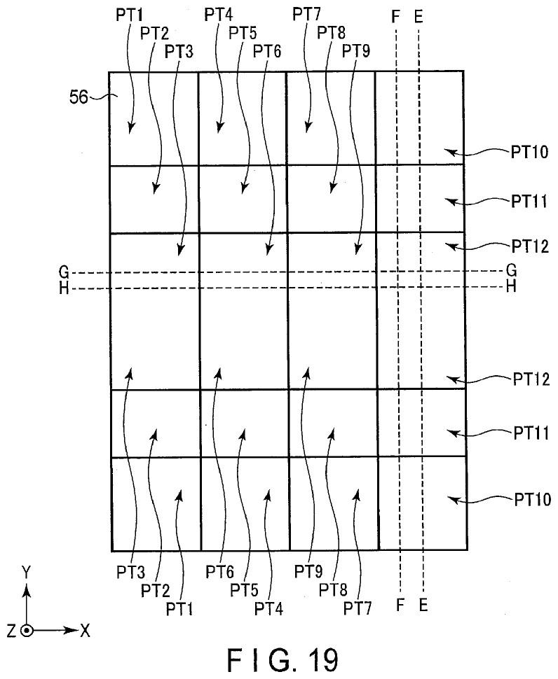

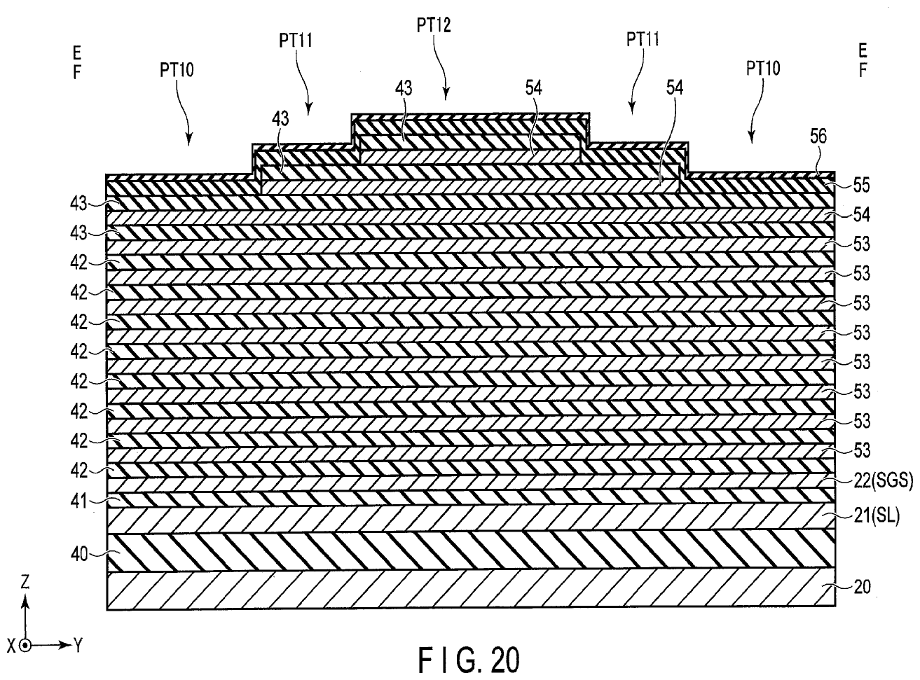

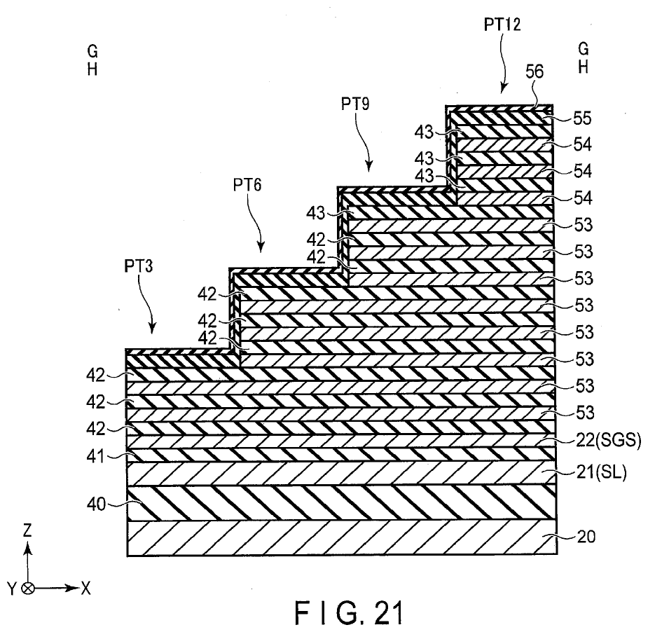

Step S1003 will be described with reference to FIGS. 19 to 21. FIG. 19 shows the area corresponding to FIG. 7. Shown in FIG. 19 is a member for processing 56. FIG. 20 is a cross-sectional view showing a cross section taken along line E-E in FIG. 19 and a cross section taken along line F-F in FIG. 19. FIG. 21 is a cross-sectional view showing a cross section taken along line G-G in FIG. 19 and a cross section taken along line H-H in FIG. 19.

A stopper is formed on the steps PT in step S1003. Specifically, as shown in FIGS. 19 to 21, a stopper 55 and the member for processing 56 are formed on the steps PT and on the side walls of the laminated body between the steps PT. The stopper 55 is, for example, polysilicon, a metal, or an insulator (such as silicon nitride (SiN)) that can secure a selection ratio with the member for processing 56 upon etching. Namely, the stopper 55 is different in etching rate from the member for processing 56. The member for processing 56 is a material with poor step coverage, which makes the thickness of the portion in contact with the stopper 55 formed on the side walls of the laminated body between the steps PT smaller than the thickness of the portion formed on the steps PT with the stopper 55 interposed therebetween. Specifically, the member for processing 56 is, for example, carbon (C).

[S1004]

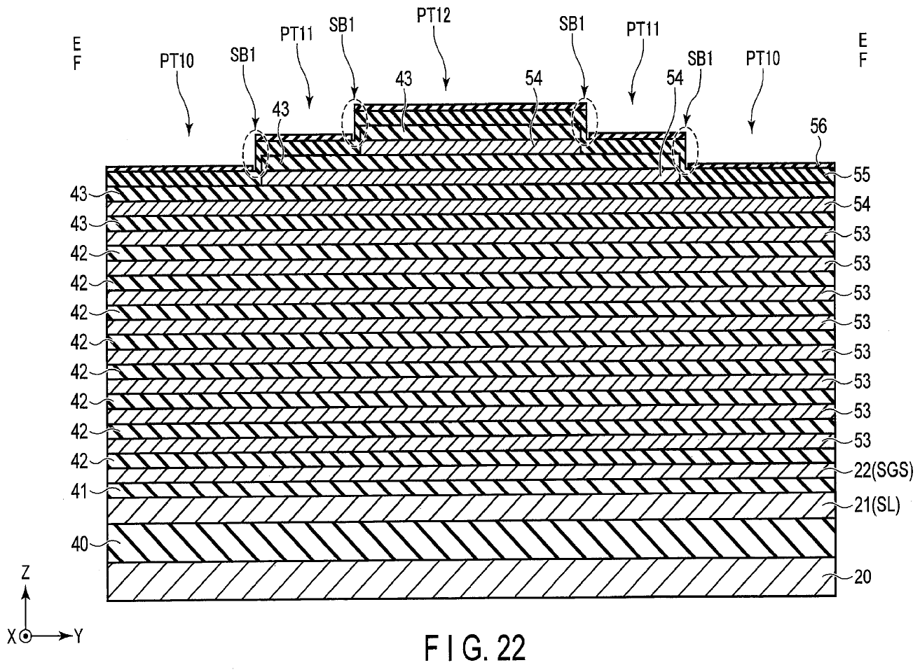

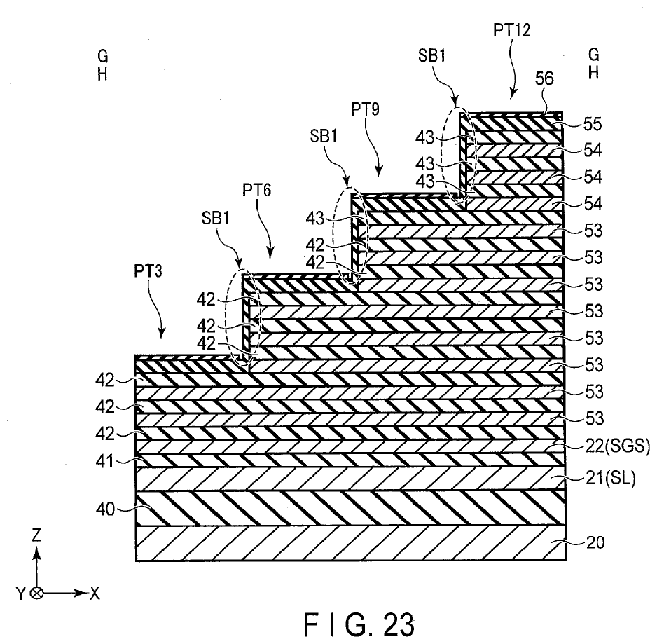

Step S1004 will be described with reference to FIGS. 22 and 23. FIG. 22 is a cross-sectional view showing a cross section taken along line E-E in FIG. 19 and a cross section taken along line F-F in FIG. 19. FIG. 23 is a cross-sectional view showing a cross section taken along line G-G in FIG. 19 and a cross section taken along line H-H in FIG. 19.

Part of the member for processing 56 is removed in step S1004. Specifically, as shown in FIGS. 22 and 23, the member for processing 56 in contact with the stopper 55 formed on the side walls of the laminated body between the steps PT is selectively removed by, for example, ashing (see SBI in the figures).

The stopper 55 formed on the side walls of the laminated body between the steps PT is thereby exposed.

[S1005]

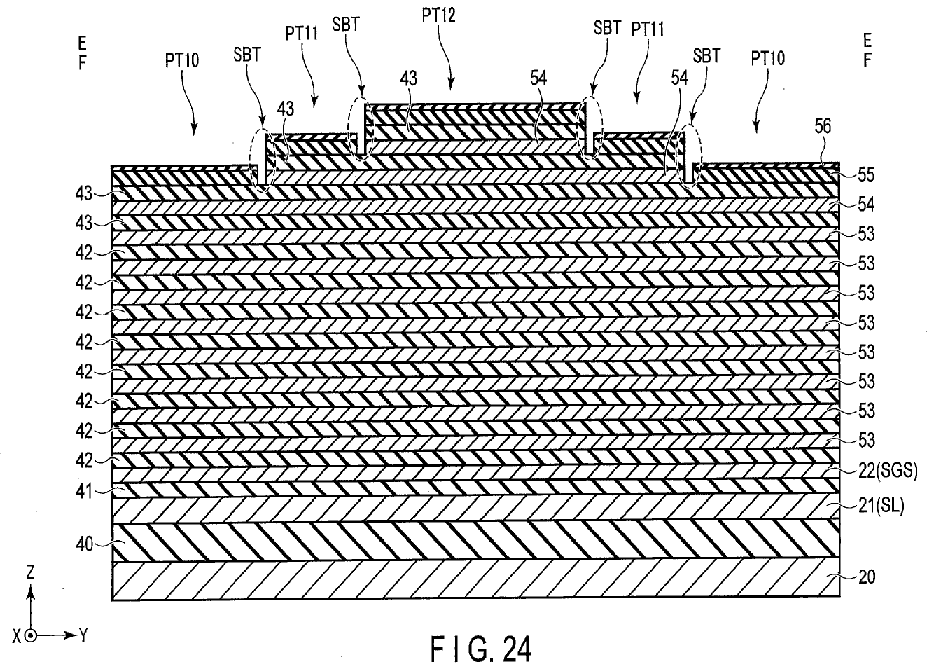

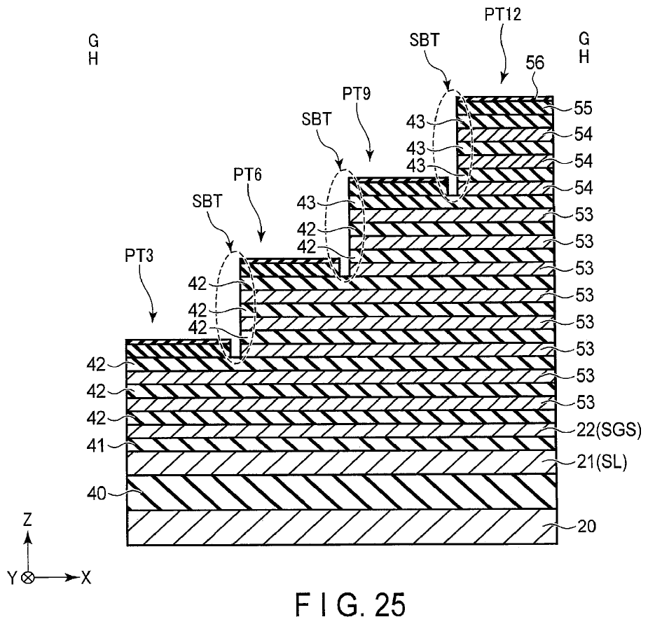

Step S1005 will be described with reference to FIGS. 24 and 25. FIG. 24 is a cross-sectional view showing a cross section taken along line E-E in FIG. 19 and a cross section taken along line F-F in FIG. 19. FIG. 25 is a cross-sectional view showing a cross section taken along line G-G in FIG. 19 and a cross section taken along line H-H in FIG. 19.

Part of the stopper 55 is removed in step S1005. Specifically, as shown in FIGS. 24 and 25, the stopper 55 formed on the side walls of the laminated body between the steps PT is selectively removed by, for example, nitric acid (HNO3) processing (see SBT in the figures). Namely, on the top surfaces of the steps PT, the stoppers 55 are formed in the regions separated from the side walls of the laminated body between the steps PT. In other words, sub-trenches SBT are formed between the stoppers 55 and the respective side walls of the laminated body between the steps PT. In the sub-trenches SBT, the insulating layer 43 or 42 is exposed.

[S1006]

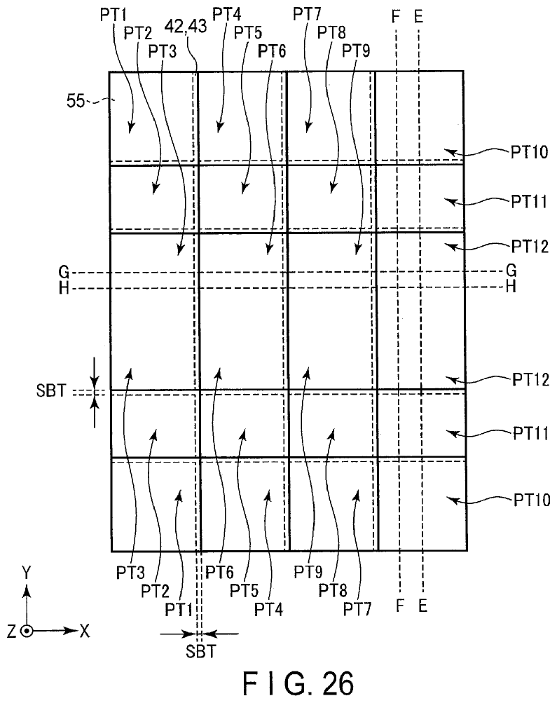

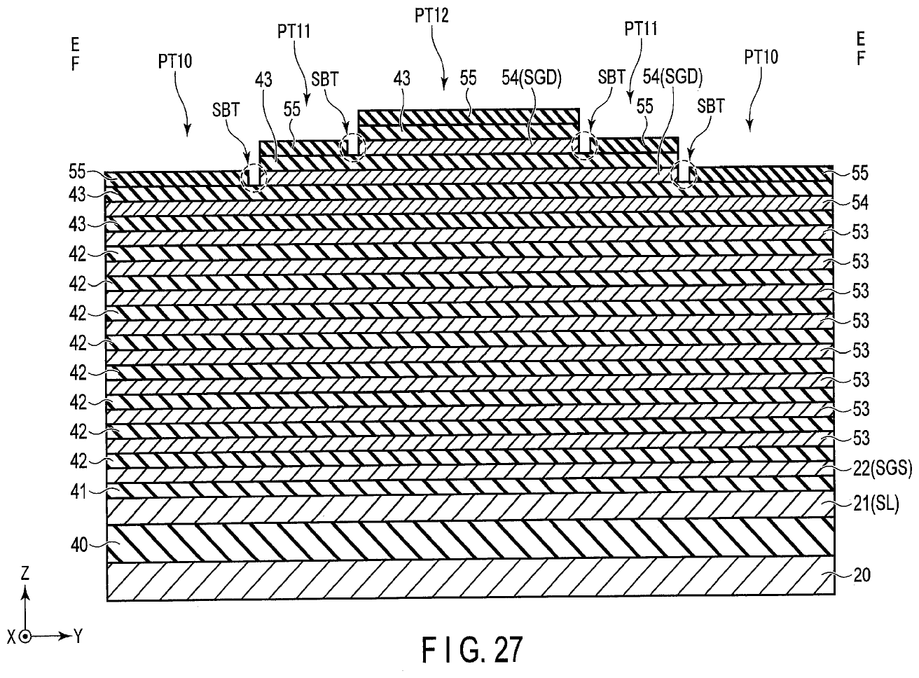

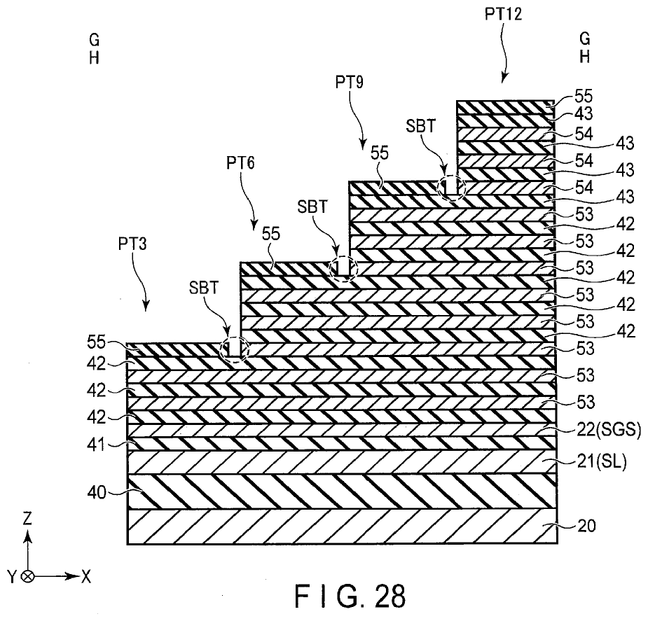

Step S1006 will be described with reference to FIGS. 26 to 28. FIG. 26 shows the area corresponding to FIG. 7. Shown in FIG. 26 are the stoppers 55 (indicated by broken lines) and the insulating layer 43 or 42 (indicated by solid lines). In FIG. 26, the areas between the broken lines and solid lines are the sub-trenches SBT. FIG. 27 is a cross-sectional view showing a cross section taken along line E-E in FIG. 26 and a cross section taken along line F-F in FIG. 26. FIG. 28 is a cross-sectional view showing a cross section taken along line G-G in FIG. 26 and a cross section taken along line H-H in FIG. 26.

The members for processing 56 formed on the steps PT via the stoppers 55 are removed in step S1006. Specifically, as shown in FIGS. 26 to 28, the members for processing 56 are removed by, for example, ashing.

[S1007]

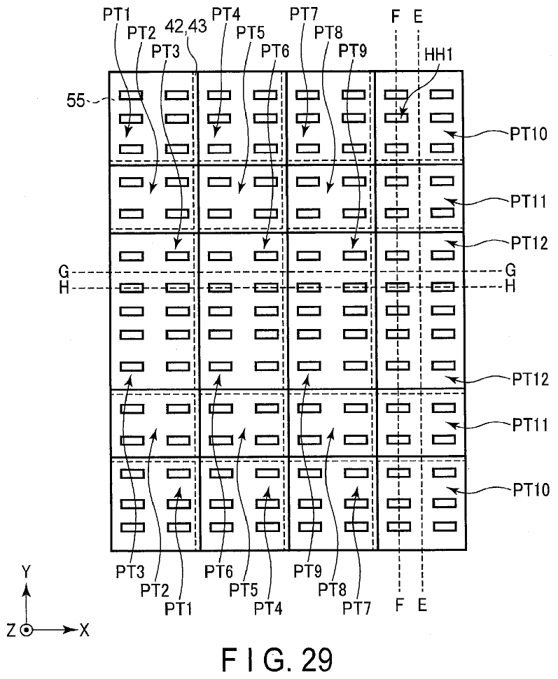

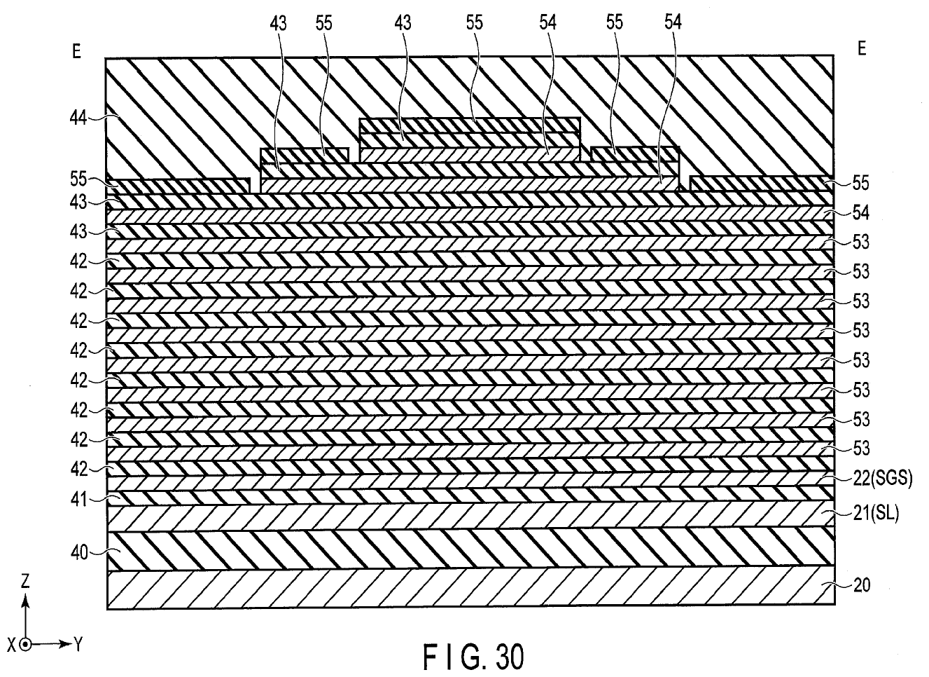

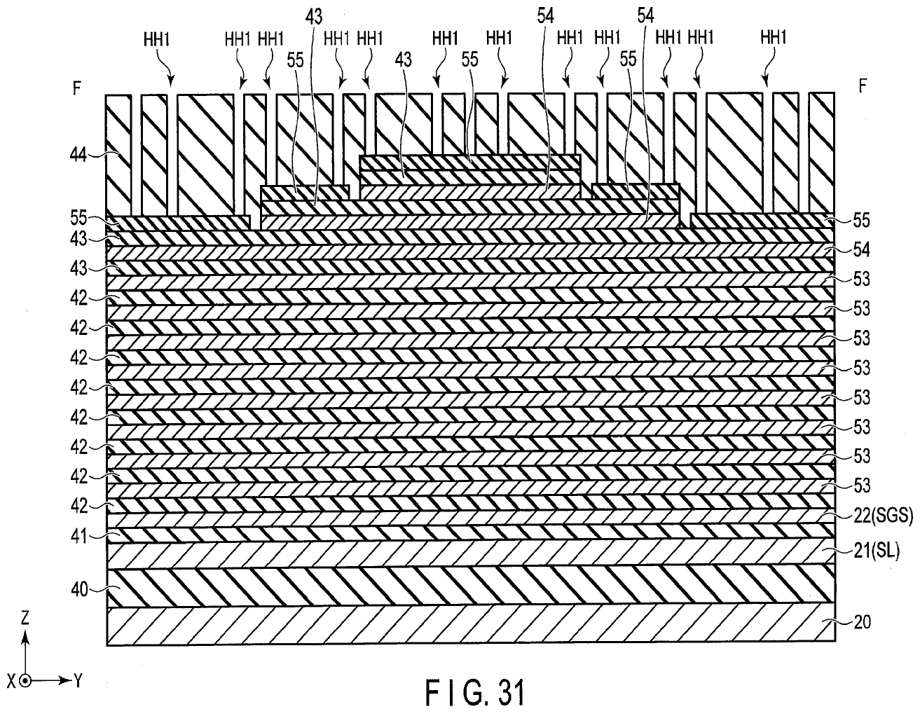

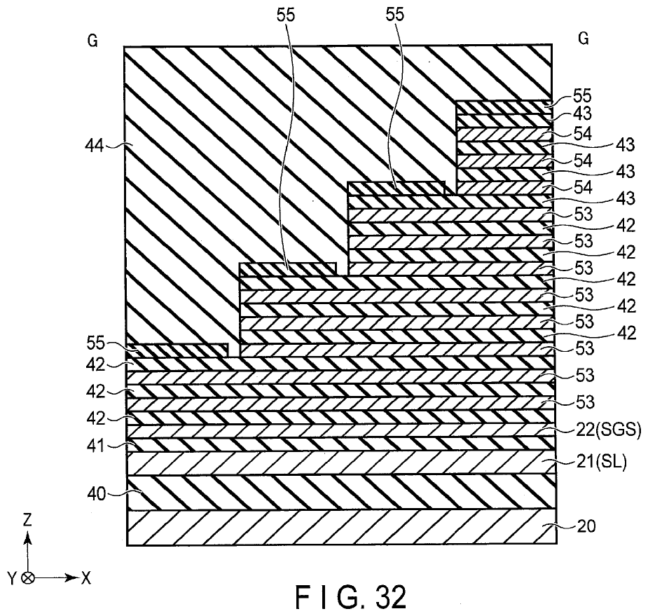

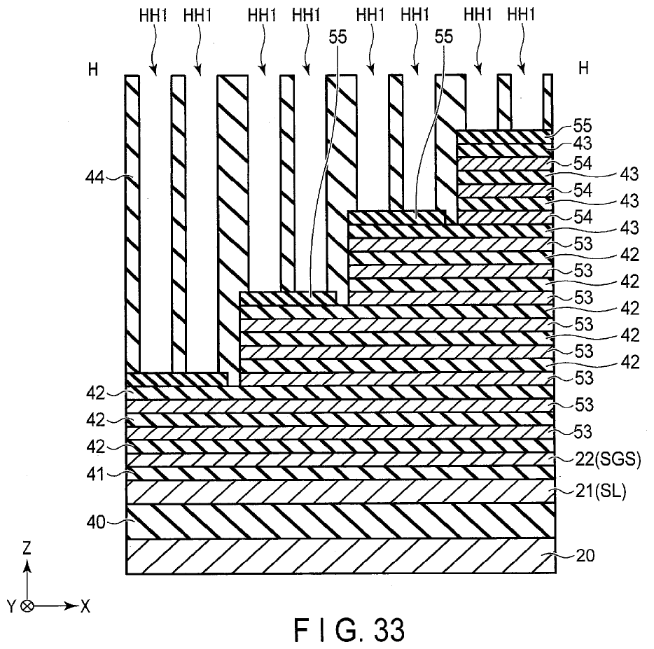

Step S1007 will be described with reference to FIGS. 29 to 33. FIG. 29 shows the area corresponding to FIG. 7. Shown in FIG. 29 are first holes HH1 formed at positions at which support pillars HR are formed in a later step. The insulating layer 44 is omitted in FIG. 29, and the same applies to the figures showing the planar layouts of the subsequent manufacturing steps. FIG. 30 is a cross-sectional view showing a cross section taken along line E-E in FIG. 29. FIG. 31 is a cross-sectional view showing a cross section taken along line F-F in FIG. 29. FIG. 32 is a cross-sectional view showing a cross section taken along line G-G in FIG. 29. FIG. 33 is a cross-sectional view showing a cross section taken along line H-H in FIG. 29.

The first holes HH1 are formed in step S1007. Specifically, as shown in FIGS. 29 to 33, an insulating layer 44 is formed to cover the entire semiconductor memory device 1 after step S1006, and the top surface thereof is planarized. The insulating layer 44 includes, for example, silicon oxide (SiO₂) Then, a mask including openings at positions corresponding to support pillars HR is formed by, for example, photolithography. The first holes HH1 are then formed by anisotropic etching using the formed mask. Each of the first holes HH1 formed in this step passes through the insulating layer 44 so that the bottom of the first hole HH1 stops, for example, within the stoppers 55. The anisotropic etching in this step is, for example, RIE. The first holes HH1 are used to partially remove the stoppers 55. The first holes HH1 are also formed in regions in which the slits SLT are formed later so as to remove the stoppers 55 in the regions in which the slits SLT are formed. This is because, when trenches PSLT are formed in the regions in which the slits SLT are formed, the processing may be stopped at the stoppers 55, which may increase the number of manufacturing steps.

In a later step, the sacrificial members 53 and 54 are replaced with the conductive layers 23 and 24 by means using phosphoric acid (H₃PO₄). At that time, if, for example, polysilicon is used as the stopper 55, polysilicon may be removed by phosphoric acid. Consequently, in the regions from which the stopper 55 is removed above the word line WL or select gate line SGD to which the contact plug is coupled, a conductive layer made of the same material as the word line WL or select gate line SGD is formed. Namely, the selection ratio cannot be secured between the stopper 55 and the conductive layer to which the contact plug is coupled. To avoid such a structure, the first holes HH1 are preferably formed also in the regions in which the slits SLT are formed.

[S1008]

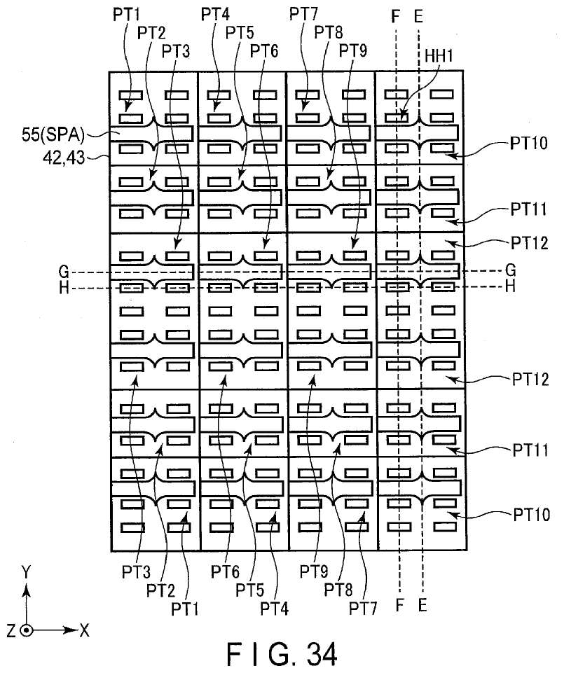

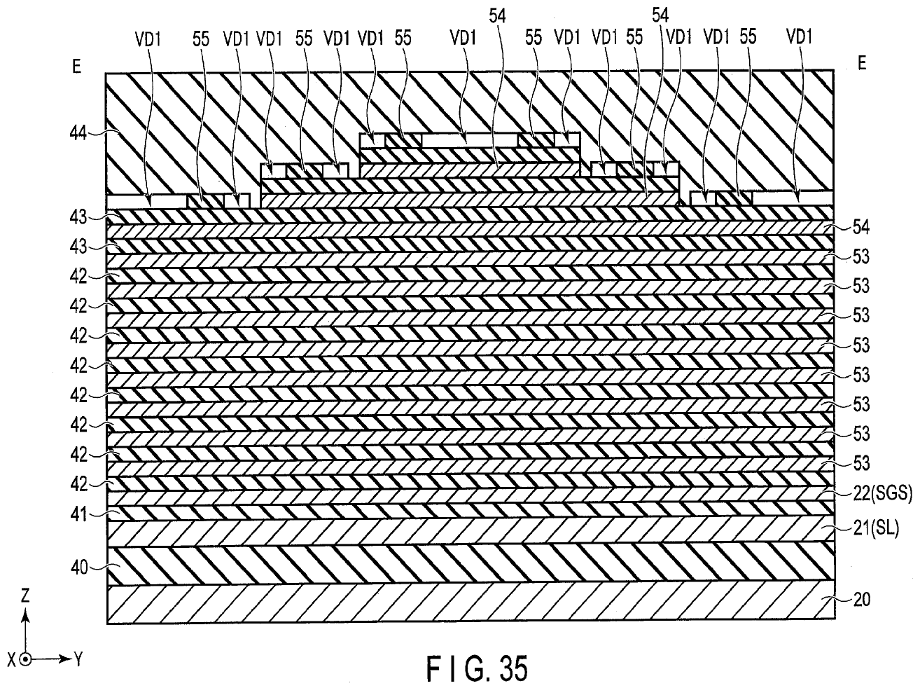

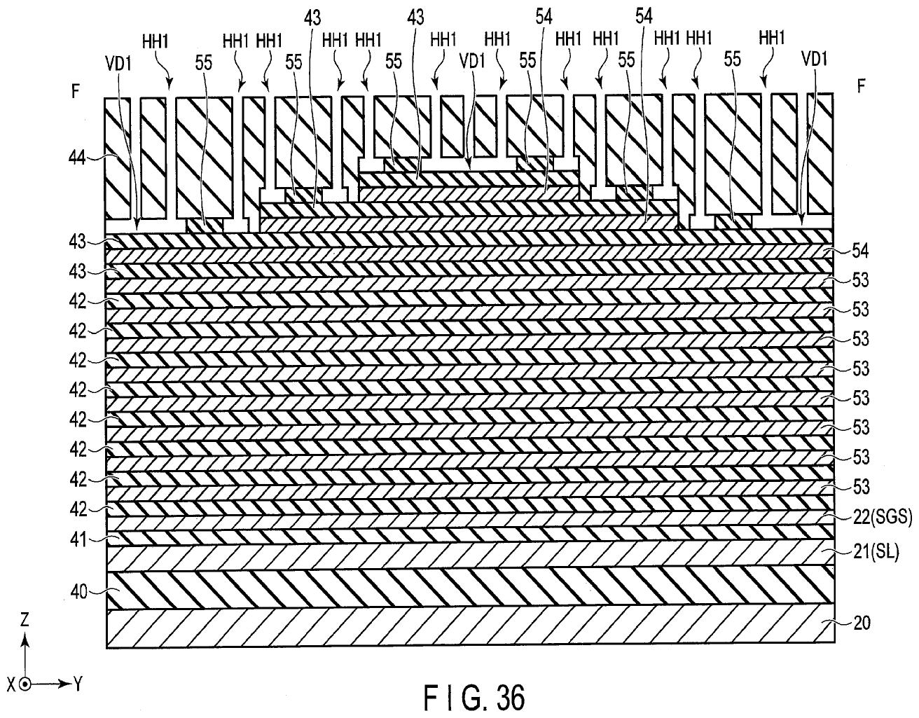

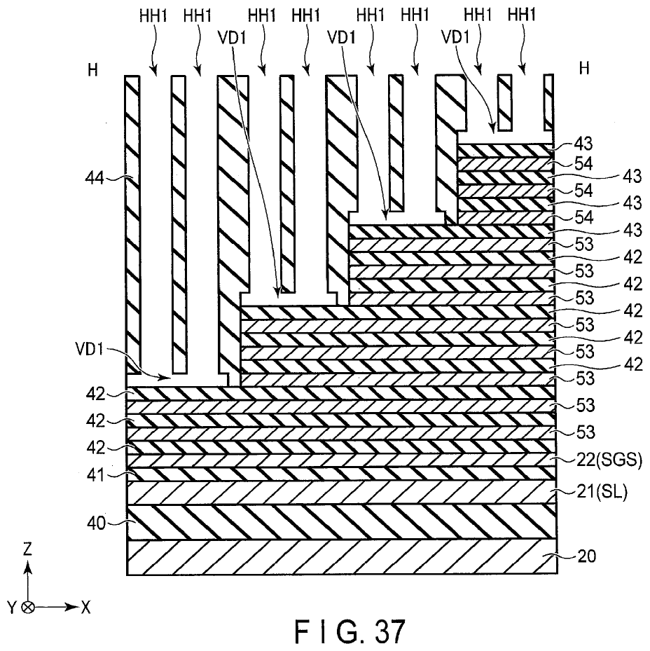

Step S1008 will be described with reference to FIGS. 34 to 37. FIG. 34 shows the area corresponding to FIG. 7. Shown in FIG. 34 is the stopper 55 remaining after etching. FIG. 35 is a cross-sectional view showing a cross section taken along line E-E in FIG. 34. FIG. 36 is a cross-sectional view showing a cross section taken along line F-F in FIG. 34. FIG. 37 is a cross-sectional view showing a cross section taken along line H-H in FIG. 34.

The stoppers 55 are partially removed via the first holes HH1 in step S1008. Specifically, as shown in FIGS. 34 to 37, dry etching (chemical dry etching (CDE)) is performed via the first holes HH1 formed in step S1007. Accordingly, the stoppers 55 provided on the bottoms of the first holes HH1 and therearound are partially removed. The portions from which the stoppers 55 are removed become voids VD1.

When the stopper 55 is resistant to phosphoric acid (H₃PO₄), the structure after the replacement processing described in step S1007 is not produced; therefore, this step S1008 may be omitted.

[S1009]

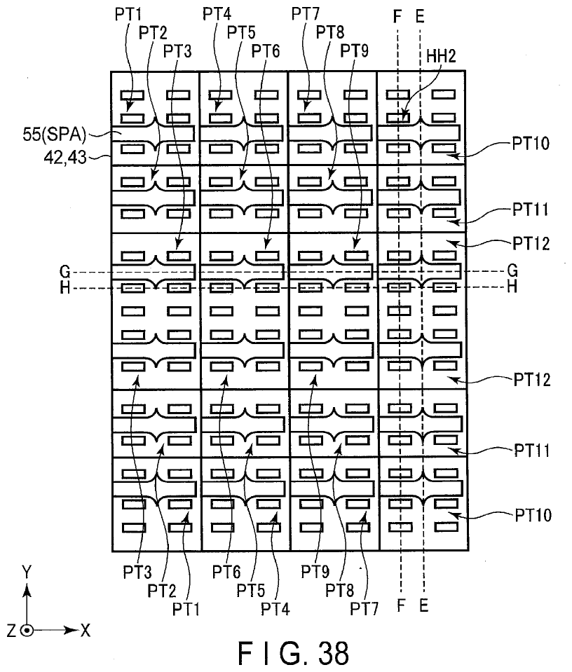

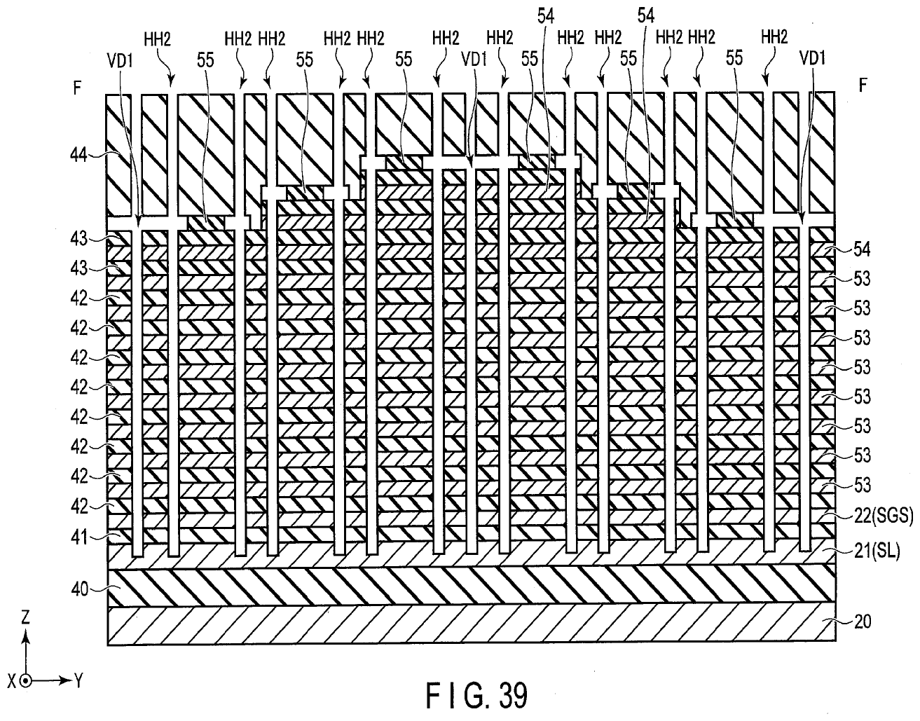

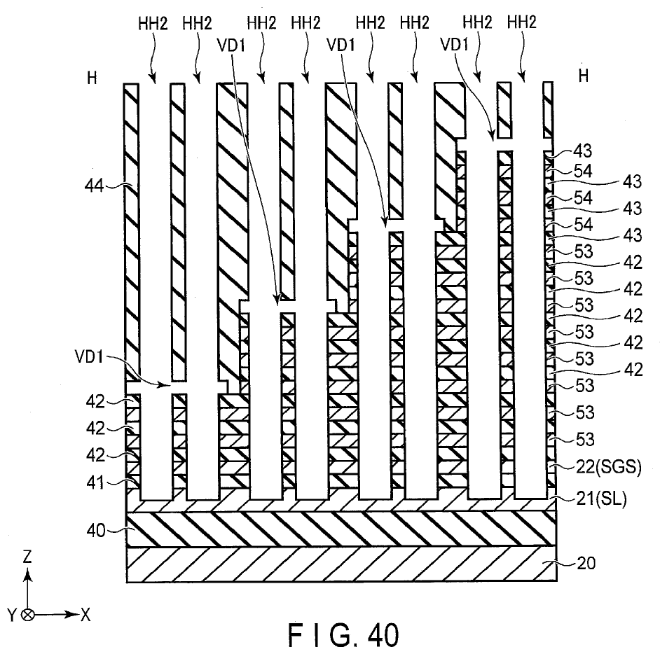

Step S1009 will be described with reference to FIGS. 38 to 40. FIG. 38 shows the area corresponding to FIG. 7. Shown in FIG. 38 are second holes HH2 to be filled with support pillars HR in a later step. FIG. 39 is a cross-sectional view showing a cross section taken along line F-F in FIG. 38. FIG. 40 is a cross-sectional view showing a cross section taken along line H-H in FIG. 38.

The second holes HH2 are formed in step S1009. Specifically, as shown in FIGS. 38 to 40, the second holes HH2 are formed by removing the insulating layers 41 to 43, sacrificial members 53 and 54, and conductive layer 22 below the first holes HH1 by anisotropic etching. Each of the second holes HH2 formed in this step passes through the insulating layers 41 to 43, sacrificial members 53 and 54, and conductive layer 22 in the Z direction so that the bottom of the second hole HH2 stops, for example, within the conductive layer 21. The anisotropic etching in this step is, for example, RIE.

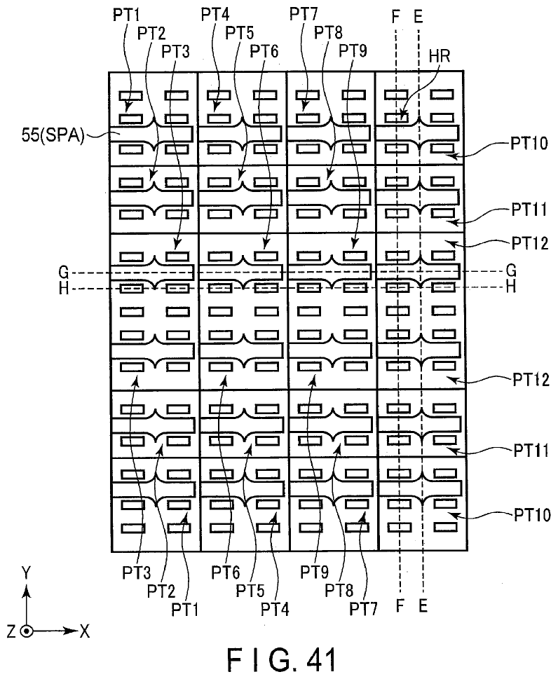

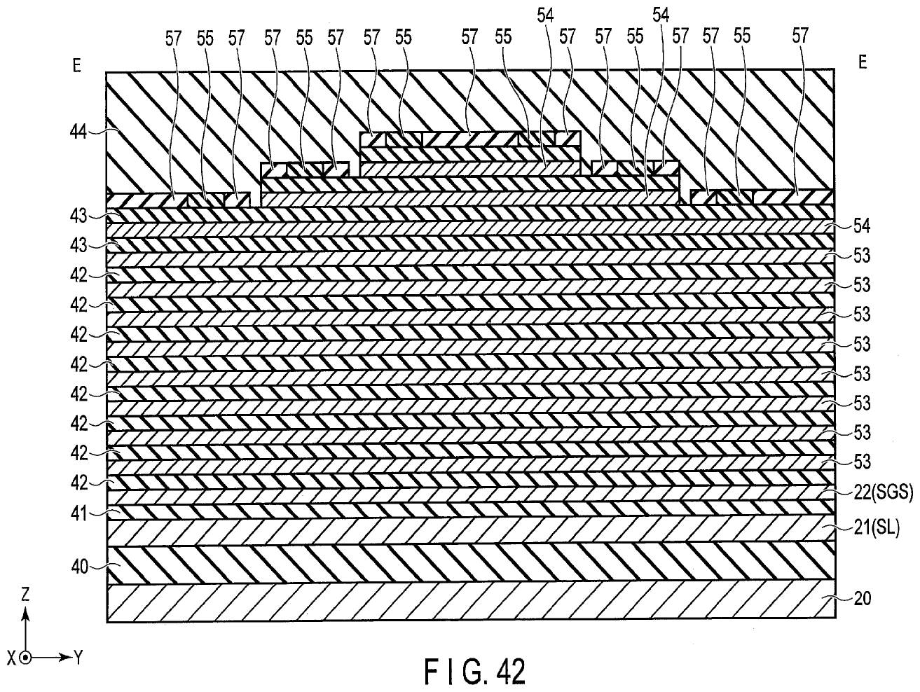

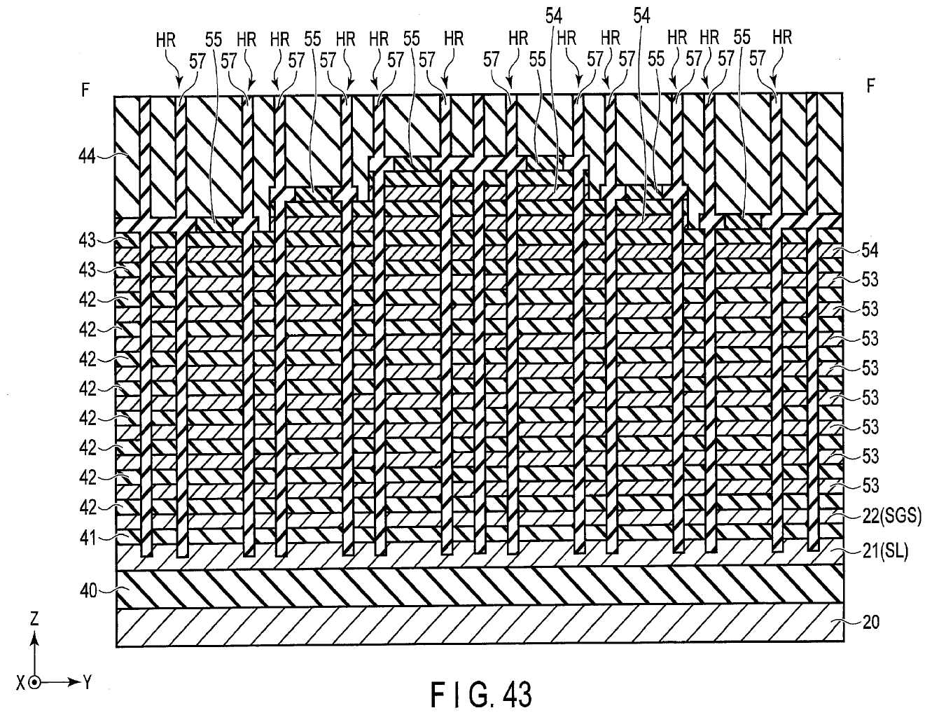

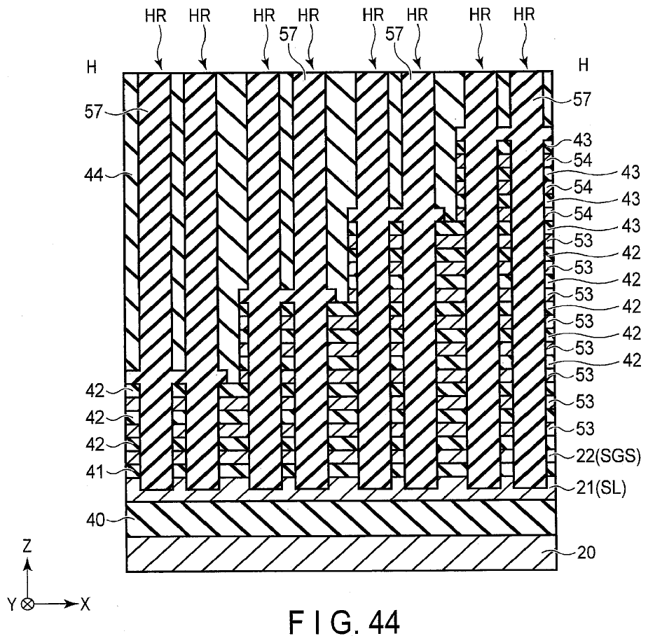

Step S1010 will be described with reference to FIGS. 41 to 44. FIG. 41 shows the area corresponding to FIG. 7. Shown in FIG. 41 are support pillars HR. FIG. 42 is a cross-sectional view showing a cross section taken along line E-E in FIG. 41. FIG. 43 is a cross-sectional view showing a cross section taken along line F-F in FIG. 41. FIG. 44 is a cross-sectional view showing a cross section taken along line H-H in FIG. 41.

The support pillars HR are formed in step S1010. Specifically, as shown in FIGS. 41 to 44, an insulating layer 57 is embedded in the second holes HH2 formed in step S1009. The insulating layer 57 is thereby embedded in the second holes HH2 and the voids VD1.

The insulating layer 57 embedded in each of the second holes HH2 will be referred to as the support pillar HR.

The insulating layer 57 embedded in each of the void VD1 will be referred to as the region SPB. The region SPB corresponds to a protruding portion of the insulating member constituting the insulating layer 57 which protrudes along the X-Y plane from the support pillar HR which extends in the Z direction.

[S1011]

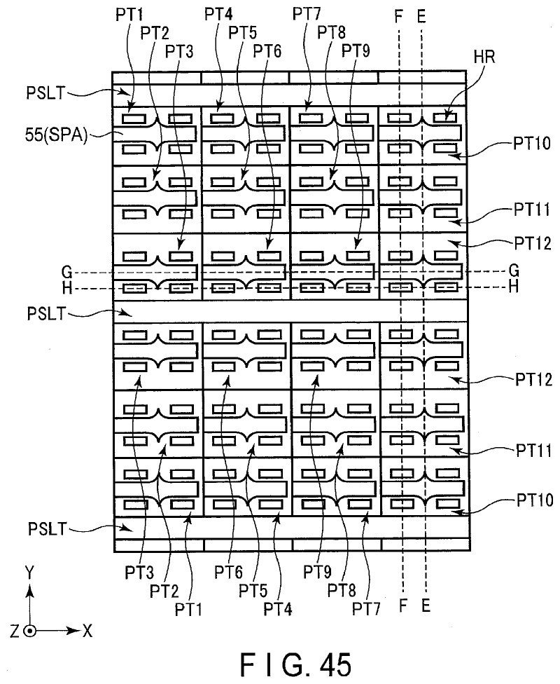

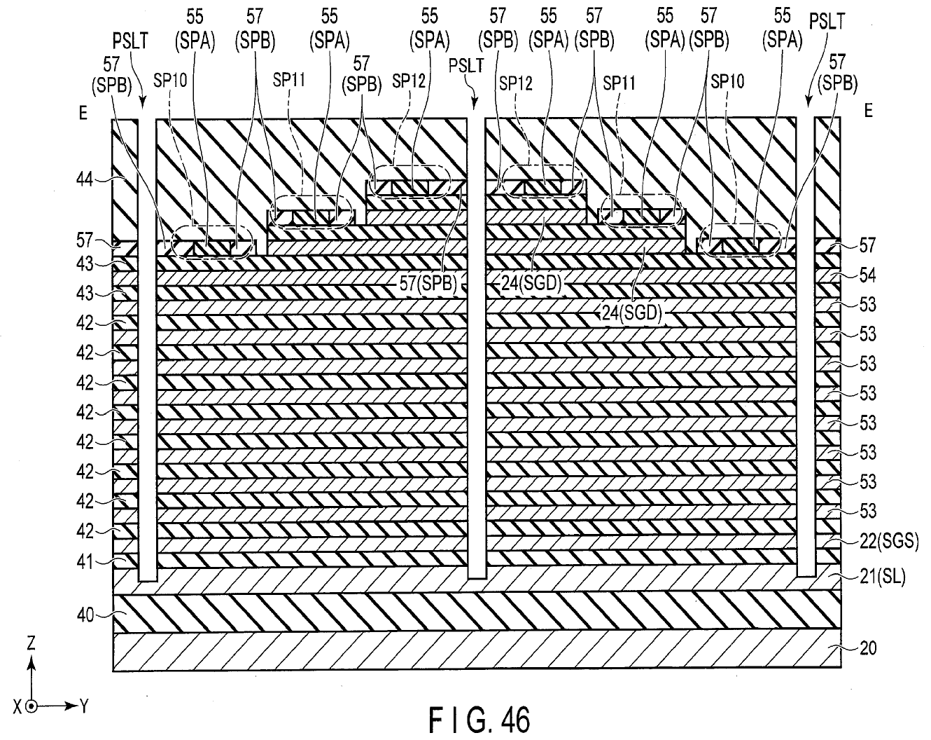

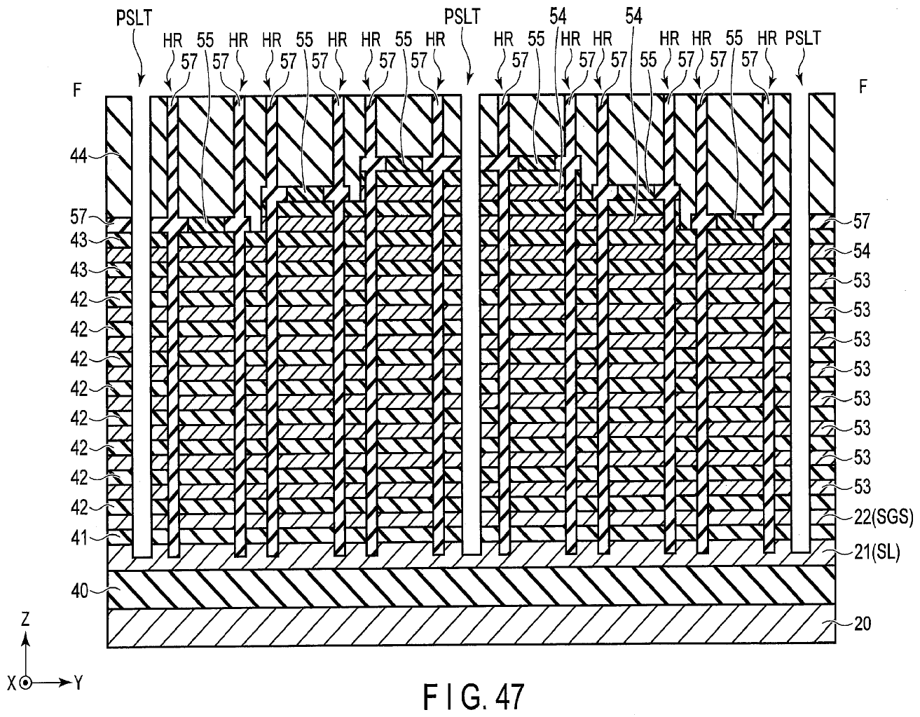

Step S1011 will be described with reference to FIGS. 45 to 47. FIG. 45 shows the area corresponding to FIG. 7. Shown in FIG. 45 are trenches PSLT, which will be converted to slits SLT later. FIG. 46 is a cross-sectional view showing a cross section taken along line E-E in FIG. 45. FIG. 47 is a cross-sectional view showing a cross section taken along line F-F in FIG. 45.

The trenches PSLT are formed in step S1011. Specifically, as shown in FIGS. 45 to 47, a mask including openings at positions corresponding to slits SLT is formed by, for example, photolithography. The trenches PSLT are formed by anisotropic etching using the formed mask. Each of the trenches PSLT formed in this step passes through the insulating layers 41 to 44 and 57, sacrificial members 54 and 53, and conductive layer 22 in the Z direction so that the bottom of the trench PSLT stops, for example, within the conductive layer 21. The anisotropic etching in this step is, for example, RIE.

[S1012]

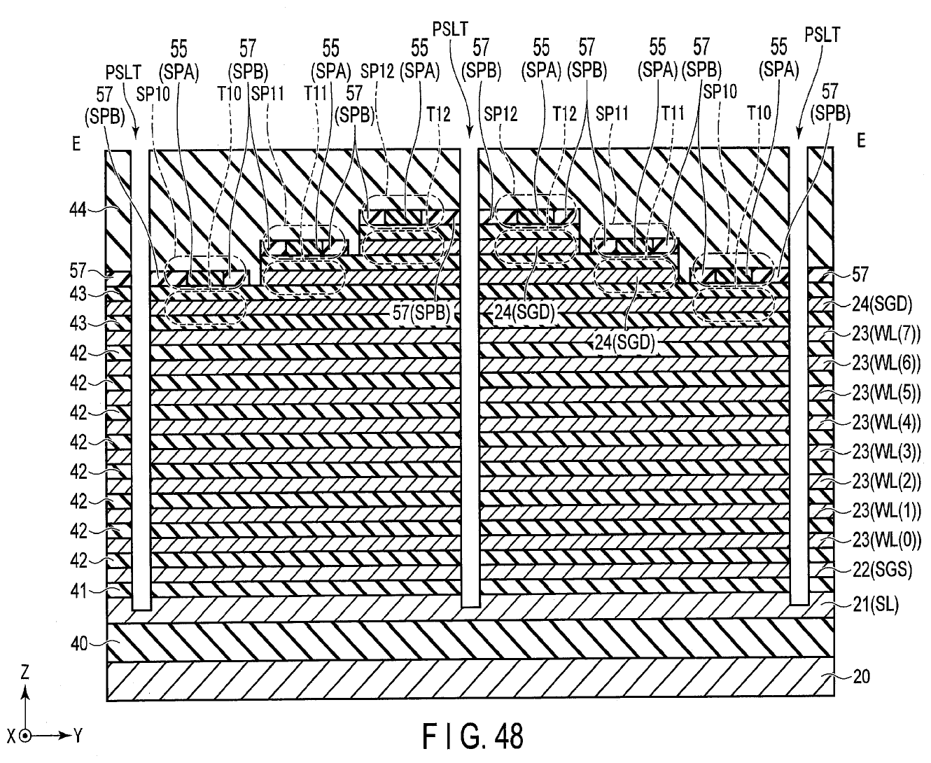

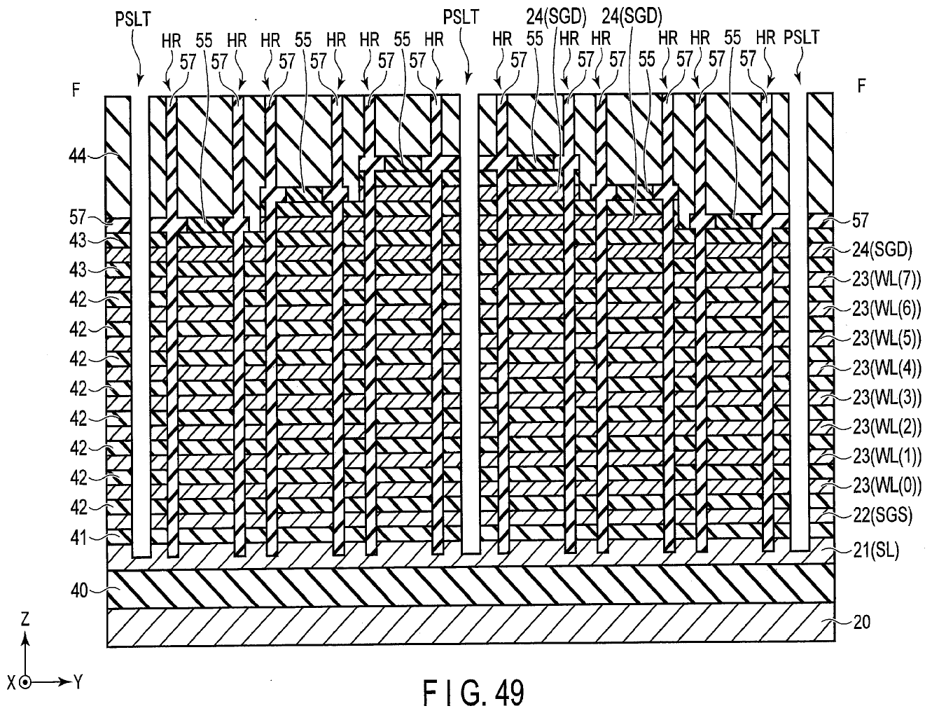

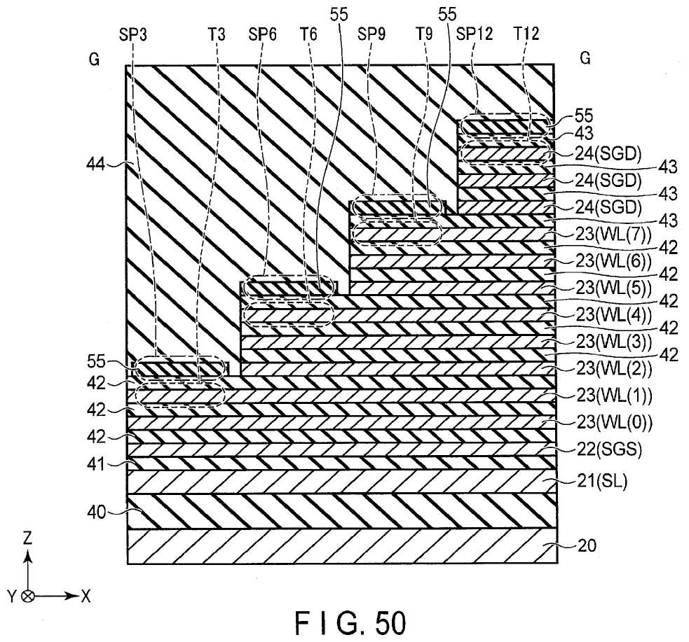

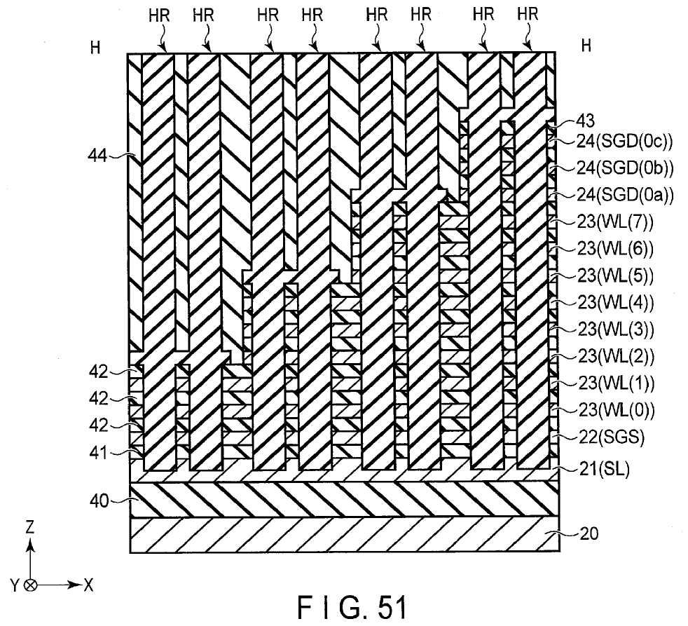

Step S1012 will be described with reference to FIGS. 48 to 51. FIG. 48 is a cross-sectional view showing a cross section taken along line E-E in FIG. 45. FIG. 49 is a cross-sectional view showing a cross section taken along line F-F in FIG. 45. FIG. 50 is a cross-sectional view showing a cross section taken along line G-G in FIG. 45. FIG. 51 is a cross-sectional view showing a cross section taken along line H-H in FIG. 45.

Replacement processing of stacked interconnect layers is executed in step S1012. Specifically, the sacrificial members 53 and 54 are selectively removed via the trenches PSLT by, for example, wet etching using thermal phosphoric acid. The three-dimensional structure from which the sacrificial members 53 and 54 have been removed is maintained by, for example, a plurality of memory pillars MP, support pillars HR, and the like. Then, as shown in FIGS. 48 to 51, a conductor is embedded in the spaces from which the sacrificial members 53 and 54 have been removed, via the trenches PSLT. In the formation of the conductor in this step, CVD for example, is used. Thereafter, the conductor formed in the trenches PSLT and the top surface of the insulating layer 44 is removed by etch-back processing. In this step, the conductors formed in adjacent interconnect layers are separated at least in the trenches PSLT.

The conductive layers 23 corresponding to the word lines WL(0) to WL(7) and the conductive layers 24 corresponding to the select gate lines SGD are thereby formed. The conductive layers 23 and 24 formed in this step may include a barrier metal. In this case, when the conductor is formed after removal of the sacrificial members 53 and 54, a tungsten layer is formed after, for example, a titanium nitride layer is formed as a barrier metal.

The terraces T are formed in this step. The stopper region SP is formed above each terrace T in the Z direction. The stopper region SP above each terrace T includes the region SPA of the stopper 55 and the region SPE of the insulating layer 57, which are adjacent to each other on the X-Y plane.

[S1013]

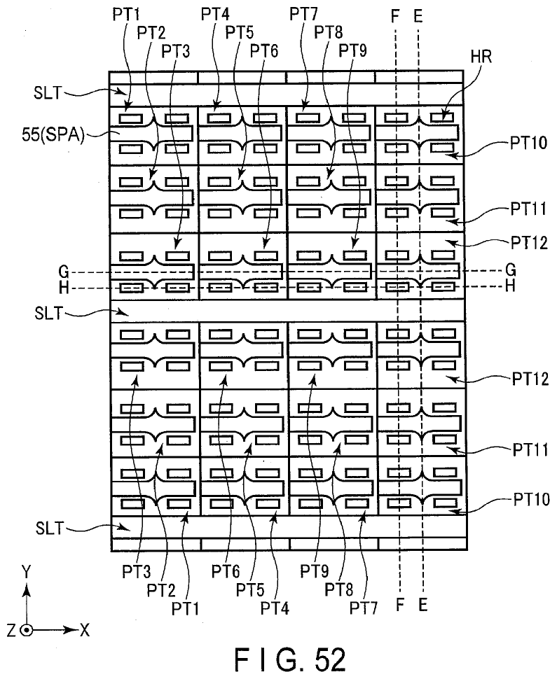

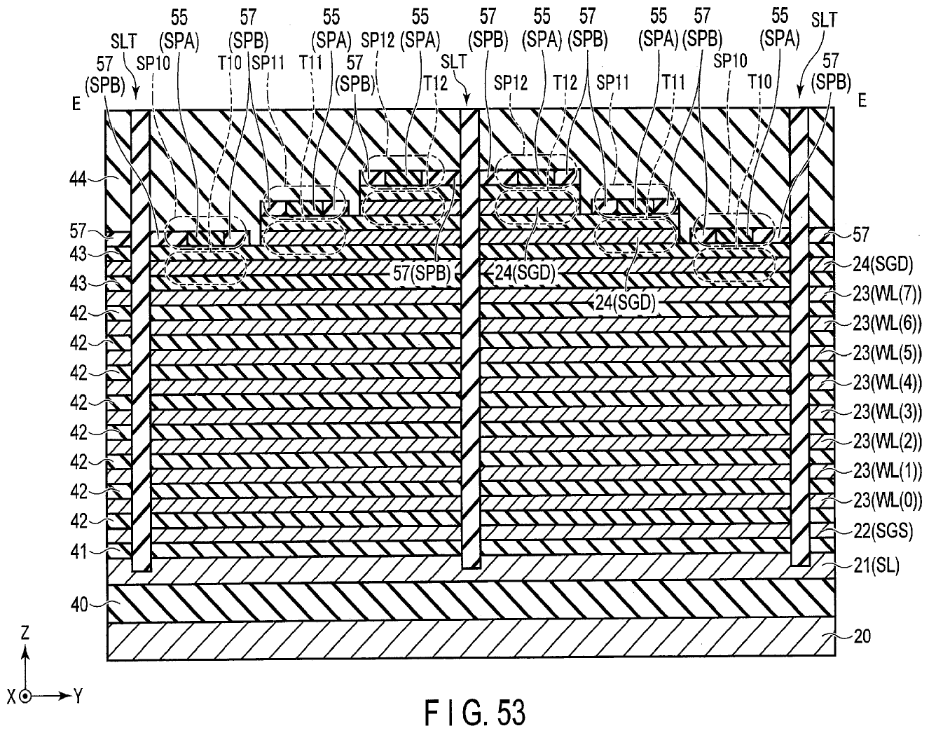

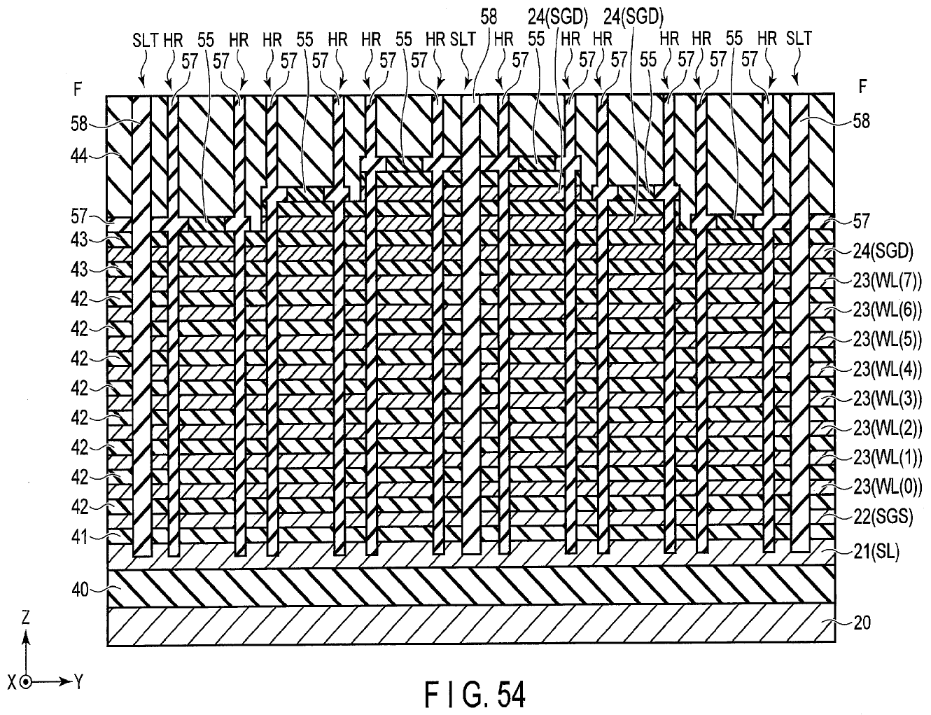

Step S1013 will be described with reference to FIGS. 52 to 54. FIG. 52 shows the area corresponding to FIG. 7. Shown in FIG. 52 are slits SLT. FIG. 53 is a cross-sectional view showing a cross section taken along line E-E in FIG. 52. FIG. 54 is a cross-sectional view showing a cross section taken along line F-F in FIG. 52.

Next, the slits SLT are formed in step S1013. Specifically, as shown in FIGS. 52 to 54, an insulating layer 58 is embedded in the trenches PSLT formed in step S1011. The insulating layer 58 embedded in each trench PSLT will be referred to as the slit SLT. The insulating layer 58 embedded in each trench PSLT is in contact with a portion of the insulating layer 57 which protrudes along the X-Y plane from a support pillar HR.

[S1014]

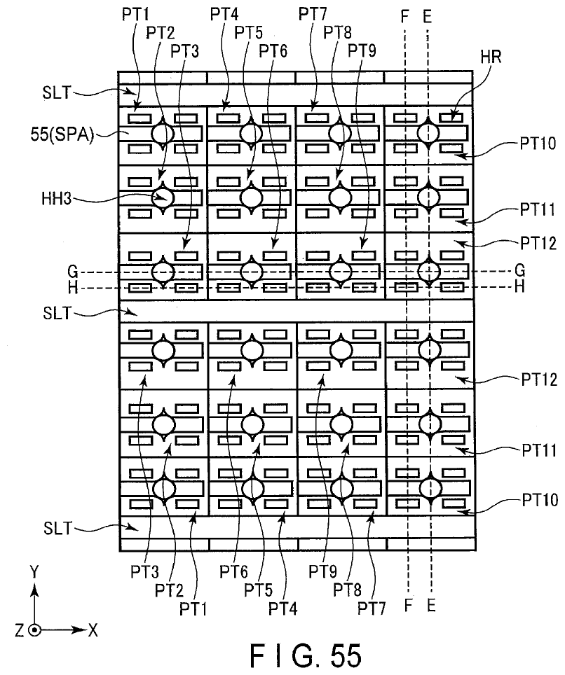

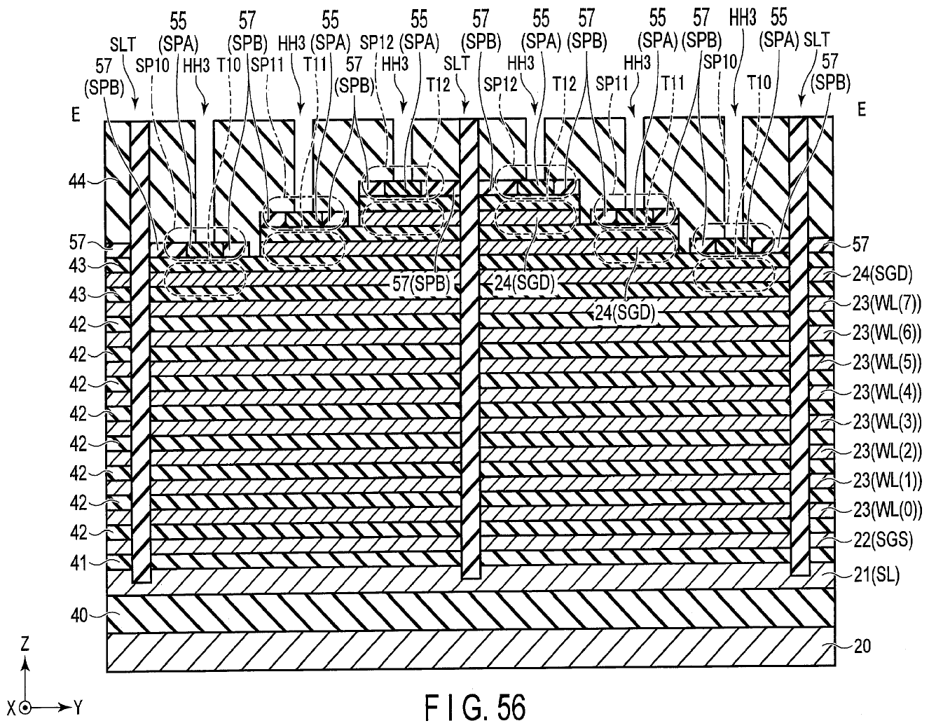

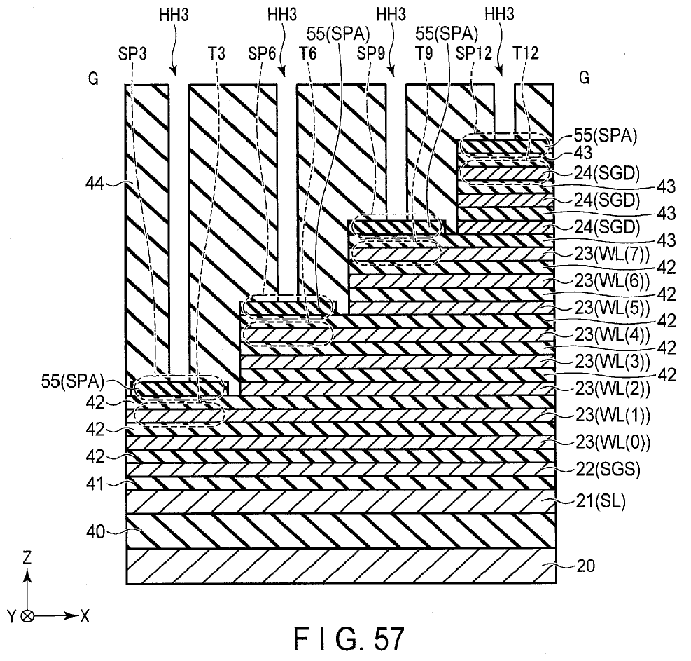

Step S1014 will be described with reference to FIGS. 55 to 57. FIG. 55 shows the area corresponding to FIG. 7. Shown in FIG. 55 are third holes HH3 provided at positions where contact plugs CC are formed in a later step. FIG. 56 is a cross-sectional view showing a cross section taken along line E-E in FIG. 55. FIG. 57 is a cross-sectional view showing a cross section taken along line G-G in FIG. 55.

The third holes HH3 are formed in step S1014. Specifically, as shown in FIGS. 55 to 57, a mask including openings at positions corresponding to contact plugs CC is formed by, for example, photolithography. At this time, the regions corresponding to the contact plugs CC are provided with the stoppers 55 (SPA). The third holes HH3 are then formed by anisotropic etching using the formed mask. Each of the third holes HH3 formed in this step passes through the insulating layer 44 so that the bottom of the third hole HH3 stops, for example, within the stoppers 55 (SPA). The anisotropic etching in this step is, for example, RIE. For example, when the insulating layers 41 to 44 are silicon oxide, the anisotropic etching of the insulating layer 44 adopts the condition that the etching rate of the stoppers 55 (SPA) is lower than that of the insulating layer 44 (insulating layers 41 to 44).

As described above, the stopper region SP is formed above each terrace T in the Z direction. Therefore, etching can be stopped by the stopper region SP before a hole that reaches each terrace T is formed.

[S1015]

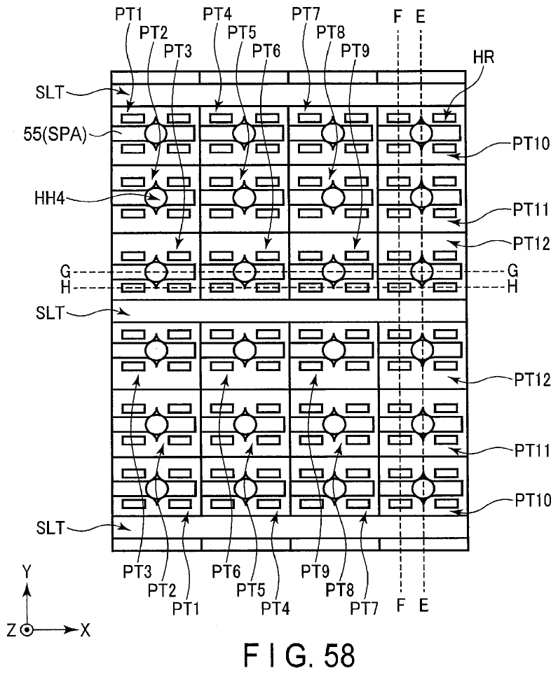

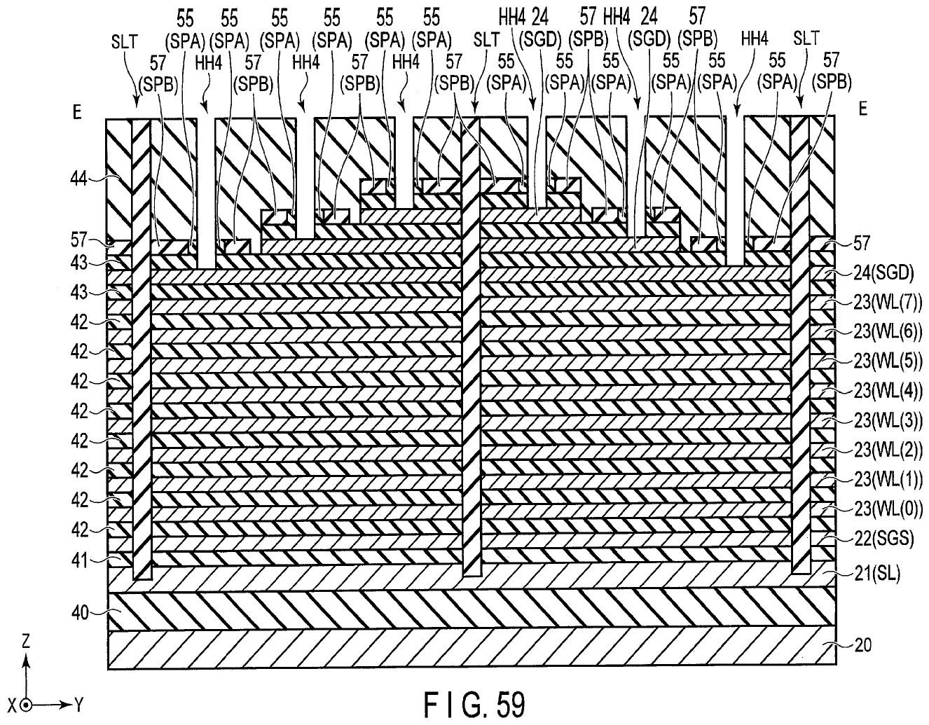

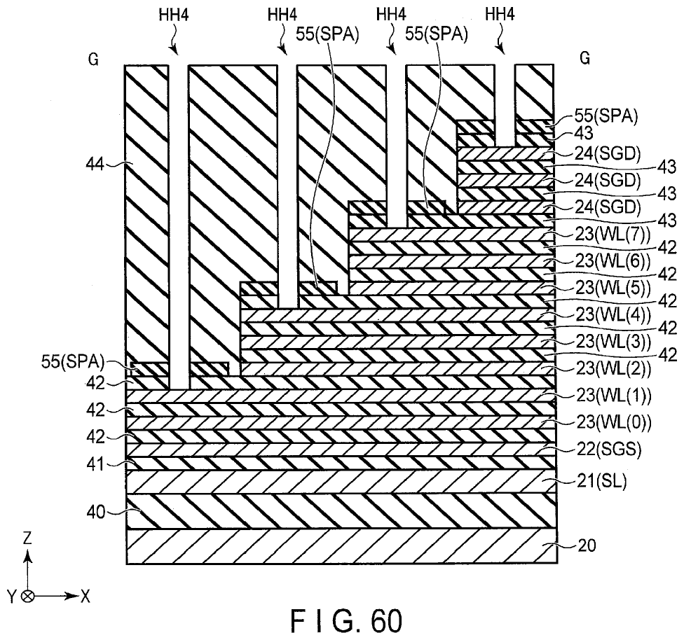

Step S1015 will be described with reference to FIGS. 58 to 60. FIG. 58 shows the area corresponding to FIG. 7. Shown in FIG. 58 are fourth holes HH4 provided at positions where contact plugs CC are formed in a later step. FIG. 59 is a cross-sectional view showing a cross section taken along line E-E in FIG. 58. FIG. 60 is a cross-sectional view showing a cross section taken along line G-G in FIG. 58.

The fourth holes HH4 are formed in step S1015. Specifically, as shown in FIGS. 58 to 60, the fourth holes HH4 are formed by removing the stoppers 55 (SPA) at the bottoms of the third holes HH3 and the insulating layer 43 or 42 by anisotropic etching. Each of the fourth holes HH4 formed in this step passes through the stopper 55 (SPA) so that the bottom of the fourth hole HH4 stops, for example, within a conductive layer 23 or 24 provided below the stopper 55 (SPA). The anisotropic etching in this step is, for example, RIE.

Etching has already been collectively performed to reach the stopper regions SP. Therefore, the fourth holes HH4 can be formed in the respective terraces T in the same etching time. This can suppress over-etching of a terrace T caused by the difference in etching time due to the positional difference in the Z direction.

[S1016]

Step S1016 will be described with reference to FIGS. 7 to 11.

Contacts CC are formed in step S1016. Specifically, as shown in FIGS. 7 to 11, the contact plugs CC are formed on the respective terraces T by embedding a conductive layer 61 in the fourth holes HH4.

Then, the top surface of the insulating layer 44 is planarized by, for example, CMP.

By the above-described manufacturing steps, the hookup area HA of the memory cell array 10 of the semiconductor memory device 1 and the contact plugs CC for supplying voltages to the word lines WL and the like in the hookup area HA can be formed. The above-described manufacturing steps are merely an example, and another step may be inserted between manufacturing steps.

### <1-5> Advantageous Effects

According to the above-described embodiment, the stoppers 55 for stopping etching are formed above the terraces T in contact with the contact plugs CC in the hookup area HA. Accordingly, etching can be appropriately performed even when holes for the contact plugs CC are formed for the terraces T at different levels.

When contact plugs CC are brought into contact with terraces T at different levels in the Z direction, the etching time differs depending on the level of the terrace T. Therefore, if etching is collectively performed on the terraces T at different levels, terraces Tin upper layers may be over-etched. In addition, when the conductive layer thickness in the Z direction at a terrace T is thin, the terrace T may be passed through. In the present embodiment, however, the stoppers 55, which stop etching, are provided above the terraces T in the Z direction. Therefore, when holes for contact plugs CC brought into contact with the terraces T are formed, etching can be performed to reach the stoppers 55 before the holes reach the terraces T. As a result, etching in step S1015 can be performed on all the terraces T under approximately the same conditions. Consequently, the above-described over-etching due to the position of the terrace T in the Z direction can be suppressed.

Moreover, according to the above-described embodiment, the stoppers 55 provided above adjacent terraces T are separated. Therefore, even when for example a conductive material is used for the stopper 55, adjacent contact plugs CC are not short-circuited via adjacent stoppers 55. In addition, use of a conductive material for the stopper 55 can secure the selection ratio with the insulating layer 44; as a result, the stopper 55 can be effectively used when holes for contact plugs CC are formed. Therefore, over-etching due to the position of the terrace T can be suppressed.

### <2> Modifications

### <2-1> Method for Manufacturing Semiconductor Memory Device According to First Modification

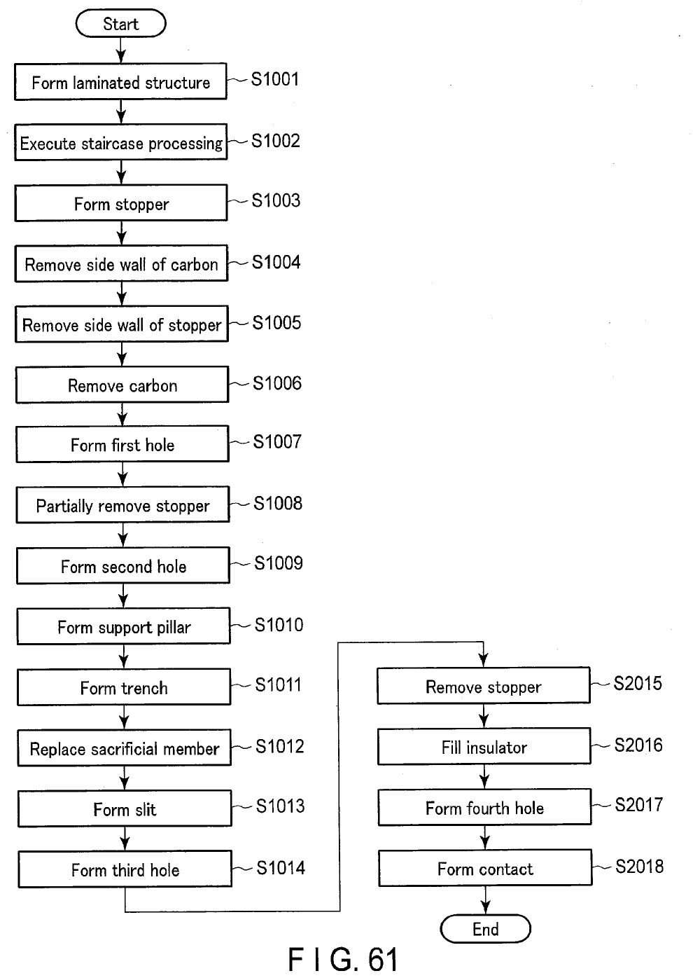

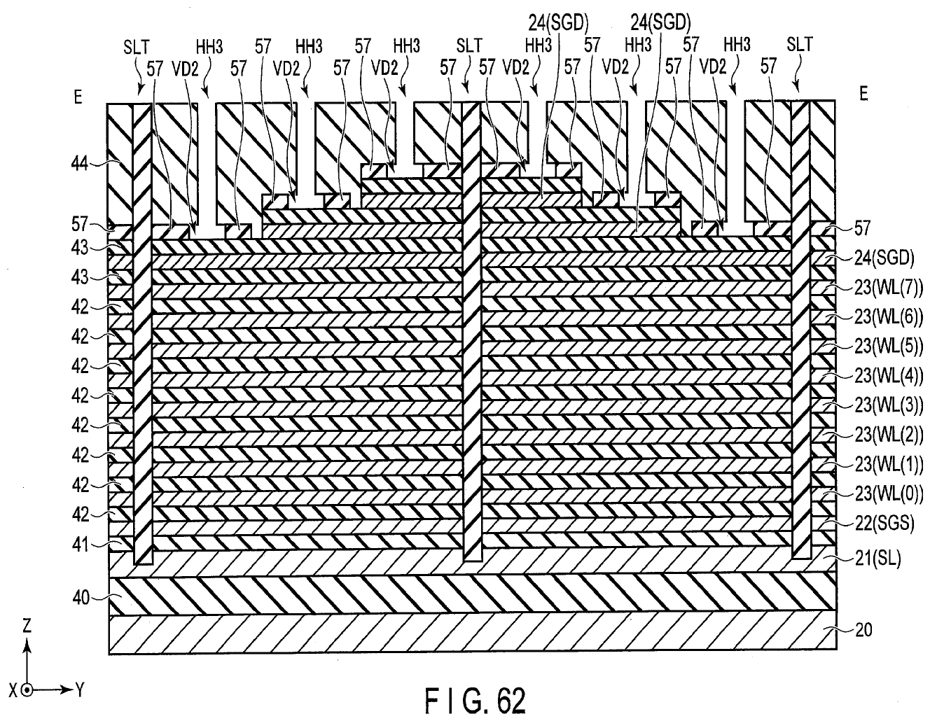

Hereinafter, an example of the series of manufacturing steps related to the hookup area in the semiconductor memory device 1 according to a first modification of the embodiment will be described, with reference to FIG. 61 as appropriate. FIG. 61 is a flowchart showing an example of the method for manufacturing the semiconductor memory device 1 according to the first modification of the embodiment. FIGS. 62 to 71 show cross-sectional structures respectively including structures corresponding to the memory cell array 10 in respective manufacturing steps of the semiconductor memory device 1 according to the first modification of the embodiment. For simplification, descriptions of the steps for manufacturing the cell area CA are omitted herein. The plan view of each manufacturing step to be referred to below shows the area corresponding to FIG. 7.

[S1001] to [S1014]

Steps S1001 to S1014 are the same as those described with reference to FIG. 12.

[S2015]

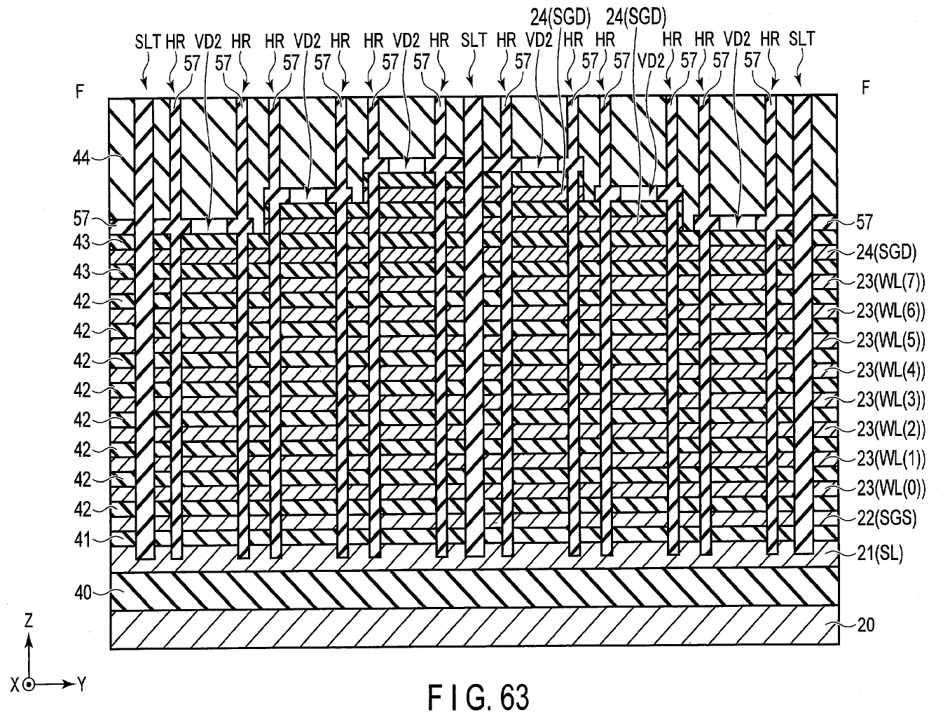

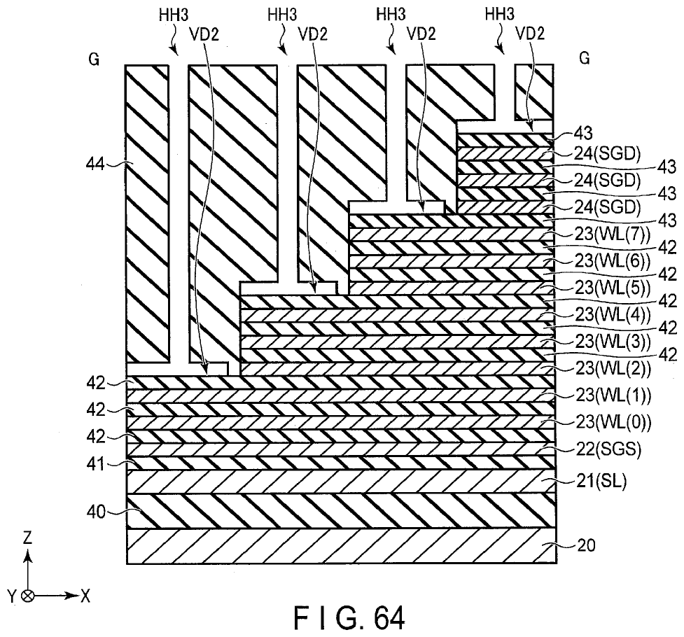

Step S2015 will be described with reference to FIGS. 62 to 64. FIG. 62 is a cross-sectional view showing a cross section taken along line E-E in FIG. 55. FIG. 63 is a cross-sectional view showing a cross section taken along line F-F in FIG. 55. FIG. 64 is a cross-sectional view showing a cross section taken along line G-G in FIG. 55.

The stoppers 55 are removed via the third holes HH3 in step S2015. Specifically, as shown in FIGS. 62 to 64, wet etching is performed via the third holes HH3 formed in step S1014. The stoppers 55 at the bottoms of the third holes HH3 and therearound are thereby removed. The portions from which the stoppers 55 are removed become voids VD2.

[S2016]

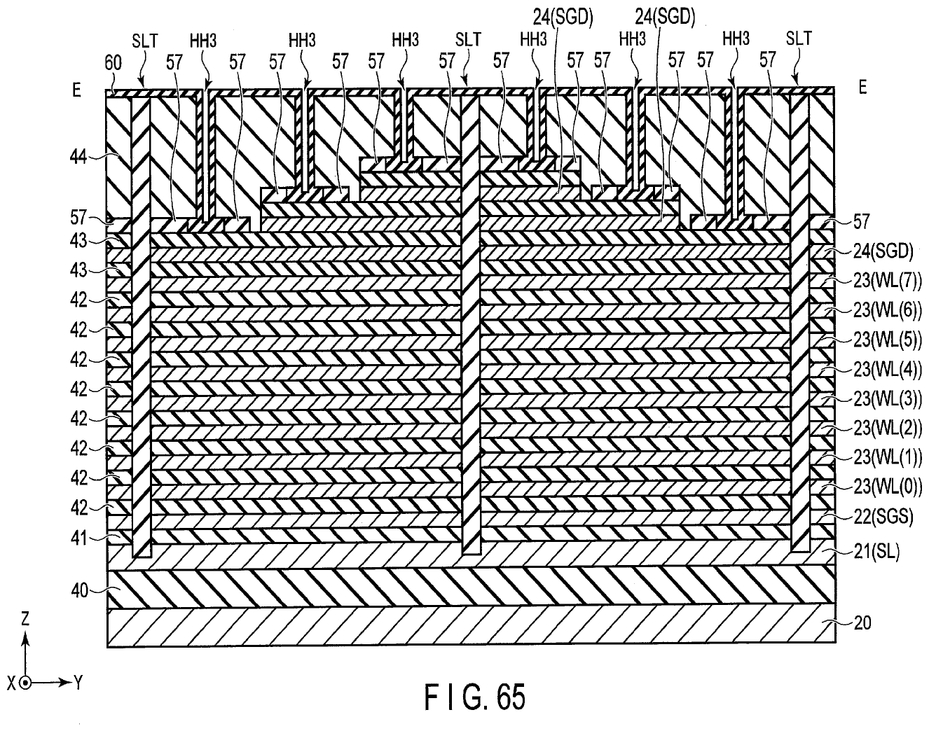

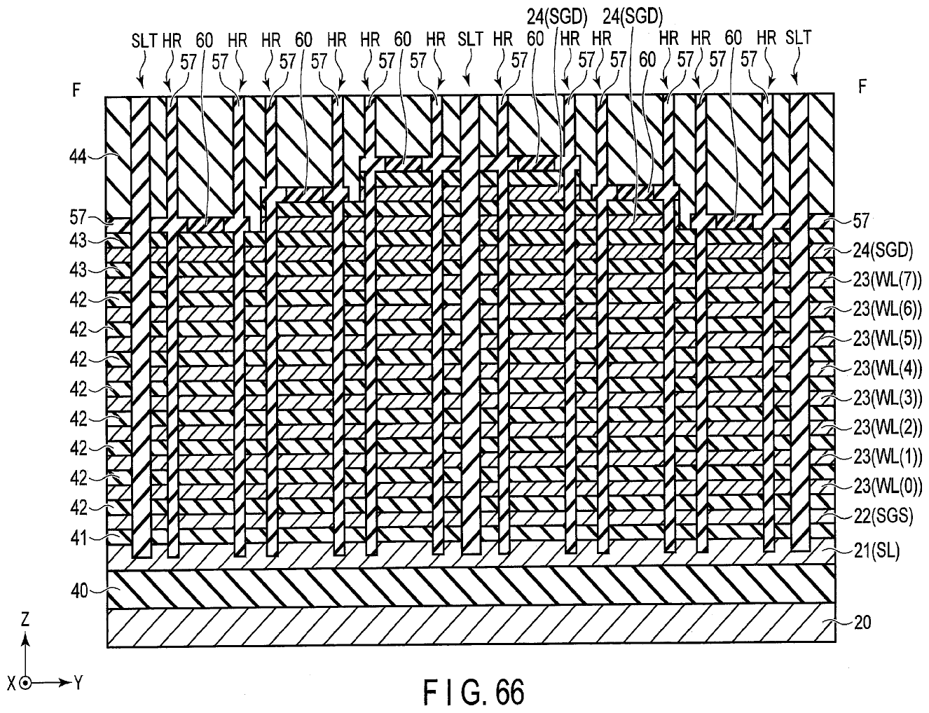

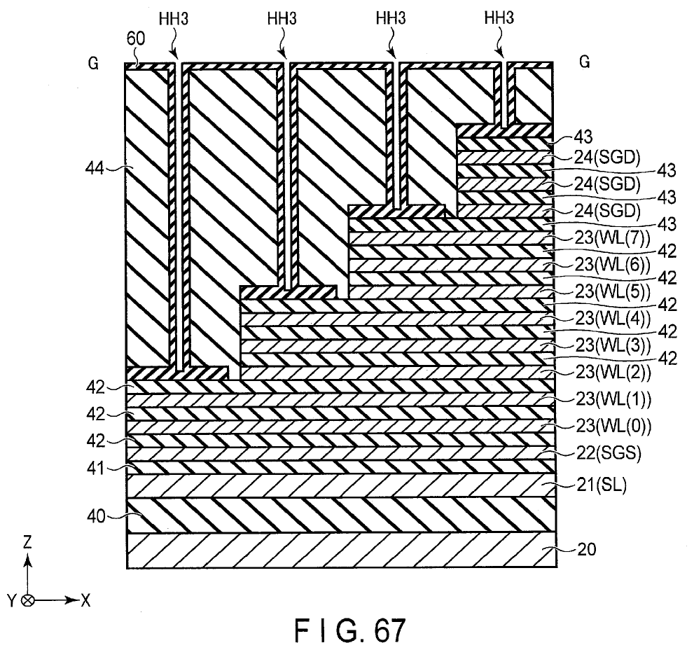

Step S2016 will be described with reference to FIGS. 65 to 67. FIG. 65 is a cross-sectional view showing a cross section taken along line E-E in FIG. 55. FIG. 66 is a cross-sectional view showing a cross section taken along line F-F in FIG. 55. FIG. 67 is a cross-sectional view showing a cross section taken along line G-G in FIG. 55.

An insulator is embedded in the voids VD2 in step S2016. Specifically, as shown in FIGS. 65 to 67, an insulating layer 60 is deposited on the entire surface so that the insulating layer 60 is embedded in the voids VD2 formed in step S2015.

[S2017]

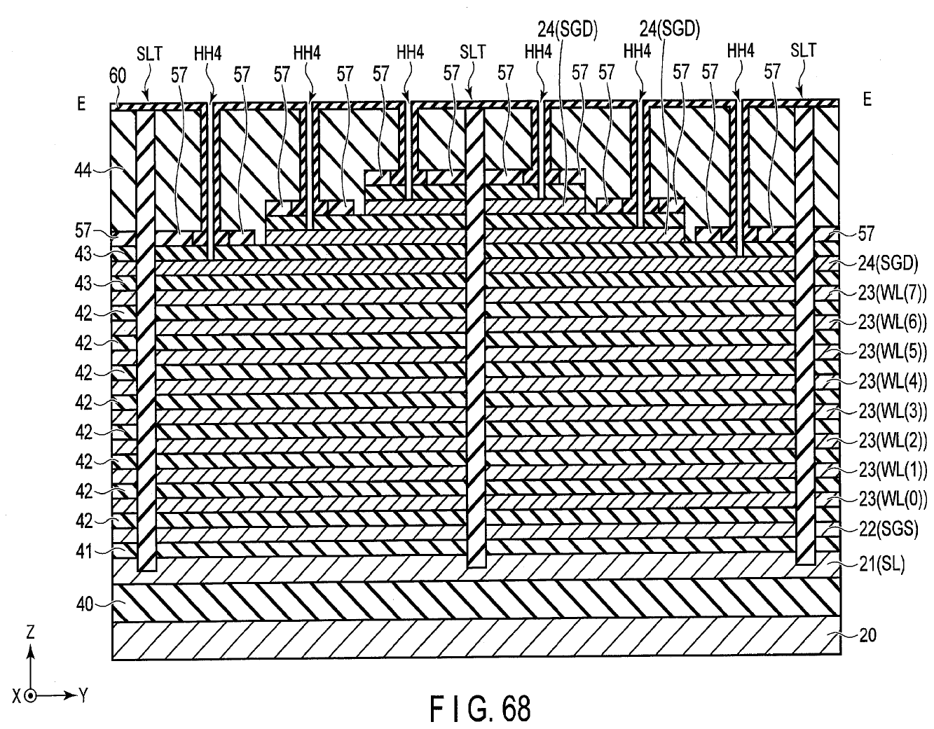

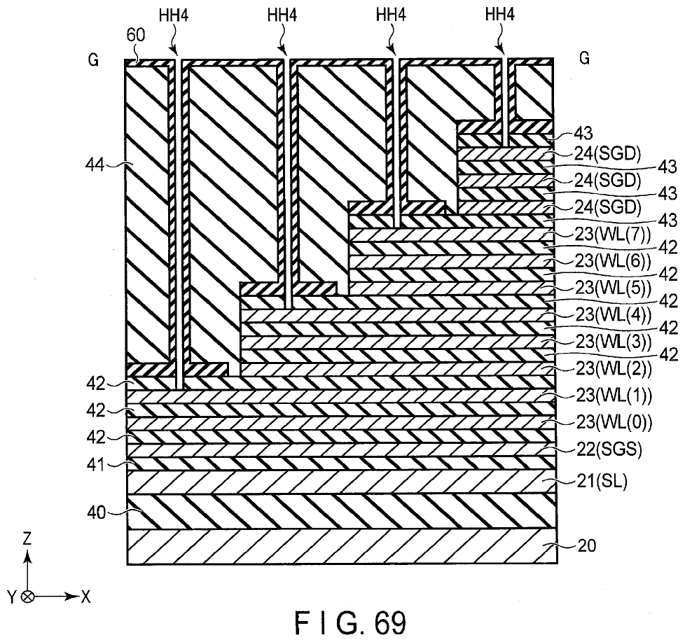

Step S2017 will be described with reference to FIGS. 68 and 69. FIG. 68 is a cross-sectional view showing a cross section taken along line E-E in FIG. 58. FIG. 69 is a cross-sectional view showing a cross section taken along line G-G in FIG. 58.

The fourth holes HH4 are formed in step S2017. Specifically, as shown in FIGS. 68 and 69, the fourth holes HH4 reaching the respective terraces T are formed by removing the insulating layer 60 at the bottoms of the third holes HH3 and the insulating layer 43 or 42 by anisotropic etching. The fourth holes HH4 formed in this step stop, for example, within a conductive layer 23 or 24 provided below the stopper 55. The anisotropic etching in this step is, for example, RIE.

[S2018]

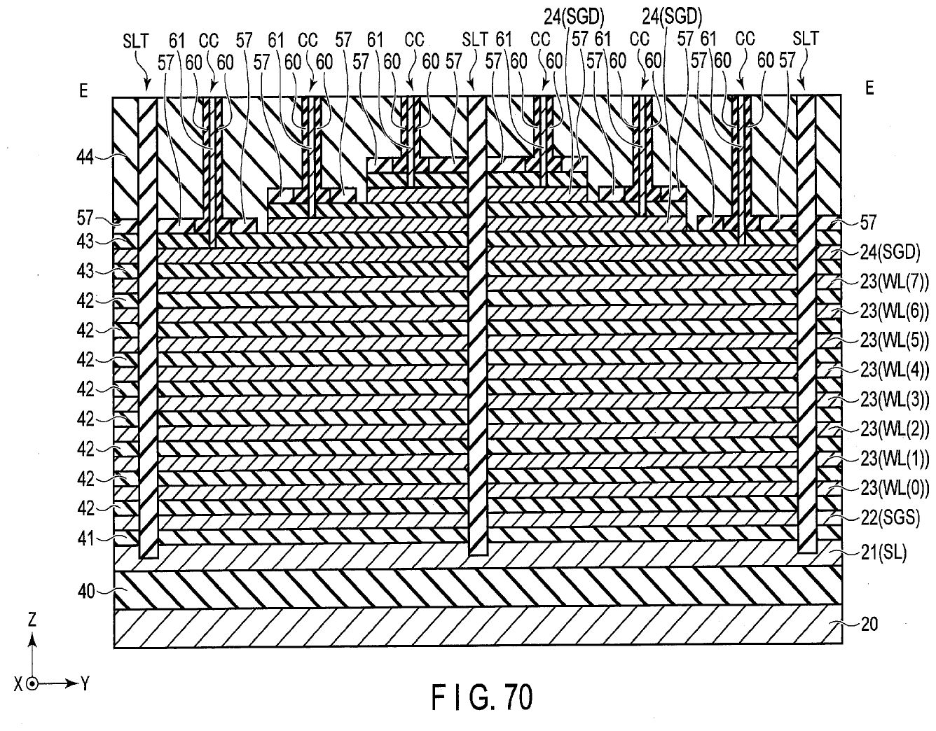

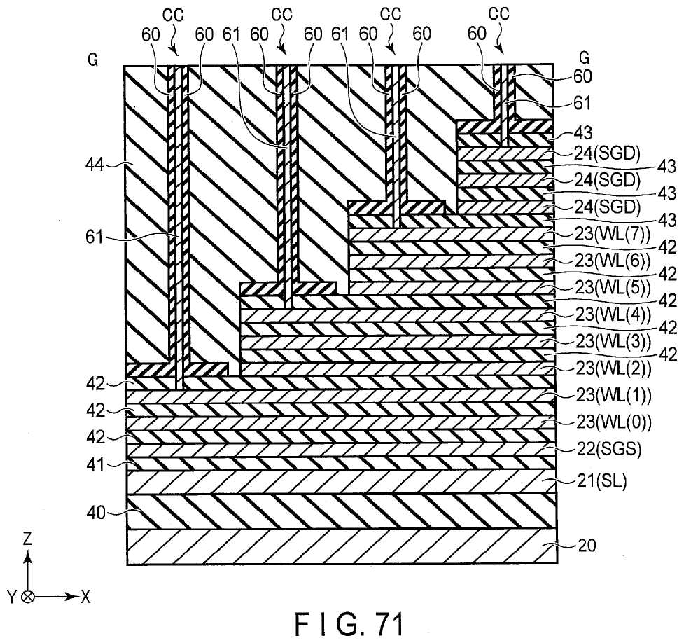

Step S2018 will be described with reference to FIGS. 70 and 71. FIG. 70 is a cross-sectional view showing a cross section taken along line E-E in FIG. 7. FIG. 71 is a cross-sectional view showing a cross section taken along line G-G in FIG. 7.

Contacts CC are formed in step S2018. Specifically, as shown in FIGS. 70 and 71, contact plugs CC are formed on the respective terraces T by embedding a conductive layer 61 in the fourth holes HH4. Then, the top surface of the insulating layer 44 is planarized by, for example CMP.

For example, when the stopper 55 is a film undesirable in terms of the characteristics of the semiconductor memory device 1, deterioration in the characteristics of the semiconductor memory device 1 can be suppressed by adopting this modification.

### <2-2> Method for Manufacturing Semiconductor Memory Device According to Second Modification

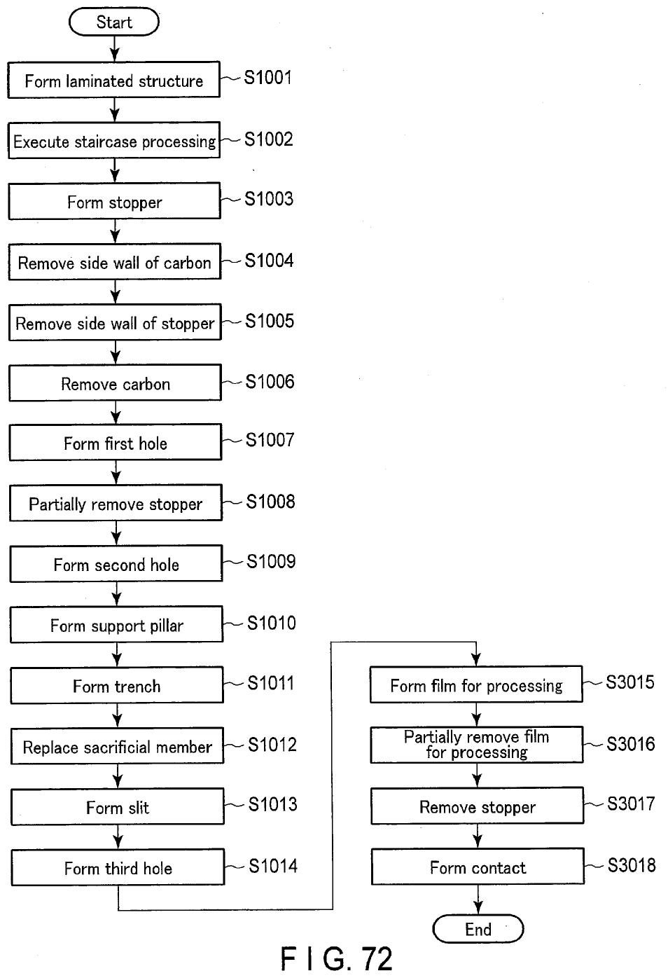

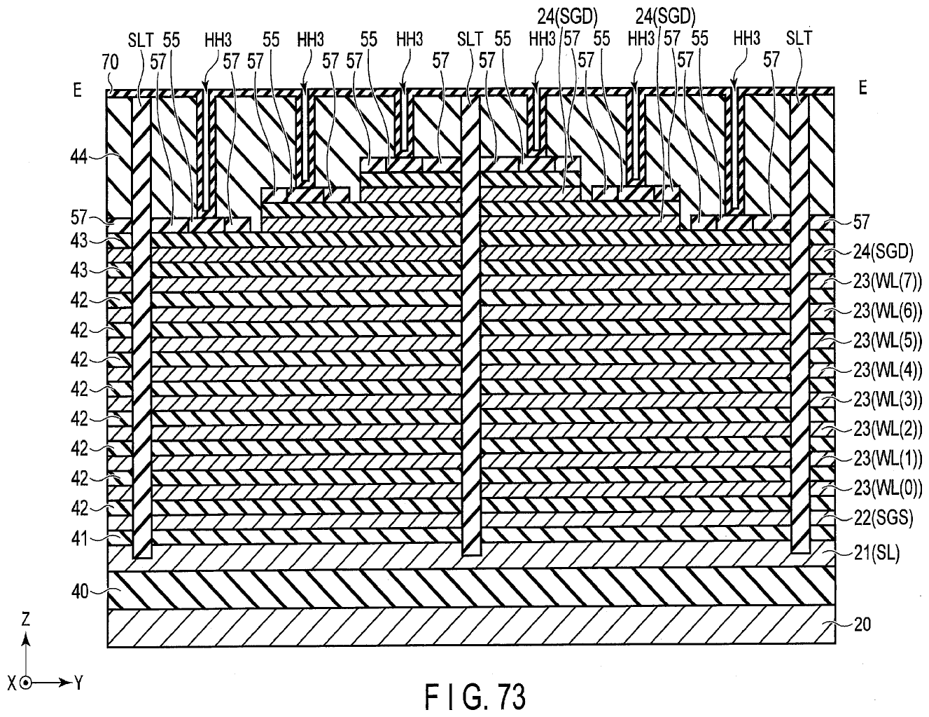

Hereinafter, an example of the series of manufacturing steps related to the hookup area in the semiconductor memory device 1 according to a second modification of the embodiment will be described, with reference to FIG. 72 as appropriate. FIG. 72 is a flowchart showing an example of the method for manufacturing the semiconductor memory device 1 according to the second modification of the embodiment. FIGS. 73 to 80 show cross-sectional structures respectively including structures corresponding to the memory cell array 10 in respective manufacturing steps of the semiconductor memory device 1 according to the second modification of the embodiment. For simplification, descriptions of the steps for manufacturing the cell area CA are omitted herein. The plan view of each manufacturing step to be referred to below shows the area corresponding to FIG. 7.

[S1001] to [S1014]

Steps S1001 to S1014 are the same as those described with reference to FIG. 12.

[S3015]

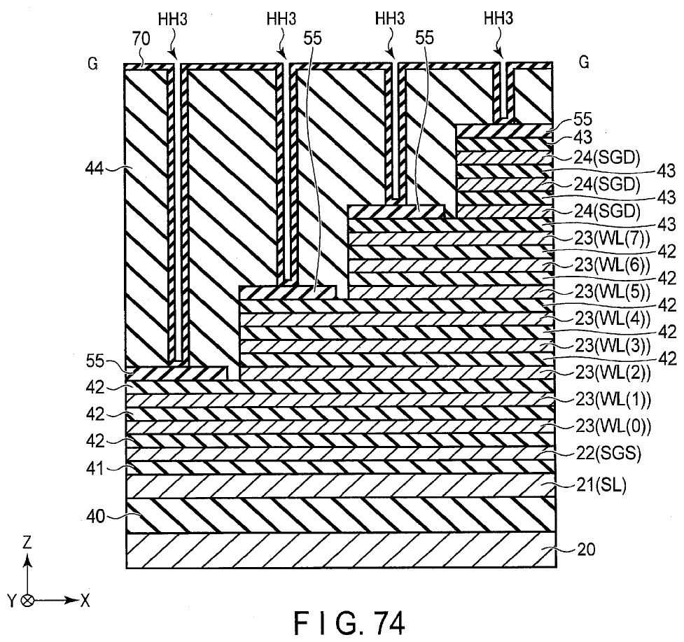

Step S3015 will be described with reference to FIGS. 73 and 74. FIG. 73 is a cross-sectional view showing a cross section taken along line E-E in FIG. 55. FIG. 74 is a cross-sectional view showing a cross section taken along line G-G in FIG. 55.

A film for processing is formed in the third holes HH3 in step S3015. Specifically, as shown in FIGS. 73 and 74, the film for processing 70 is formed in the third holes HH3 formed in step S1014. Accordingly, the film for processing 70 is formed on the side walls and bottoms of the third holes HH3. The film for processing 70 is a film that can secure a selection ratio of etching with the stopper 55.

[S3016]

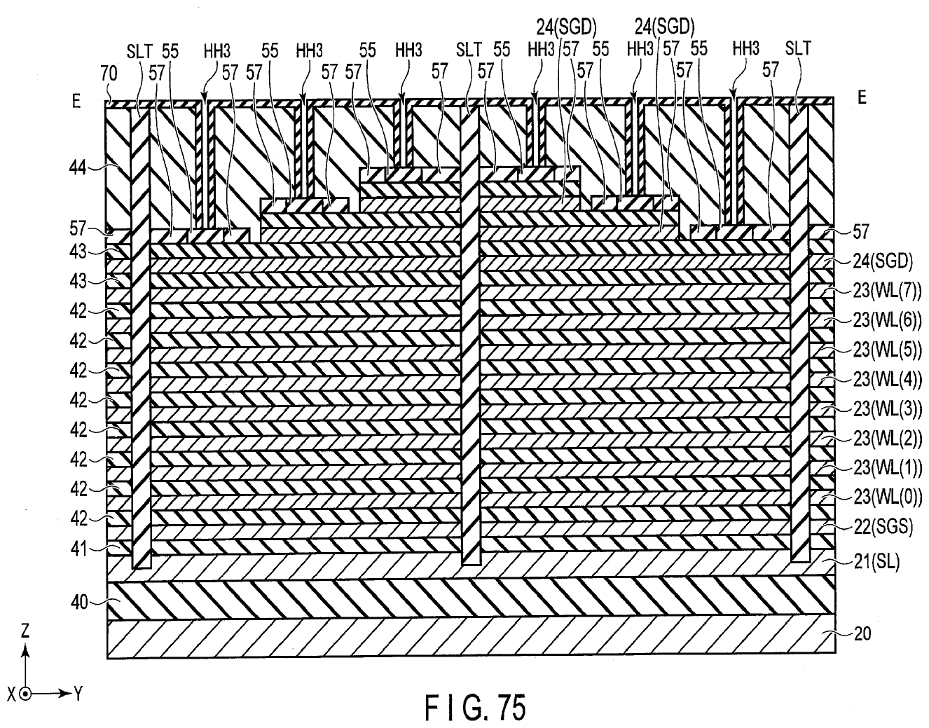

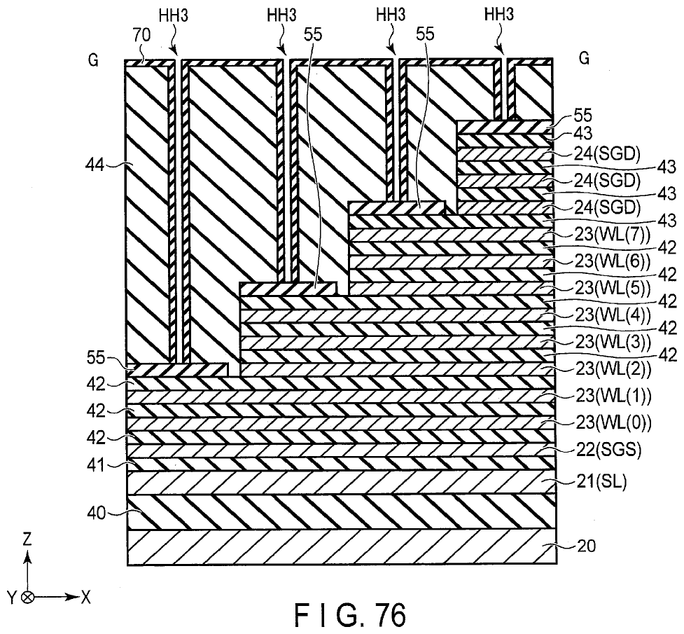

Step S3016 will be described with reference to FIGS. 75 and 76. FIG. 75 is a cross-sectional view showing a cross section taken along line E-E in FIG. 55. FIG. 76 is a cross-sectional view showing a cross section taken along line G-G in FIG. 55.

The film for processing 70 is partially removed in step S3016. Specifically, as shown in FIGS. 75 and 76, the film for processing 70 at the bottoms of the third holes HH3 is removed by anisotropic etching. The anisotropic etching in this step is, for example, RIE.

[S3017]

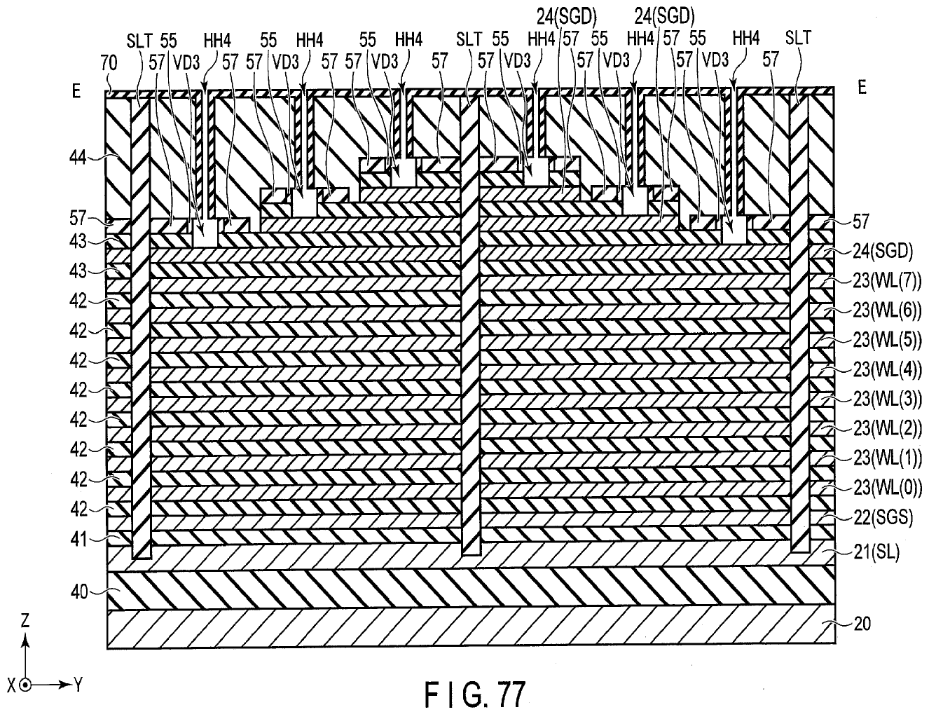

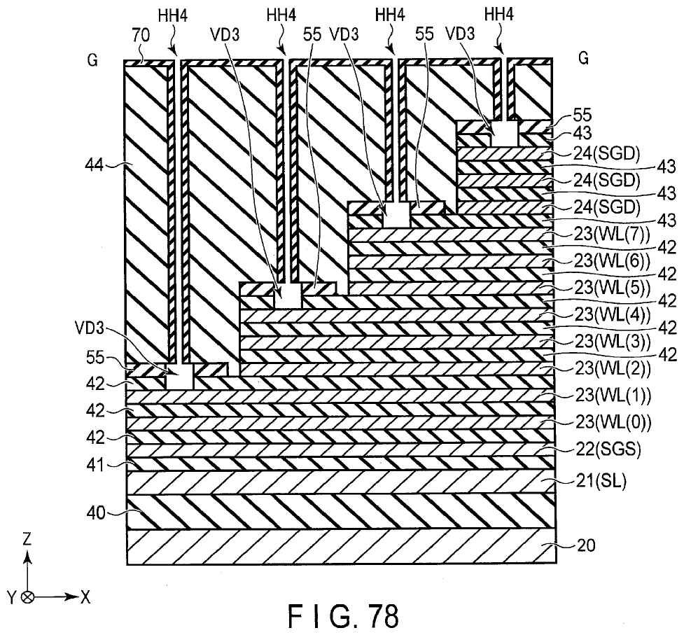

Step S3017 will be described with reference to FIGS. 77 and 78. FIG. 77 is a cross-sectional view showing a cross section taken along line E-E in FIG. 58. FIG. 78 is a cross-sectional view showing a cross section taken along line G-G in FIG. 58.

The stoppers 55 are removed in step S3017. Specifically, as shown in FIGS. 77 and 78, wet etching is performed by using the film for processing 70 formed on the side walls of the third holes HH3 as a mask. In the wet etching, parts of the stoppers 55 provided at the bottoms of the third holes HH3 and therearound as well as the insulating layer 43 or 42 are removed. Accordingly, the fourth holes HH4 that reach the respective terraces T are formed, and the conductive layer 23 or 24, which serves as the terraces T, is exposed at the bottoms of the fourth holes HH4. The portions from which parts of the stoppers 55 and the insulating layer 43 or 42 are removed become voids VD3. The area of the terrace T exposed by each void VD3 is larger than the area of each fourth hole HH4 on the X-Y plane orthogonal to the Z direction.

[S3018]

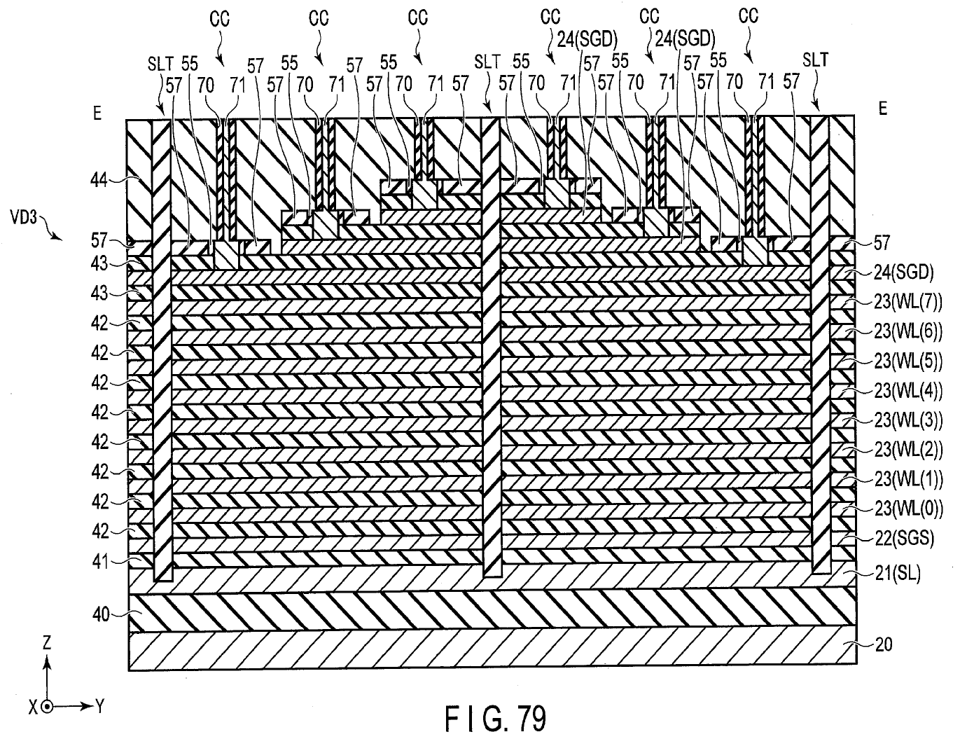

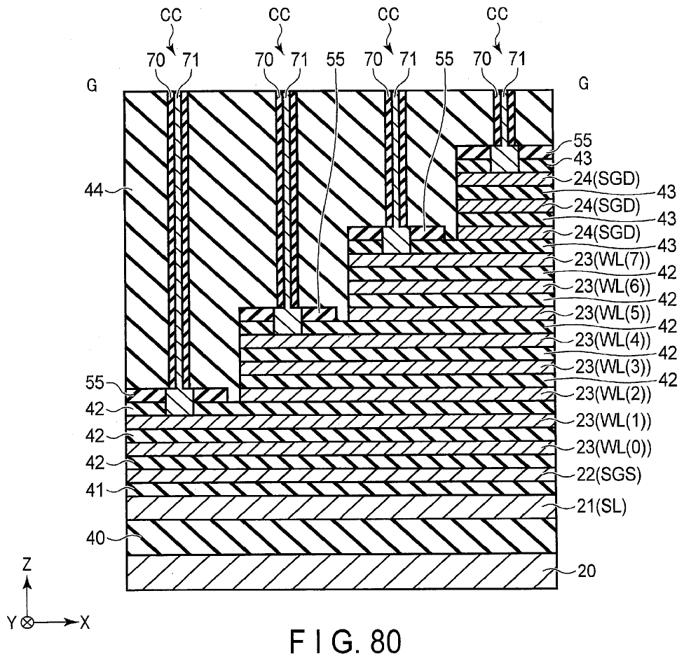

Step S3018 will be described with reference to FIGS. 79 and 80. FIG. 79 is a cross-sectional view showing a cross section taken along line E-E in FIG. 7. FIG. 80 is a cross-sectional view showing a cross section taken along line G-G in FIG. 7.

Contacts CC are formed in step S3018. Specifically, as shown in FIGS. 79 and 80, contact plugs CC are formed on the respective terraces T by embedding a conductive layer 71 in the fourth holes HH4 and the voids VD3. Then, the top surface of the insulating layer 44 is planarized by, for example CMP. The area of a portion of each contact plug CC coupled to the terrace T is larger than the area of the cross section on the X-Y plane orthogonal to the Z direction of a portion of the contact plug CC passing through the insulating layer 44.

In the second modification, the area of contact between the terrace T and the contact plug CC is larger than in the above-described embodiment, and the resistance can be lowered.

### <2-3> Method for Manufacturing Semiconductor Memory Device According to Third Modification

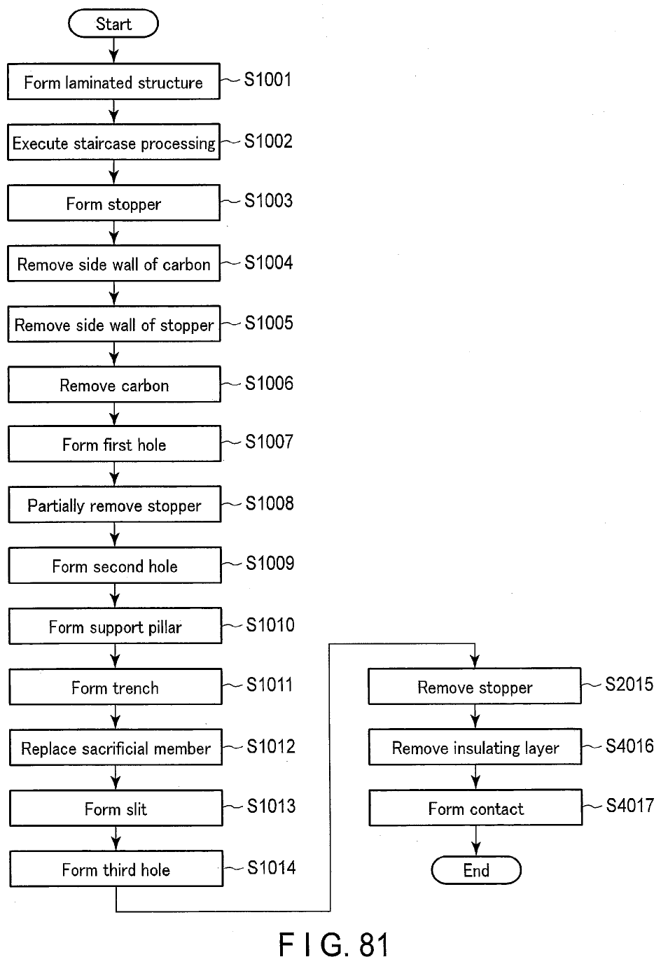

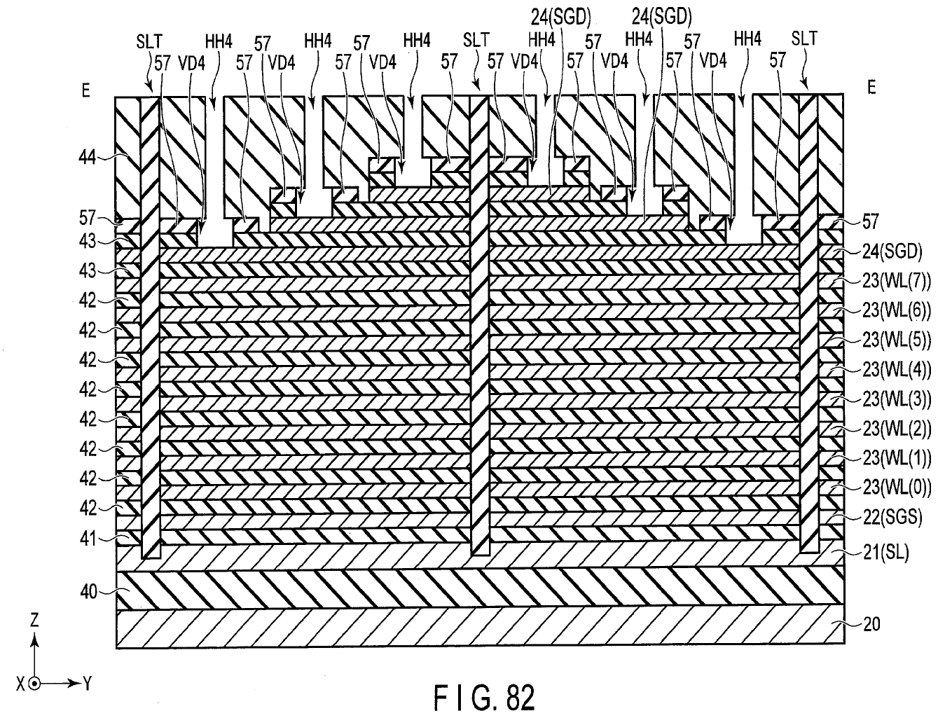

Hereinafter, an example of the series of manufacturing steps related to the hookup area in the semiconductor memory device 1 according to a third modification of the embodiment will be described, with reference to FIG. 81 as appropriate. FIG. 81 is a flowchart showing an example of the method for manufacturing a semiconductor memory device 1 according to the third modification of the embodiment. FIGS. 82 to 85 show cross-sectional structures respectively including structures corresponding to the memory cell array 10 in respective manufacturing steps of the semiconductor memory device 1 according to the third modification of the embodiment. For simplification, descriptions of the steps for manufacturing the cell area CA are omitted herein. The plan view of each manufacturing step to be referred to below shows the area corresponding to FIG. 7.

[S1001] to [S1014]

Steps S1001 to S1014 are the same as those described with reference to FIG. 12.

[S2015]

Step S2015 is the same as that described with reference to FIG. 61. In this modification, the stoppers 55 exposed at the bottoms of the third holes HH3 are not all removed, but the stoppers 55 at the bottoms of the third holes HH3 and therearound are partially removed.

[S4016]

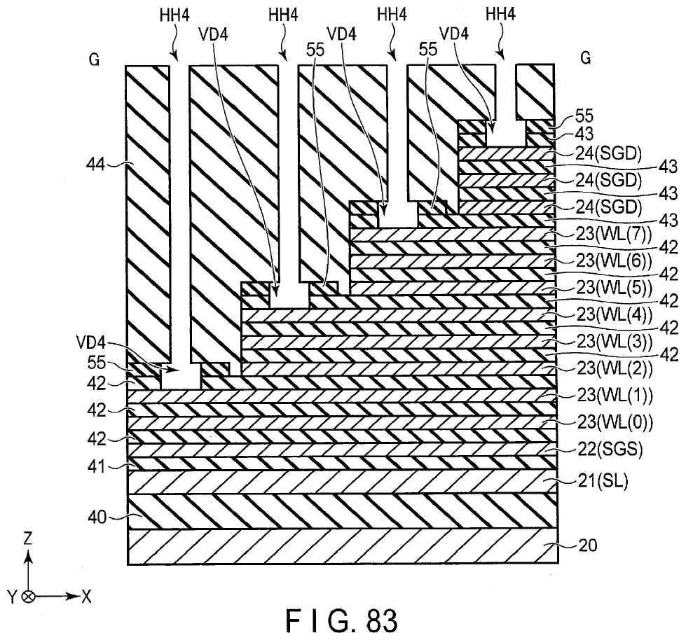

Step S4016 will be described with reference to FIGS. 82 and 83. FIG. 82 is a cross-sectional view showing a cross section taken along line E-E in FIG. 58. FIG. 83 is a cross-sectional view showing a cross section taken along line G-G in FIG. 58.

An insulating layer below the third holes HH3 is removed in step S4016. Specifically, as shown in FIGS. 82 and 83, wet etching is performed via the third holes HH3. In the wet etching, the insulating layer 43 or 42 provided around the bottoms of the third holes HH3 is removed. Accordingly, the fourth holes HH4 that reach the respective terraces T are formed, and the conductive layer 23 or 24, which serves as the terraces T, is exposed at the bottoms of the fourth holes HH4. The portions from which the insulating layer 43 or 42 is removed become voids VD4. The area of the terrace T exposed by each void VD4 is larger than the area of each fourth hole HH4 on the X-Y plane orthogonal to the Z direction.

[S4017]

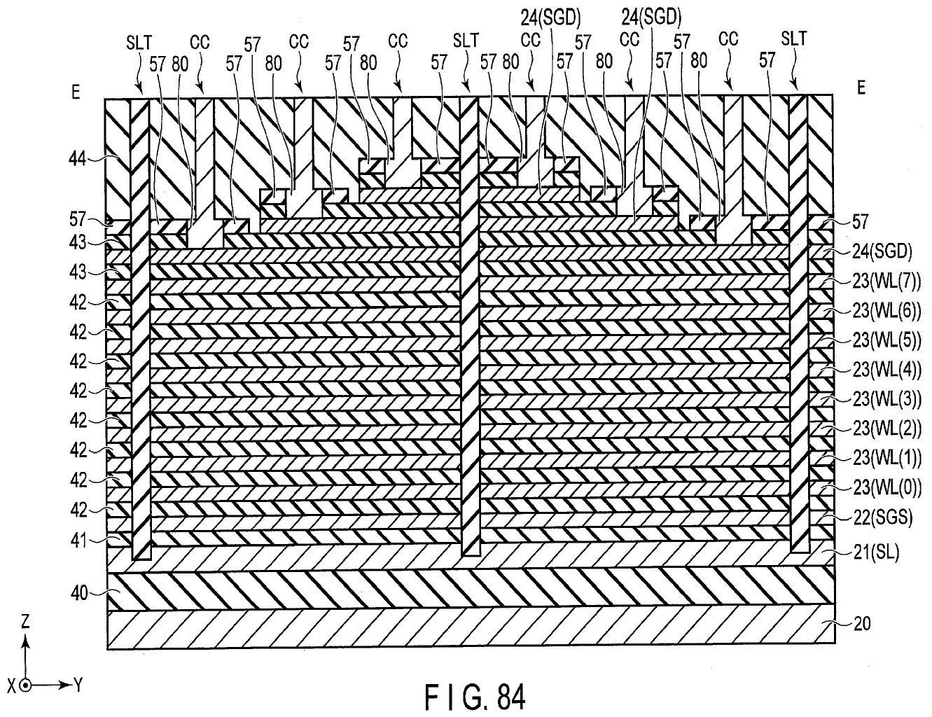

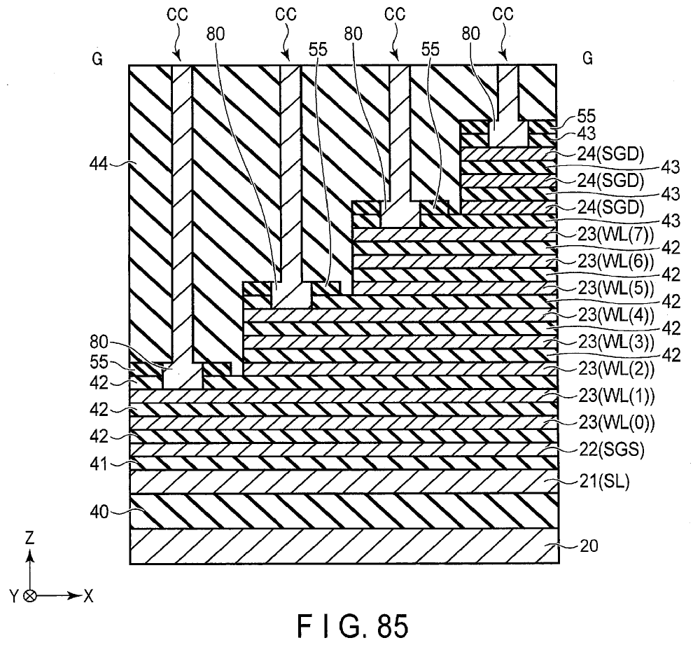

Step S4017 will be described with reference to FIGS. 84 and 85. FIG. 84 is a cross-sectional view showing a cross section taken along line E-E in FIG. 7. FIG. 85 is a cross-sectional view showing a cross section taken along line G-G in FIG. 7.

Contacts CC are formed in step S4017. Specifically, as shown in FIGS. 84 and 85, contact plugs CC are formed on the respective terraces T by embedding a conductive layer 80 in the fourth holes HH4 and the voids VD4. Then, the top surface of the insulating layer 44 is planarized by, for example CMP. The area of a portion of each contact plug CC coupled to the terrace T is larger than the area of the cross section on the X-Y plane orthogonal to the Z direction of a portion of the contact plug CC passing through the insulating layer 44.

In the third modification, the area of contact between the terrace T and the contact plug CC is larger than in the above-described embodiment, and the resistance can be lowered, as in the second modification.

### <3> Others

In the above embodiment, the memory cell array 10 may have a different structure. For example, the memory pillar MP may have a structure in which a plurality of pillars are coupled in the Z direction.

Described as an example in the above embodiment is the case where the semiconductor memory device 1 has a structure in which a circuit such as the sense amplifier module 16 is provided under the memory cell array 10; however, the structure is not limited to this. For example, the semiconductor memory device 1 may have a structure in which the memory cell array 10, the sense amplifier module 16, and the like are formed on the semiconductor substrate 20. Alternatively, the semiconductor memory device 1 may have a structure in which a chip provided with the sense amplifier module 16 and the like is bonded to a chip provided with the memory cell array 10.

Described in the above embodiment is the structure in which a word line WL is adjacent to the select gate line SGS, and a word line WL is adjacent to a select gate line SGD; however, the structure is not limited to this. For example, a dummy word line may be provided between the word line WL of the topmost layer and a select gate line SGD. Similarly, a dummy word line may be provided between the word line WL of the bottommost layer and the select gate line SGS. When a plurality of pillars are coupled, a conductive layer in the vicinity of each coupling portion may be used as a dummy word line.

The drawings used for description of the above embodiment exemplify the case where the memory pillars MP, support pillars HR, and the like have the same outside diameter and cross-sectional area at any level in the Z direction, but the embodiment is not limited thereto. For example, the memory pillars MP and support pillars HR may be tapered, or may be bulged in the middle in the Z direction.

The expression “coupling” herein refers to electrical coupling, and does not exclude, for example, an existence of another element between the coupled elements. The expression “electrically coupled” may be “electrically coupled” with an insulator interposed in-between as long as the same operation as that in the case of “electrically coupled” can be ensured. The “film thickness” indicates, for example, the difference between the inside diameter and the outside diameter of a constituent element formed in the memory hole MH. The “inside diameter” and “outside diameter” indicate those on a cross section parallel to the semiconductor substrate 20, respectively.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first laminated body including a first conductive layer, a first insulating layer, a second conductive layer, and a second insulating layer, the first conductive layer, the first insulating layer, the second conductive layer, and the second insulating layer being sequentially stacked in a first direction;
a first pillar passing through the first laminated body, and including portions intersecting with the first and second conductive layers and configured to function as first and second memory cell transistors, respectively;
a third insulating layer provided above the first laminated body;
a first stopper having an etching rate different from etching rates of the first to third insulating layers and provided on the first insulating layer on a first region of the first conductive layer;
a second stopper having an etching rate different from the etching rates of the first to third insulating layers, provided on the second insulating layer on a second region of the second conductive layer, and separated from the first stopper;
a third conductive layer passing through the first insulating layer, the first stopper, and the third insulating layer, and coupled to the first region; and
a fourth conductive layer passing through the second insulating layer, the second stopper, and the third insulating layer, and coupled to the second region.

2. The semiconductor memory device according to claim 1, wherein the first stopper and the second stopper include a conductive material.

3. The semiconductor memory device according to claim 1, wherein the first conductive layer is a first word line of the first memory cell transistor, and the second conductive layer is a second word line of the second memory cell transistor.

4. The semiconductor memory device according to claim 1, wherein
the first to third insulating layers include silicon oxide, and
in anisotropic etching on silicon oxide, etching rates of the first stopper and the second stopper are lower than etching rates of the first to third insulating layers.

5. The semiconductor memory device according to claim 1, further comprising a slit dividing the first laminated body in a second direction orthogonal to the first direction,
wherein the first stopper and the second stopper are separated from the slit.

6. The semiconductor memory device according to claim 1, further comprising:
a first insulating member extending in the first direction in the first laminated body and passing through the first region of the first conductive layer of the first laminated body near the third conductive layer; and
a second insulating member extending in the first direction in the first laminated body and passing through the second region of the second conductive layer of the first laminated body near the fourth conductive layer.

7. The semiconductor memory device according to claim 6, wherein
the first insulating member includes a first protrusion that protrudes in a direction orthogonal to the first direction, and
the second insulating member includes a second protrusion that protrudes in the direction orthogonal to the first direction.

8. The semiconductor memory device according to claim 7, wherein
the first protrusion of the first insulating member is adjacent to the first stopper in the direction orthogonal to the first direction, and
the second protrusion of the second insulating member is adjacent to the second stopper in the direction orthogonal to the first direction.

9. The semiconductor memory device according to claim 1, further comprising:
a third stopper; and
a fifth conductive layer,
wherein the first laminated body further includes a sixth conductive layer and a fourth insulating layer that are sequentially stacked on the second insulating layer in the first direction,
a portion where the first pillar intersects the sixth conductive layer functions as a select transistor,
the third stopper has an etching rate different from etching rates of the first to fourth insulating layers, is provided on the fourth insulating layer on a third region of the sixth conductive layer, and is separated from the second stopper, and
the fifth conductive layer passes through the fourth insulating layer, the third stopper, and the third insulating layer, and is coupled to the third region.

10. The semiconductor memory device according to claim 9, wherein the first to third stoppers include a conductive material.

11. The semiconductor memory device according to claim 9, wherein the sixth conductive layer is a select gate line of the select transistor.

12. The semiconductor memory device according to claim 1, wherein
an area of a portion of the third conductive layer coupled to the first region is larger than an area of a portion of the third conductive layer passing through the third insulating layer on a plane orthogonal to the first direction, and
an area of a portion of the fourth conductive layer coupled to the second region is larger than an area of a portion of the fourth conductive layer passing through the third insulating layer on a plane orthogonal to the first direction.

13. A semiconductor memory device comprising:
a first laminated body including a first conductive layer, a first insulating layer, a second conductive layer, and a second insulating layer, the first conductive layer, the first insulating layer, the second conductive layer, and the second insulating layer being sequentially stacked in a first direction;
a first pillar passing through the first laminated body, and including portions intersecting with the first and second conductive layers and configured to function as first and second memory cell transistors, respectively;
a third insulating layer provided above the first laminated body;
a third conductive layer passing through the first and third insulating layers, and coupled to a first region of the first conductive layer; and
a fourth conductive layer passing through the second and third insulating layers, and coupled to a second region of the second conductive layer, wherein
an area of a portion of the third conductive layer coupled to the first region is larger than an area of a portion of the third conductive layer passing through the third insulating layer on a plane orthogonal to the first direction, and
an area of a portion of the fourth conductive layer coupled to the second region is larger than an area of a portion of the fourth conductive layer passing through the third insulating layer on a plane orthogonal to the first direction.

14. The semiconductor memory device according to claim 13, wherein the first conductive layer is a first word line of the first memory cell transistor, and the second conductive layer is a second word line of the second memory cell transistor.

15. The semiconductor memory device according to claim 13, further comprising a first insulating member extending in the first direction in the first laminated body, and passing through the first region of the first conductive layer of the first laminated body near the third conductive layer.

16. The semiconductor memory device according to claim 15, wherein the first insulating member includes a first protrusion that protrudes in a direction orthogonal to the first direction.

17. The semiconductor memory device according to claim 16, further comprising a slit dividing the first laminated body in a second direction orthogonal to the first direction, wherein the slit is in contact with the first protrusion of the first insulating member.

18. The semiconductor memory device according to claim 13, further comprising a fifth conductive layer,
wherein the first laminated body further includes a sixth conductive layer and a fourth insulating layer that are sequentially stacked on the second insulating layer in the first direction,
a portion where the first pillar intersects the sixth conductive layer functions as a select transistor,
the fifth conductive layer passes through the fourth and third insulating layers, and is coupled to a third region of the sixth conductive layer, and
an area of a portion of the fifth conductive layer coupled to the third region is larger than an area of a portion of the fifth conductive layer passing through the third insulating layer on a plane orthogonal to the first direction.

19. The semiconductor memory device according to claim 18, wherein the sixth conductive layer is a select gate line of the select transistor.

20. A method for manufacturing a semiconductor memory device, comprising:
sequentially stacking a first member, a first insulating layer, a second member, and a second insulating layer in a first direction;
processing the first member, the first insulating layer, the second member, and the second insulating layer to form a first region of the first member and a second region of the second member so as not to overlap each other in the first direction;
forming a first stopper having an etching rate different from an etching rate of the first insulating layer on the first insulating layer on the first region of the first member and a second stopper having an etching rate different from an etching rate of the second insulating layer and separated from the first stopper on the second insulating layer on the second region of the second member;
forming a third insulating layer having an etching rate different from the etching rates of the first and second stoppers on the first and second stoppers;
replacing the first member with a first conductive layer and the second member with a second conductive layer;
forming a plurality of first holes each passing through the third insulating layer and reaching the first stopper or the second stopper;
forming a plurality of second holes each passing through the first stopper and the first insulating layer or the second stopper and the second insulating layer and reaching the first region of the first conductive layer or the second region of the second conductive layer; and
forming a conductor in the second holes.
